(19) United States
(12) Patent Application Publication
(10) Pub. No.: US 2017/0075155 A1
(43) Pub. Date: Mar. 16, 2017

(54) DISPLAY DEVICE AND MANUFACTURING METHOD OF THE SAME

(71) Applicant: Semiconductor Energy Laboratory Co., LTD., Atsugi-shi (JP)

(72) Inventors: Yoshiaki OIKAWA, Atsugi (JP); Junichi KOEZUKA, Tochigi (JP); Kenichi OKAZAKI, Tochigi (JP)

(21) Appl. No.: 15/261,220

(22) Filed: Sep. 9, 2016

(30) Foreign Application Priority Data
Sep. 11, 2015 (JP) 2015-179114

(51) Int. Cl. G02F 1/1368; G02F 1/1335; H01L 27/12

(52) U.S. Cl. CPC G02F 1/1368; H01L 27/1225; G02F 1/133555; G02F 2201/123; G02F 2202/10

(57) ABSTRACT

A novel display device that is highly convenient or reliable is provided. Furthermore, a display device with low power consumption and high display quality is provided. The display device includes a first display element, a second display element, a first transistor, and a second transistor. The first display element includes a first pixel electrode and a liquid crystal layer. The second display element includes a second pixel electrode and a light-emitting layer. The first transistor is electrically connected to the first pixel electrode. The second transistor is electrically connected to the second pixel electrode. The first transistor and the second transistor each include an oxide semiconductor film. The first pixel electrode and the second pixel electrode each include at least one metal element contained in the oxide semiconductor film.

### BACKGROUND OF THE INVENTION

1. Field of the Invention

One embodiment of the present invention relates to a display device and a manufacturing method thereof.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specific examples of the technical field of one embodiment of the present invention disclosed in this specification include a semiconductor device, a display device, a light-emitting device, a power storage device, a memory device, a method for driving any of them, and a method for manufacturing any of them.

2. Description of the Related Art

There is a liquid crystal display device in which a surface-emitting light source is provided as a backlight and combined with a transmissive liquid crystal display device in order to reduce power consumption and suppress a reduction in display quality (see Patent Document 1).

### REFERENCE

### Patent Document

### [Patent Document 1] Japanese Published Patent Application No. 2011-248351

### SUMMARY OF THE INVENTION

An object of one embodiment of the present invention is to provide a novel display device that is highly convenient or reliable.

Another object of one embodiment of the present invention is to provide a display device with low power consumption and high display quality. Another object of one embodiment of the present invention is to reduce the width of the driver circuit of the display device to achieve a narrower bezel. Another object of one embodiment of the present invention is to provide a novel display device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is a display device including a first display element, a second display element, a first transistor, and a second transistor. The first display element includes a first pixel electrode and a liquid crystal layer. The second display element includes a second pixel electrode and a light-emitting layer. The first transistor is electrically connected to the first pixel electrode. The second transistor is electrically connected to the second pixel electrode. The first transistor and the second transistor each include an oxide semiconductor film. The first pixel electrode and the second pixel electrode each include at least one metal element contained in the oxide semiconductor film.

In the above embodiment, it is preferable that the first display element further include a reflective film. In the above embodiment, it is preferable that the reflective film be electrically connected to the first pixel electrode and have a function of reflecting incident light. In the above embodiment, it is preferable that the reflective film be provided with an opening transmitting incident light. In the above embodiment, it is preferable that the second display element have a function of emitting light toward the opening.

In any of the above embodiments, the oxide semiconductor film preferably contains In, Zn, and M (M is Al, Ga, Y, or Sn). In any of the above embodiments, it is preferable that the oxide semiconductor film include a crystal part and that the crystal part have c-axis alignment.

In any of the above embodiments, it is preferable that one or both of the first transistor and the second transistor have a staggered structure.

In any of the above embodiments, it is preferable that one or both of the first transistor and the second transistor have a first conductive film, a first insulating film over the first conductive film, a first oxide semiconductor film over the first insulating film, a second insulating film over the first oxide semiconductor film, and a second oxide semiconductor film over the second insulating film. The second oxide semiconductor film covers a side surface of the first oxide semiconductor film with the second insulating film positioned therebetween in a cross section in a channel width direction. The first oxide semiconductor film is surrounded by the first conductive film and the second oxide semiconductor film in the cross section in the channel width direction.

One embodiment of the present invention can provide a novel display device that is highly convenient or reliable. According to one embodiment of the present invention, a display device with low power consumption and high display quality can be provided. According to one embodiment of the present invention, a display device with reduced width of the driver circuit and a narrower bezel can be provided. According to one embodiment of the present invention, a novel display device can be provided.

Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIG. 1 is a block diagram and circuit diagrams illustrating a display device.

FIG. 2 is a circuit diagram illustrating a pixel circuit.

FIGS. 3A and 3B are schematic views each illustrating a display region of a display element.

FIGS. 4A and 4B are top views illustrating a display device and a pixel circuit.

FIG. 5 is a cross-sectional view illustrating a display device.

FIG. 6 is a cross-sectional view illustrating a display device.

FIG. 7 is a cross-sectional view illustrating a display device.

FIG. 8 is a cross-sectional view illustrating a display device.

FIGS. 9A to 9C illustrate cross-sectional views illustrating a manufacturing process of a display device.

FIGS. 10A to 10C are cross-sectional views illustrating a manufacturing process of a display device.

FIGS. 11A to 11C are cross-sectional views illustrating a manufacturing process of a display device.

FIGS. 12A to 12C are cross-sectional views illustrating a manufacturing process of a display device.

FIGS. 13A and 13B are cross-sectional views illustrating a manufacturing process of a display device.

FIG. 14 is a cross-sectional view illustrating a manufacturing process of a display device.

FIG. 15 is a cross-sectional view illustrating a display device.

FIG. 16 is a cross-sectional view illustrating a display device.

FIG. 17 is a cross-sectional view illustrating a display device.

FIG. 18 is a cross-sectional view illustrating a display device.

FIGS. 19A to 19C are a top view and cross-sectional views illustrating a semiconductor device.

FIGS. 20A to 20C are a top view and cross-sectional views illustrating a semiconductor device.

FIGS. 21A and 21B are cross-sectional views illustrating a semiconductor device.

FIGS. 22A and 22B are cross-sectional views illustrating a semiconductor device.

FIGS. 23A and 23B are cross-sectional views illustrating a semiconductor device.

FIGS. 24A and 24B are cross-sectional views illustrating a semiconductor device.

FIGS. 25A and 25B are cross-sectional views illustrating a semiconductor device.

FIGS. 26A and 26B are cross-sectional views illustrating a semiconductor device.

FIGS. 27A and 27B are cross-sectional views illustrating a semiconductor device.

FIGS. 28A and 28B are cross-sectional views illustrating a semiconductor device.

FIGS. 29A and 29B are cross-sectional views illustrating a semiconductor device.

FIGS. 30A to 30C each illustrate a band structure.

FIGS. 31A to 31D are cross-sectional views illustrating a method for manufacturing a semiconductor device.

FIGS. 32A to 32C are cross-sectional views illustrating a method for manufacturing a semiconductor device.

FIGS. 33A and 33B are cross-sectional views illustrating a method for manufacturing a semiconductor device.

FIGS. 34A to 34D are cross-sectional views illustrating a method for manufacturing a semiconductor device.

FIGS. 35A to 35C are cross-sectional views illustrating a method for manufacturing a semiconductor device.

FIGS. 36A to 36C are cross-sectional views illustrating a method for manufacturing a semiconductor device.

FIGS. 37A to 37E show structural analysis of a CAAC-OS and a single crystal oxide semiconductor by XRD and selected-area electron diffraction patterns of a CAAC-OS.

FIGS. 38A to 38E show a cross-sectional TEM image and plan-view TEM images of a CAAC-OS and images obtained through analysis thereof.

FIGS. 39A to 39D show electron diffraction patterns and a cross-sectional TEM image of an nc-OS.

FIGS. 40A and 40B are cross-sectional TEM images of an a-like OS.

FIG. 41 shows a change of crystal parts of an In—Ga—Zn oxide due to electron irradiation.

FIG. 42 illustrates a display module.

FIGS. 43A to 43E each illustrate an electronic device.

FIGS. 44A to 44E are perspective views each illustrating a display device.

FIGS. 45A and 45B are perspective views illustrating a display device.

FIGS. 46A and 46B illustrate a structure of a data processor.

### DETAILED DESCRIPTION OF THE INVENTION

Embodiments will be described below with reference to drawings. However, the embodiments can be implemented in many different modes, and it will be readily appreciated by those skilled in the art that modes and details thereof can be changed in various ways without departing from the spirit and scope of the present invention. Thus, the present invention should not be interpreted as being limited to the following description of the embodiments.

In the drawings, the size, the layer thickness, and the region are exaggerated for clarity in some cases. Therefore, embodiments of the present invention are not limited to such a scale. Note that the drawings are schematic views showing ideal examples, and embodiments of the present invention are not limited to shapes or values shown in the drawings.

Note that in this specification, ordinal numbers such as “first”, “second”, and “third” are used in order to avoid confusion among components, and the terms do not limit the components numerically.

Note that in this specification, terms for describing arrangement, such as “over” “above”, “under”, and “below”, are used for convenience in describing a positional relation between components with reference to drawings. Furthermore, the positional relation between components is changed as appropriate in accordance with a direction in which each component is described. Thus, there is no limitation on terms used in this specification, and description can be made appropriately depending on the situation.

In this specification and the like, a transistor is an element having at least three terminals of a gate, a drain, and a source. In addition, the transistor has a channel region between a drain (a drain terminal, a drain region, or a drain electrode) and a source (a source terminal, a source region, or a source electrode), and current can flow through the drain, the channel region, and the source. Note that in this specification and the like, a channel region refers to a region through which current mainly flows.

Furthermore, functions of a source and a drain might be switched when transistors having different polarities are employed or a direction of current flow is changed in circuit operation, for example. Therefore, the terms “source” and “drain” can be switched in this specification and the like.

Note that in this specification and the like, the expression “electrically connected” includes the case where components are connected through an “object having any electric function”. There is no particular limitation on an “object having any electric function” as long as electric signals can be transmitted and received between components that are connected through the object. Examples of an “object having any electric function” are a switching element such as a transistor, a resistor, an inductor, a capacitor, and elements with a variety of functions as well as an electrode and a wiring.

In this specification and the like, the term “parallel” indicates that the angle formed between two straight lines is greater than or equal to −10° and less than or equal to 10°, and accordingly also includes the case where the angle is greater than or equal to −5° and less than or equal to 5°. The term “perpendicular” indicates that the angle formed between two straight lines is greater than or equal to 80° and less than or equal to 100°, and accordingly also includes the case where the angle is greater than or equal to 85° and less than or equal to 95°.

In this specification and the like, the terms “film” and “layer” can be interchanged with each other. For example, in some cases, the term “conductive film” can be used instead of the term “conductive layer”, and the term “insulating layer” can be used instead of the term “insulating film”.

Unless otherwise specified, off-state current in this specification and the like refers to drain current of a transistor in an off state (also referred to as a non-conducting state and a cutoff state). Unless otherwise specified, the off state of an n-channel transistor means that the voltage between its gate and source (V_{gs}: gate-source voltage) is lower than the threshold voltage Vₜₕ, and the off state of a p-channel transistor means that the gate-source voltage V_{gs} is higher than the threshold voltage Vₜₕ. For example, the off-state current of an n-channel transistor sometimes refers to drain current that flows when the gate-source voltage V_{gs} is lower than the threshold voltage Vₜₕ.

The off-state current of a transistor depends on V_{gs} in some cases. Therefore, “the off-state current of a transistor is I or lower” may mean that the off-state current of the transistor is I or lower at a certain V_{gs}. The off-state current of a transistor may refer to off-state current at a given V_{gs}, at V_{gs} in a given range, at V_{gs} at which sufficiently low off-state current is obtained, or the like.

As an example, an assumption is made that an n-channel transistor has a threshold voltage Vₜₕ of 0.5 V and a drain current of 1×10⁻⁹ A at V_{gs} of 0.5 V, 1×10⁻¹³ A at V_{gs} of 0.1 V, 1×10⁻¹⁹ A at V_{gs} of −0.5 V, and 1×10⁻²² A at V_{gs} of −0.8 V. The drain current of the transistor is 1×10⁻¹⁹ A or lower at V_{gs} of −0.5 V or at V_{gs} in the range of −0.8 V to −0.5 V; therefore, it may be said that the off-state current of the transistor is 1×10⁻¹⁹ A or lower. Since the drain current of the transistor is 1×10⁻²² A or lower at a certain V_{gs}, it may be said that the off-state current of the transistor is 1×10⁻²² A or lower.

In this specification and the like, the off-state current of a transistor with a channel width W is sometimes represented by a current value per channel width W or by a current value per given channel width (e.g., 1 μm). In the latter case, the off-state current may be represented by current per length (e.g., A/μm).

The off-state current of a transistor depends on temperature in some cases. Unless otherwise specified, the off-state current in this specification may be off-state current at room temperature, 60° C., 85° C., 95° C., or 125° C. Alternatively, the off-state current may be off-state current at a temperature at which the reliability of a semiconductor device or the like including the transistor is ensured or a temperature at which the semiconductor device or the like including the transistor is used (e.g., a temperature in the range of 5° C. to 35° C.). The state in which the off-state current of a transistor is I or lower may indicate that the off-state current of the transistor at room temperature, 60° C., 85° C., 95° C., 125° C., a temperature at which the reliability of a semiconductor device or the like including the transistor is ensured, or a temperature at which the semiconductor device or the like including the transistor is used (e.g., a temperature in the range of 5° C. to 35° C.) is I or lower at a certain V_{gs}.

The off-state current of a transistor depends on the voltage V_{ds} between its drain and source in some cases. Unless otherwise specified, the off-state current in this specification may be off-state current at V_{ds} of 0.1 V, 0.8 V, 1 V, 1.2 V, 1.8 V, 2.5 V, 3 V, 3.3 V, 10 V, 12 V, 16 V, or 20 V. Alternatively, the off-state current may be off-state current at V_{ds} at which the reliability of a semiconductor device or the like including the transistor is ensured or at V_{ds} used in the semiconductor device or the like including the transistor. The state in which the off-state current of a transistor is I or lower may indicate that the off-state current of the transistor at V_{ds} of 0.1 V, 0.8 V, 1 V, 1.2 V, 1.8 V, 2.5 V, 3 V, 3.3 V, 10 V, 12 V, 16 V, or 20 V, at V_{ds} at which the reliability of a semiconductor device or the like including the transistor is ensured, or at V_{ds} used in the semiconductor device or the like including the transistor is I or lower at a certain V_{gs}.

In the above description of the off-state current, a drain may be replaced with a source. That is, the off-state current sometimes refers to current that flows through a source of a transistor in the off state.

In this specification and the like, the term “leakage current” sometimes expresses the same meaning as “off-state current”. In this specification and the like, the off-state current sometimes refers to current that flows between a source and a drain of a transistor in the off state, for example.

In this specification and the like, a “semiconductor” includes characteristics of an “insulator” in some cases when the conductivity is sufficiently low, for example. Furthermore, a “semiconductor” and an “insulator” cannot be strictly distinguished from each other in some cases because a border between the “semiconductor” and the “insulator” is not clear. Accordingly, a “semiconductor” in this specification and the like can be called an “insulator” in some cases. Similarly, an “insulator” in this specification and the like can be called a “semiconductor” in some cases. Alternatively, an “insulator” in this specification and the like can be called a “semi-insulator” in some cases.

In this specification and the like, a “semiconductor” includes characteristics of a “conductor” in some cases when the conductivity is sufficiently high, for example. Further, a “semiconductor” and a “conductor” cannot be strictly distinguished from each other in some cases because a border between the “semiconductor” and the “conductor” is not clear. Accordingly, a “semiconductor” in this specification and the like can be called a “conductor” in some cases. Similarly, a “conductor” in this specification and the like can be called a “semiconductor” in some cases.

In this specification and the like, an impurity in a semiconductor refers to an element that is not a main component of the semiconductor. For example, an element with a concentration of lower than 0.1 atomic % is an impurity. When an impurity is contained, the density of states (DOS) may be formed in a semiconductor, the carrier mobility may be decreased, or the crystallinity may be decreased, for example. In the case where the semiconductor includes an oxide semiconductor, examples of an impurity which changes characteristics of the semiconductor include Group 1 elements, Group 2 elements, Group 14 elements, Group 15 elements, and transition metals other than the main components; specifically, there are hydrogen (included in water), lithium, sodium, silicon, boron, phosphorus, carbon, and nitrogen, for example. In the case of an oxide semiconductor, oxygen vacancy may be formed by entry of impurities such as hydrogen. Furthermore, when the semiconductor includes silicon, examples of an impurity which changes the characteristics of the semiconductor include oxygen, Group 1 elements except hydrogen, Group 2 elements, Group 13 elements, and Group 15 elements.

### Embodiment 1

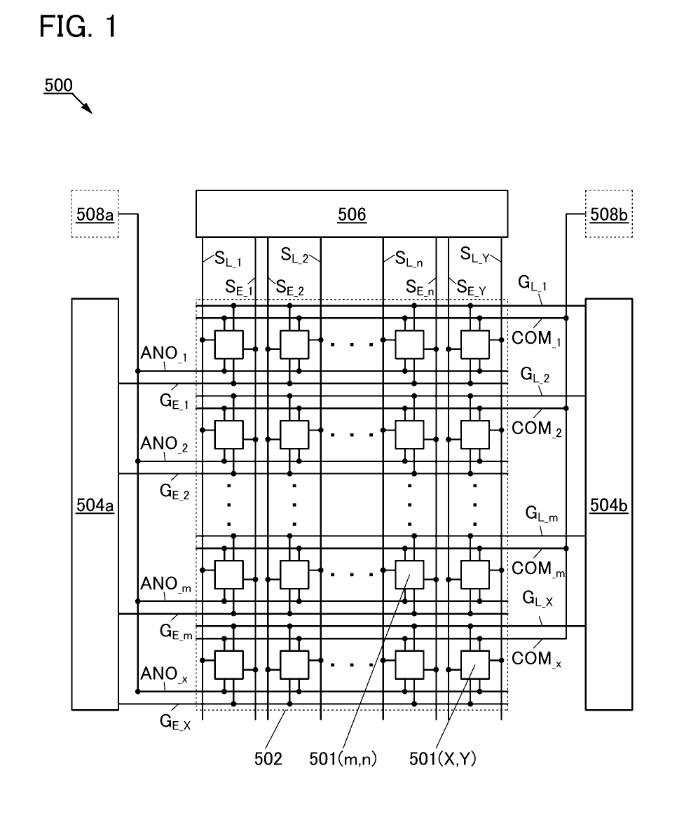

In this embodiment, a display device of one embodiment of the present invention will be described with reference to FIGS. 1, 2, 3A and 3B, 4A and 4B, 5, 6, 7, 8, 9A to 9C, 10A to 10C, 11A to 11C, 12A to 12C, 13A and 13B, and 14.

### <1-1. Structure of Display Device>

First, the structure of a display device is described with reference to FIG. 1. A display device 500 illustrated in FIG. 1 includes a pixel portion 502, gate driver circuit portions 504a and 504b and a source driver circuit portion 506 placed outside the pixel portion 502.

### [Pixel Portion]

The pixel portion 502 includes pixel circuits 501 (X, Y) arranged in X rows (X is a natural number of 2 or more) and Y columns (Y is a natural number of 2 or more). The pixel circuits 501 (X, Y) each include two display elements which have different functions. One of the two display elements has a function of reflecting incident light, and the other has a function of emitting light. Note that the details of the two display elements are described later.

### [Gate Driver Circuit Portion]

Some or all of the gate driver circuit portions 504a and 504b and the source driver circuit portion 506 are preferably formed over a substrate over which the pixel portion 502 is formed. Thus, the number of components and the number of terminals can be reduced. In the case where some or all of the gate driver circuit portions 504a and 504b and the source driver circuit portion 506 are not formed over the substrate over which the pixel portion 502 is formed, a separately prepared driver circuit board (e.g., a driver circuit board formed using a single crystal semiconductor film or a polycrystalline semiconductor film) may be formed in the display device 500 by chip on glass (COG) or tape automated bonding (TAB).

The gate driver circuit portions 504a and 504b have a function of outputting a signal (a scan signal) for selecting the pixel circuits 501 (X, Y). The source driver circuit portion 506 has a function of supplying a signal (data signal) for driving the display elements included in the pixel circuits 501 (X, Y).

The gate driver circuit portion 504a has a function of controlling the potentials of wirings supplied with scan signals (hereinafter, such wirings are referred to as scan lines G_{E}_{_}₁ to G_{E}_{_}_{X}) or a function of supplying an initialization signal. The gate driver circuit portion 504b has a function of controlling the potentials of wirings supplied with scan signals (hereinafter, such wirings are referred to as scan lines G_{L}_{_}₁ to G_{L}_{_}_{X}) or a function of supplying an initialization signal. Without being limited thereto, the gate driver circuit portions 504a and 504b each can control or supply another signal.

Although the structure in which the two gate driver circuit portions 504a and 504b are provided as gate driver circuit portions is illustrated in FIG. 1, the number of the gate driver circuit portions is not limited thereto, and one or three or more gate driver circuit portions may be provided.

### [Source Driver Circuit Portion]

The source driver circuit portion 506 has a function of generating a data signal to be written to the pixel circuits 501 (X, Y) on the basis of an image signal, a function of controlling the potentials of wirings supplied with data signals (such wirings are hereinafter referred to as signal lines S_{L}_{_}₁ to S_{L}_{_}_{Y} and signal lines S_{E}_{_}₁ to S_{E}_{_}_{Y}), or a function of supplying an initialization signal. Without being limited thereto, the source driver circuit portion 506 may have a function of generating, controlling, or supplying another signal.

The source driver circuit portion 506 includes a plurality of analog switches or the like. The source driver circuit portion 506 can output, as data signals, time-divided image signals obtained by sequentially turning on the plurality of analog switches.

Although the structure where one source driver circuit portion 506 is provided is illustrated in FIG. 1, the number of the source driver circuit portions is not limited thereto, and a plurality of source driver circuit portions may be provided in the display device 500. For example, two source driver circuit portions may be provided so that the signal lines S_{L 1} to S_{L Y} are controlled by one of the source driver circuit portions and the signal lines S_{E}_{_}₁ to S_{E}_{_}_{Y} are controlled by the other of the source driver circuit portions.

### [Pixel Circuit]

A pulse signal is input to each of the pixel circuits 501 (X, Y) through one of the scan lines G_{L 1} to G_{L X} and the scan lines G_{E 1} to G_{E X}. A data signal is input to each of the pixel circuits 501 (X, Y) through one of the signal lines S_{L}_{_}₁ to S_{L}_{_}_{Y} and the signal lines S_{E}_{_}₁ to S_{E}_{_}_{Y}.

For example, the pixel circuit 501 (m, n) in the m-th row and the n-th column (m is a natural number of X or less, and n is a natural number of Y or less) is supplied with pulse signals from the gate driver circuit portion 504a through the scan lines G_{L}_{_}ₘ and G_{E}_{_}ₘ and supplied with a data signal from the source driver circuit portion 506 through the signal lines S_{L}_{_}ₙ and S_{E}_{_}ₙ in accordance with the potentials of the scan lines G_{L}_{_}ₘ and G_{E}_{_}ₘ.

The pixel circuit 501 (m, n) includes two display elements as described above. The scan lines G_{L}_{_}₁ to G_{L}_{_}_{X} are wirings which control a potential of a pulse signal supplied to one of the two display elements. The scan lines G_{E 1} to G_{E X} are wirings which control a potential of the pulse signal supplied to the other of the two display elements.

The signal lines S_{L}_{_}₁ to S_{L}_{_}_{Y} are wirings which control a potential of a data signal supplied to one of the two display elements. The signal lines S_{E}_{_}₁ to S_{E}_{_}_{Y} are wirings which control the potential of a data signal supplied to the other of the two display elements.

### [External Circuit]

External circuits 508a and 508b are connected to the display device 500. Note that the external circuits 508a and 508b may be formed in the display device 500.

As shown in FIG. 1, the external circuit 508a is electrically connected to wirings supplied with anode potentials (hereinafter referred to as anode lines ANO_{—1} to ANO_{X}) and the external circuit 508b is electrically connected to wirings supplied with common potentials (hereinafter referred to as common lines COM_{—1} to COM_{—X}).

### <1-2. Configuration Example of Pixel Circuit>

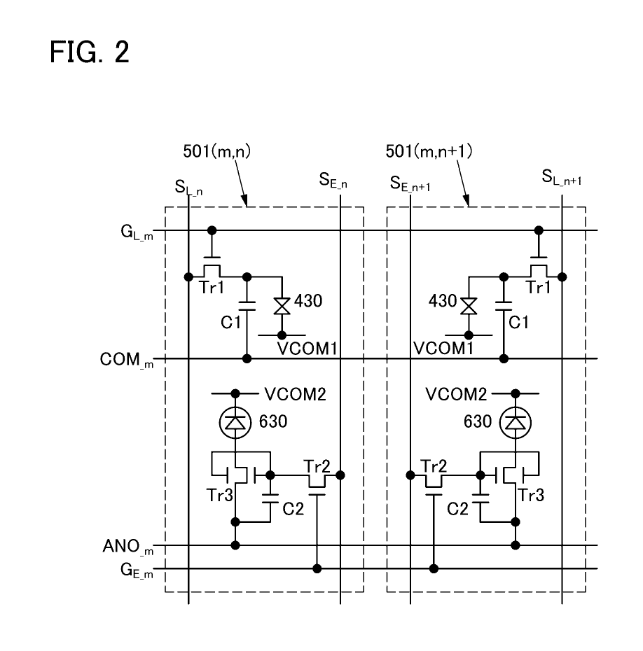

Next, the description is made of a structure of the pixel circuit 501 (m, n) with reference to FIG. 2.

FIG. 2 is a circuit diagram showing the pixel circuit 501 (m, n) and an adjacent pixel circuit (m, n+1) in a column direction of the pixel circuit 501 (m, n) which are included in the display device 500 of one embodiment of the present invention. In this specification and the like, the column direction is a direction in which the value of n of the signal line S_{L n} (or the signal line S_{E n}) increases or decreases and the row direction is a direction in which the value of m of the scan line G_{L}_{_}ₘ (or the scan line G_{E}_{_}ₘ) increases and decreases.

The pixel circuit 501 (m, n) includes a transistor Tr1, a transistor Tr2, a transistor Tr3, a capacitor C1, a capacitor C2, a display element 430, and a display element 630. The pixel circuit (m, n+1) has a configuration similar to that of the pixel circuit 501 (m, n).

The pixel circuit 501 (m, n) is electrically connected to the signal line S_{L}_{_}ₙ, the signal line S_{E}_{_}ₙ, the scan line G_{L}_{_}ₘ, the scan line G_{E}_{_}ₘ, a common line COM_{—m}, a common line VCOM1, a common line VCOM2, and an anode line ANO_{—m}. The pixel circuit 501 (m, n+1) is electrically connected to a signal line S_{L}_{_}ₙ₊₁, a signal line S_{E}_{_}ₙ₊₁, the scan line G_{L}_{_}ₘ, the scan line G_{E}_{_}ₘ, the common line COM_{—m}, the common line VCOM1, the common line VCOM2, and an anode line ANO_{—m}.

Each of the signal lines S_{L}_{_}ₙ and S_{L}_{_}ₙ₊₁, the scan line G_{L}_{_}ₘ, the common line COM_{—m}, and the common line VCOM1 is a wiring for driving the display element 430. Each of the signal lines S_{E}_{_}ₙ and S_{E}_{_}ₙ₊₁, the scan line G_{E}_{_}ₘ, the common line VCOM2, and the anode line ANO_{—m} is a wiring for driving the display element 630.

In the case where a potential supplied to the signal line S_{E}_{_}ₙ and the signal line S_{E}_{_}ₙ₊₁ is different from a potential supplied to the signal line S_{L}_{_}ₙ and the signal line S_{L n+1}, the signal line S_{E n} and the signal line S_{L n+1} are preferably positioned apart from each other as shown in FIG. 2. In other words, the signal line S_{E}_{_}ₙ is preferably positioned adjacent to the signal line S_{E}_{_}ₙ₊₁. With this arrangement, an influence of the potential difference between the signal lines S_{L}_{_}ₙ and S_{L}_{_}ₙ₊₁ and signal lines S_{E}_{_}ₙ and S_{E}_{_}ₙ₊₁ can be reduced.

### <1-3. Structure Example of First Display Element>

The display element 430 has a function of controlling transmission or reflection of light. In particular, the display element 430 is preferably a so-called reflective display element which controls reflection of light. The display element 430 serving as a reflective display element can reduce power consumption of the display device because display can be performed with the use of external light. For example, the display element 430 may have a combined structure of a reflective film, a liquid crystal element, and a polarizing plate, a structure using a micro electro mechanical systems (MEMS), or the like.

### <1-4. Structure Example of Second Display Element>

The display element 630 has a function of outputting light, that is, emitting light. Therefore, the display element 630 may be rephrased as a light-emitting element. For example, an electroluminescence element (also referred to as an EL element), or a light-emitting diode may be used as the display element 630.

As described above, in the display device of one embodiment of the present invention, display elements with different functions are used as shown in the display elements 430 and 630. In the case where a reflective liquid crystal element is used as one of the display elements and a transmissive EL element is used as the other of the display elements, a novel display device that is highly convenient or reliable can be provided. Furthermore, a display device with low power consumption and high display quality can be provided when a reflective liquid crystal element is used in an environment with bright external light and a transmissive EL element is used in an environment with weak external light.

### <1-5. Driving Method for Display Element>

Next, a method for driving the display element 430 and the display element 630 is described. Note that a structure including a liquid crystal element as the display element 430 and a light-emitting element as the display element 630 is used in the description below.

### <Driving Method for First Display Element>

A gate electrode of the transistor Tr1 is electrically connected to the scan line G_{L}_{_}ₘ in the pixel circuit 501 (m, n). One of a source electrode and a drain electrode of the transistor Tr1 is electrically connected to the signal line S_{L}_{_}ₙ. The other of the source electrode and the drain electrode of the transistor Tr1 is electrically connected to one of a pair of electrodes of the display element 430. The transistor Tr1 is configured to be turned on or off to control whether a data signal is written.

The other of the pair of electrodes of the display element 430 is electrically connected to the common line VCOM1.

One of a pair of electrodes of the capacitor C1 is electrically connected to the common line COM_{—m}, and the other of the pair of electrodes of the capacitor C1 is electrically connected to the other of the source electrode and the drain electrode of the transistor Tr1 and one of the pair of electrodes of the display element 430. The capacitor C1 has a function of storing data written to the pixel circuit 501 (m, n).

For example, the gate driver circuit portion 504b in FIG. 1 sequentially selects the pixel circuits row by row to turn on the transistor Tr1, and data of data signals are written. When the transistor Tr1 is turned off, the pixel circuit 501 (m, n) to which the data has been written is brought into a holding state. This operation is sequentially performed row by row; thus, an image is displayed.

### [Driving Method for Second Display Element]

A gate electrode of the transistor Tr2 is electrically connected to the scan line G_{E}_{_}ₘ in the pixel circuit 501 (m, n). One of a source electrode and a drain electrode of the transistor Tr2 is electrically connected to the signal line S_{E}_{_}ₙ and the other of the source electrode and the drain electrode is electrically connected to a gate electrode of the transistor Tr3. The transistor Tr2 is configured to be turned on or off to control whether a data signal is written.

One of a pair of electrodes of the capacitor C2 is electrically connected to the anode line ANOₘ. The other of the pair of electrodes of the capacitor C2 is electrically connected to the other of the source electrode and the drain electrode of the transistor Tr2. The capacitor C2 has a function of storing data written to the pixel circuit 501 (m, n).

The gate electrode of the transistor Tr3 is electrically connected to the other of the source electrode and the drain electrode of the transistor Tr2. One of a source electrode and a drain electrode of the transistor Tr3 is electrically connected to the anode line ANO_{—m}. The other of the source electrode and the drain electrode of the transistor Tr3 is electrically connected to one of a pair of electrodes of the display element 630. The transistor Tr3 includes a backgate electrode. The backgate electrode is electrically connected to the gate electrode of the transistor Tr3.

The other of the pair of electrodes of the display element 630 is electrically connected to the common line VCOM2.

For example, the gate driver circuit portion 504a in FIG. 1 sequentially selects the pixel circuits row by row to turn on the transistor Tr2, and data of data signals are written. When the transistor Tr2 is turned off, the pixel circuit 501 (m, n) to which the data has been written is brought into a holding state. Furthermore, the amount of current flowing between the source electrode and the drain electrode of the transistor Tr3 is controlled in accordance with the potential of the written data signal. The display element 630 emits light with a luminance corresponding to the amount of flowing current. This operation is sequentially performed row by row; thus, an image is displayed.

In this manner, two display elements can be controlled separately with the use of different transistors in the display device of one embodiment of the present invention. Accordingly, a display device having high display quality can be provided.

Transistors used in the display device of one embodiment of the present invention (the transistor Tr1 and the transistor Tr2) each include an oxide semiconductor film. The transistor including an oxide semiconductor film can have relatively high field-effect mobility and thus can operate at high speed. The off-state current of the transistor including an oxide semiconductor film is extremely low. Therefore, the luminance of the display device can be kept even when the refresh rate of the display device is lowered, so that power consumption can be lowered.

A progressive type display, an interlace type display, or the like can be employed as the display type of the display element 430 and the display element 630.

Further, as color elements controlled in the pixel at the time of color display, three colors of R (red), G (green), and B (blue) can be given. Note that color elements are not limited to the three colors of R, G, and B. Alternatively, one or more colors of yellow, cyan, magenta, white, and the like may be added to RGB. Further, the sizes of display regions may be different between respective dots of color elements. However, the display device of one embodiment of the present invention is not limited to a color display device and can be applied to a monochrome display device.

### <1-6. Display Region of Display Element>

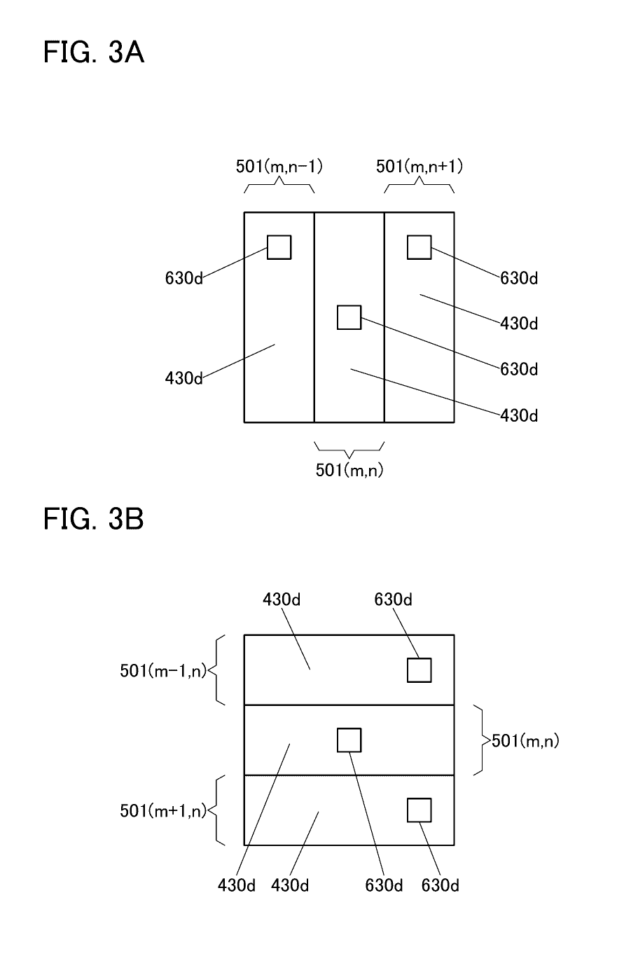

Here, the display regions of the display elements 430 and 630 in the pixel circuit 501 (m, n) are illustrated using FIGS. 3A and 3B.

FIG. 3A is a schematic view illustrating display regions of the pixel circuit 501 (m, n) and pixel circuits 501 (m, n−1) and 501 (m, n+1) which are adjacent to the pixel circuit 501 (m, n) in the column direction.

The pixel circuit 501 (m, n), the pixel circuit 501 (m, n−1), and the pixel circuit 501 (m, n+1) illustrated in FIG. 3A each include a display region 430d functioning as a display region of the display element 430 and a display region 630d functioning as a display region of the display element 630.

For example, the display region 430d includes a region which reflects light and the display region 630d includes a region which transmits light. Furthermore, as shown in FIG. 3A, each of the pixel circuits 501 (m, n−1) and (m, n+1) adjacent to the pixel circuit 501 (m, n) in the column direction of the pixel circuit 501 (m, n) preferably includes the display region 630d at a position different from the position of the display region 630d in the pixel circuit 501 (m, n).

With the arrangement of the display regions 630d shown in FIG. 3A, the manufacturing yield in the case of separately forming the display element 630 can be increased or interference of light extracted from the display elements 630 between adjacent pixel circuits can be suppressed.

Although an example where the pixel circuits 501 (m, n−1), 501 (m, n), and 501 (m, n+1) are provided in a stripe arrangement in the column direction is shown in FIG. 3A, one embodiment of the present invention is not limited thereto. For example, a stripe arrangement in the row direction shown in FIG. 3B may be employed. Alternatively, although not illustrated, delta arrangement or pentile arrangement may be used. FIG. 3B is a schematic view illustrating display regions of the pixel circuit 501 (m, n) and pixel circuits 501 (m−1, n) and 501 (m+1, n) which are adjacent to the pixel circuit 501 (m, n) in the row direction of the pixel circuit 501 (m, n).

The pixel circuit 501 (m, n), the pixel circuit 501 (m−1, n), and the pixel circuit 501 (m+1, n) illustrated in FIG. 3B each include the display region 430d functioning as a display region of the display element 430 and the display region 630d functioning as a display region of the display element 630. The structures of the display regions 430d and 630d may be similar to those shown in FIG. 3A.

### <1-7. Structure Example of Display Device (Top View)>

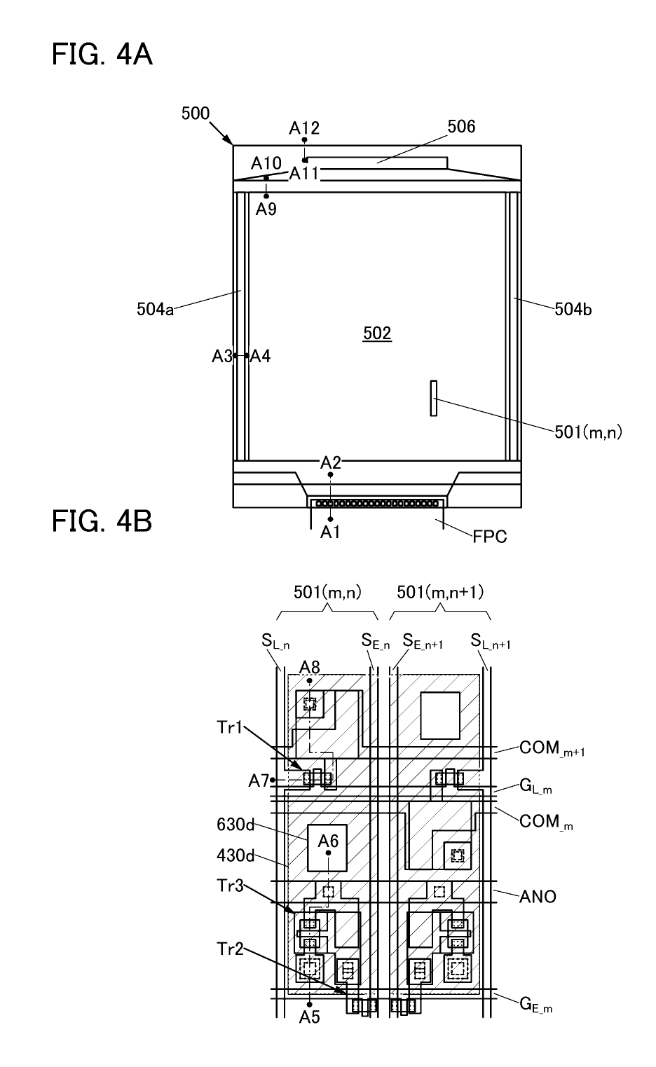

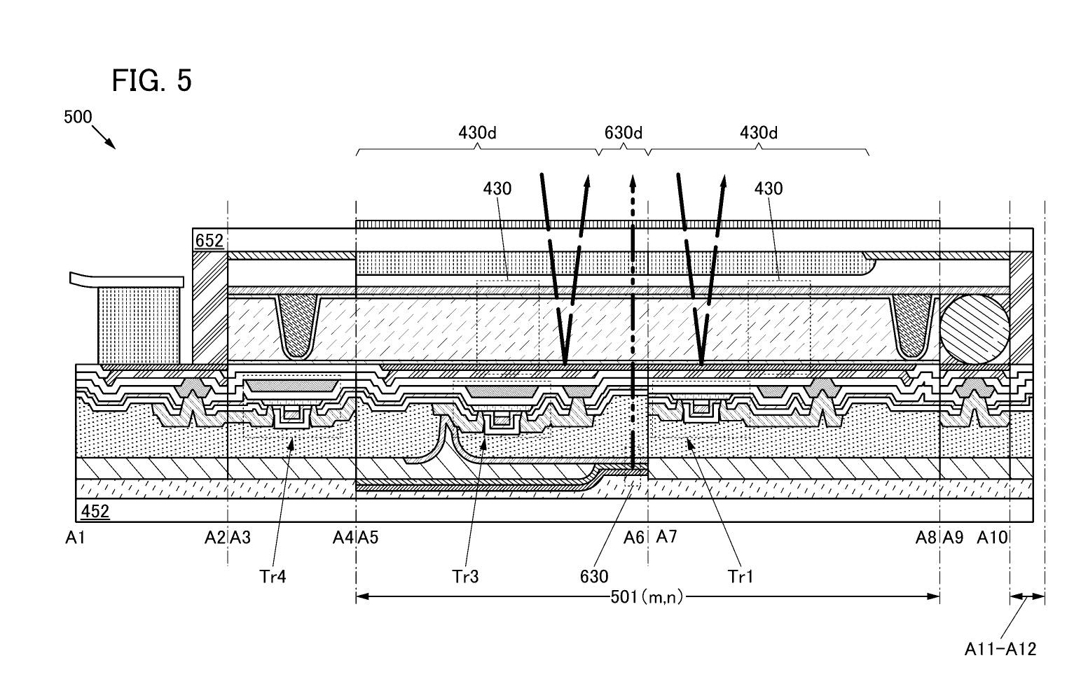

Next, a specific structure example of the display device 500 illustrated in FIG. 1 will be described with reference to FIGS. 4A and 4B and FIG. 5.

FIG. 4A is a top view of the display device 500. As described above, the display device 500 includes the pixel portion 502, the gate driver circuit portions 504a and 504b and the source driver circuit portion 506 placed outside the pixel portion 502. FIG. 4A schematically illustrates the pixel circuit 501 (m, n) included in the pixel portion 502. A flexible printed circuit (FPC) is electrically connected to the display device 500 in FIG. 4A.

FIG. 4B is a top view schematically illustrating the pixel circuit 501 (m, n) shown in FIG. 4A and the pixel circuit 501 (m, n+1) adjacent to the pixel circuit 501 (m, n). The signal lines S_{L}_{_}ₙ, S_{L}_{_}ₙ₊₁, S_{E}_{_}ₙ, and S_{E}_{_}ₙ₊₁, the scan lines G_{L}_{_}ₘ and G_{E}_{_}ₘ, the common line COMₘ, and the transistors Tr1, Tr2, and Tr3 in FIG. 4B respectively correspond to the reference numerals in FIG. 2. The display region 430d and the display region 630d in FIG. 4B correspond to the reference numerals in FIG. 3A. A common line COM_{—m+1} in FIG. 4B indicates a common line included in the pixel circuit 501 (m, n+1) adjacent to the pixel circuit 501 (m, n).

### <1-8. Structure Example of Display Device (Cross Section)>

Next, a cross-sectional structure of the display device 500 will be described with reference to FIG. 5.

FIG. 5 is a cross-sectional view corresponding to cross sections taken along the dashed-dotted lines A1-A2, A3-A4, A5-A6, A7-A8, A9-A10, and A11-A12 illustrated in FIGS. 4A and 4B.

A cross section taken along the dashed-dotted line A1-A2 corresponds to a region in which the FPC is attached to the display device 500. A cross section taken along the dashed-dotted line A3-A4 corresponds to a region in which the gate driver circuit portion 504a is provided. A cross section taken along the dashed-dotted line A5-A6 corresponds to a region in which the display element 430 and the display element 630 are provided. A cross section taken along the dashed-dotted line A7-A8 corresponds to a region in which the display element 430 is provided. A cross section taken along the dashed-dotted line A9-A10 corresponds to a connection region of the display device 500. A cross section taken along the dashed-dotted line A11-A12 corresponds to the edge of the display device 500 and the vicinity thereof.

In FIG. 5, the display device 500 includes the display element 430, the display element 630, the transistor Tr1, the transistor Tr3, and a transistor Tr4 between a substrate 452 and a substrate 652.

As described above, the display element 430 has a function of reflecting incident light and the display element 630 has a function of emitting light. In FIG. 5, the light entering the display element 430 and the reflected light are schematically denoted by arrows of dashed lines. Furthermore, the light emitted from the display element 630 is schematically denoted by an arrow of a dashed double-dotted line.

### [Pixel Circuit]

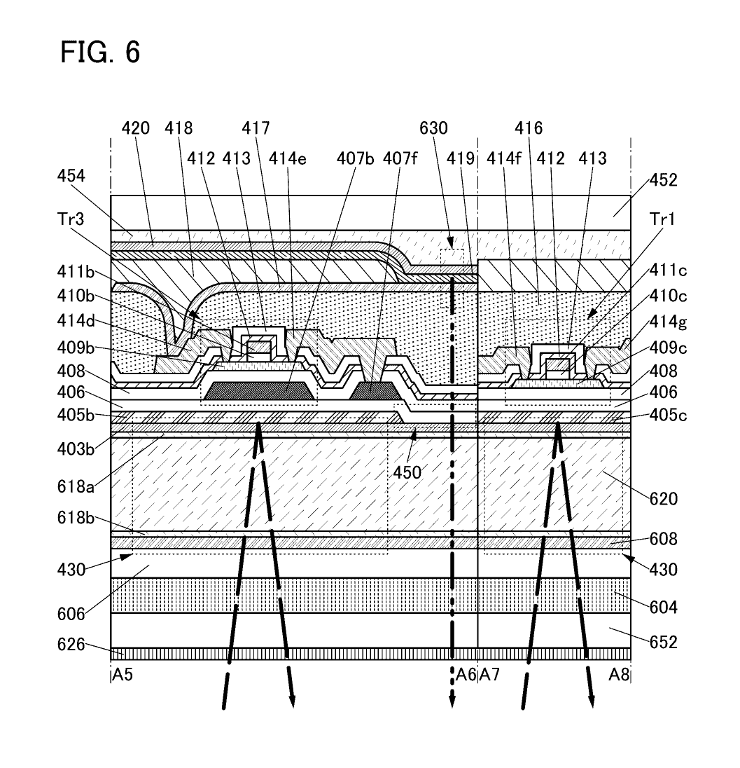

The cross sections taken along the dashed-dotted lines A5-A6 and A7-A8 in FIG. 5 are described with reference to FIG. 6. FIG. 6 corresponds to an enlarged cross-sectional view of some components taken along the dashed-dotted lines A5-A6 and A7-A8 in FIG. 5. Further, the enlarged cross-sectional view is reversed upside down. Note that in FIG. 6, some components are not illustrated in order to avoid complexity of the drawing.

The display element 430 includes a conductive film 403b, a liquid crystal layer 620, and a conductive film 608. The conductive film 403b functions as a pixel electrode and the conductive film 608 functions as a counter electrode. The conductive film 403b is electrically connected to the transistor Tr1.

The display element 430 includes conductive films 405b and 405c electrically connected to the conductive film 403b. The conductive films 405b and 405c each have a function of reflecting incident light. That is, the conductive films 405b and 405c function as reflective films. An opening 450 transmitting incident light is provided in the reflective films. In FIG. 6, a conductive film functioning as a reflective film is separated into island shapes by the opening 450, whereby the conductive film 405c is positioned below the transistor Tr1 and the conductive film 405b is positioned below the transistor Tr3. Since light of the display element 630 is emitted from the opening 450, the opening 450 corresponds to the display region 630d illustrated in FIG. 5.

The display element 630 has a function of emitting light toward the opening 450. In FIG. 6, the display element 630 is a bottom emission type light-emitting element.

The display element 630 includes a conductive film 417, an EL layer 419, and a conductive film 420. The conductive film 417 functions as a pixel electrode and an anode electrode. The conductive film 420 functions as a counter electrode and a cathode electrode. Although a description is made on a structure where the conductive film 417 functions as an anode electrode and the conductive film 420 functions as a cathode electrode in this embodiment, one embodiment of the present invention is not limited thereto. For example, the conductive film 417 may function as a cathode electrode and the conductive film 420 may function as an anode electrode.

The conductive film 417 is electrically connected to the transistor Tr3.

The transistors Tr1 and Tr3 each include an oxide semiconductor film. The conductive films 403b and 417 functioning as pixel electrodes each contain at least one metal element contained in the oxide semiconductor films included in the transistors Tr1 and Tr3.

For example, in the case where oxide semiconductor films are used in channel regions of the transistors Tr1 and Tr3 and oxide semiconductor films having the same composition as the oxide semiconductor films which are used in the channel regions are used in the conductive films 403b and 417 functioning as pixel electrodes, manufacturing cost can be reduced. As illustrated in FIG. 6, since a plurality of insulating films, conductive films, semiconductor films, or the like are necessary in a display device including a plurality of display elements and a plurality of transistors, it is important to use the same material in different processes.

Each of the transistors Tr1 and Tr3 preferably has a staggered (top-gate) structure as illustrated in FIG. 6. With the staggered transistors, parasitic capacitance between the gate electrode and each of the source electrode and the drain electrode can be reduced.

The transistor Tr1 is formed over an insulating film 406 and an insulating film 408 and includes an oxide semiconductor film 409c over the insulating film 408, an insulating film 410c over the oxide semiconductor film 409c, and an oxide semiconductor film 411c over the insulating film 410c. The insulating film 410c functions as a gate insulating film and the oxide semiconductor film 411c functions as a gate electrode.

Insulating films 412 and 413 are provided over the oxide semiconductor films 409c and 411c. An opening reaching the oxide semiconductor film 409c is provided in the insulating films 412 and 413 and conductive films 414f and 414g are electrically connected to the oxide semiconductor film 409c through the opening. The conductive films 414f and 414g function as a source electrode and a drain electrode of the transistor Tr1.

Insulating films 416 and 418 are provided over the transistor Tr1.

The transistor Tr3 is formed over the insulating film 406 and includes a conductive film 407b over the insulating film 406, the insulating film 408 over the conductive film 407b, an oxide semiconductor film 409b over the insulating film 408, an insulating film 410b over the oxide semiconductor film 409b, and an oxide semiconductor film 411b over the insulating film 410b. The conductive film 407b functions as a first gate electrode and the insulating film 408 functions as a first gate insulating film. The insulating film 410b functions as a second gate insulating film and the oxide semiconductor film 411b functions as a second gate electrode.

Insulating films 412 and 413 are provided over the oxide semiconductor films 409b and 411b. An opening reaching the oxide semiconductor film 409b is provided in the insulating films 412 and 413 and conductive films 414d and 414e are electrically connected to the oxide semiconductor film 409b through the opening. The conductive films 414d and 414e function as a source electrode and a drain electrode of the transistor Tr3.

A conductive film 414e is electrically connected to a conductive film 407f through an opening provided in the insulating films 406, 408, 412, and 413. The conductive film 407f is formed through the same process as that of the conductive film 407b and functions as a connection electrode.

The insulating film 416 and the conductive film 417 are provided over the transistor Tr3. An opening reaching the conductive film 414d is provided in the insulating film 416, and the conductive film 414d and the conductive film 417 are electrically connected to each other through the opening.

An insulating film 418, the EL layer 419, and the conductive film 420 are provided over the conductive film 417. An opening reaching the conductive film 417 is provided in the insulating film 418, and the conductive film 417 and the EL layer 419 are electrically connected to each other through the opening.

The conductive film 420 is adhered to the substrate 452 with a sealant 454 placed therebetween.

A coloring film 604, an insulating film 606, and the conductive film 608 are provided over the substrate 652 which faces the substrate 452. A functional film 626 is provided below the substrate 652. Light reflected by the display element 430 and light emitted from the display element 630 are extracted through the coloring film 604, the functional film 626, and the like.

The display element 430 includes alignment films 618a and 618b in contact with the liquid crystal layer 620 as illustrated in FIG. 6. Note that a structure without the alignment films 618a and 618b may be employed.

When the structures of the transistors Tr1 and Tr3 are made different from each other as illustrated in FIG. 6, the area of the circuit can be reduced. Specifically, the transistor Tr1 is a single-gate transistor in which the oxide semiconductor film 411c functioning as a gate electrode is provided, whereas the transistor Tr3 is a multi-gate transistor in which the conductive film 407b functioning as a first gate electrode and the oxide semiconductor film 411b functioning as a second gate electrode are provided. Note that there is no limitation on the structure of the transistor which is used in the display device of one embodiment of the present invention. For example, both transistors Tr1 and Tr3 may have either a single-gate structure or a multi-gate structure.

### [FPC and Gate Driver Circuit Portion]

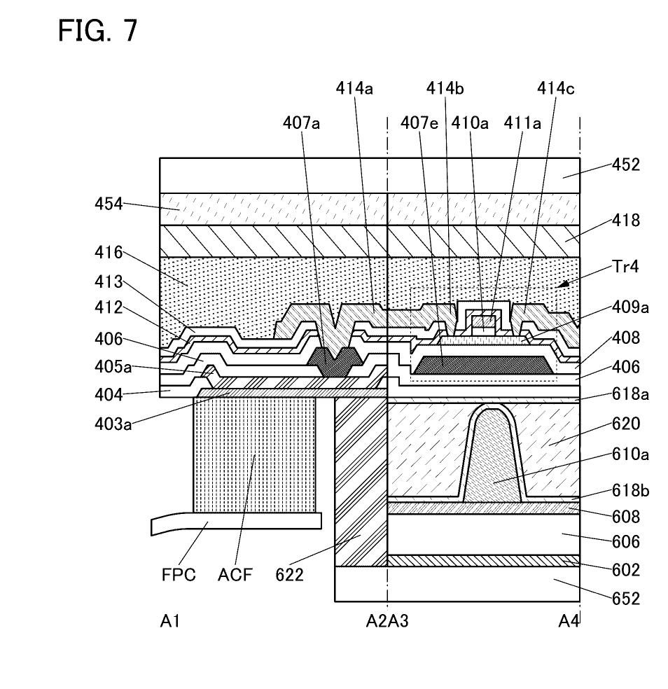

The cross-sections taken along the dashed-dotted line A1-A2 and the dashed-dotted line A3-A4 in FIG. 5 are described with reference to FIG. 7. FIG. 7 corresponds to an enlarged cross-sectional view of components taken along the dashed-dotted lines A1-A2 and A3-A4 in FIG. 5. Further, the enlarged cross-sectional view is reversed upside down. Note that in FIG. 7, some components are not illustrated in order to avoid complexity of the drawing.

The FPC illustrated in FIG. 7 is electrically connected to a conductive film 403a through an anisotropic conductive film (ACF). An insulating film 404 is provided over the conductive film 403a. An opening reaching the conductive film 403a is provided in the insulating film 404, and the conductive film 403a and a conductive film 405a are electrically connected to each other through the opening.

The insulating film 406 is provided over the conductive film 405a. An opening reaching the conductive film 405a is provided in the insulating film 406, and the conductive film 405a and a conductive film 407a are electrically connected to each other through the opening. The insulating films 408, 412, and 413 are provided over the conductive film 407a. An opening reaching the conductive film 407a is provided in the insulating films 408, 412, and 413 and the conductive film 407a and a conductive film 414a are electrically connected to each other through the opening.

The insulating films 416 and 418 are provided over the insulating film 413 and the conductive film 414a. The insulating film 418 is adhered to the substrate 452 with the sealant 454 placed therebetween.

The transistor Tr4 illustrated in FIG. 7 corresponds to a transistor included in the gate driver circuit portion 504a.

The transistor Tr4 is formed over the insulating film 406 and includes a conductive film 407e over the insulating film 406, the insulating film 408 over the conductive film 407e, an oxide semiconductor film 409a over the insulating film 408, an insulating film 410a over the oxide semiconductor film 409a, and an oxide semiconductor film 411a over the insulating film 410a. The conductive film 407e functions as a first gate electrode. The insulating film 410a functions as a second gate insulating film and the oxide semiconductor film 411a functions as a second gate electrode.

The insulating films 412 and 413 are provided over the oxide semiconductor films 409a and 411a. An opening reaching the oxide semiconductor film 409a is provided in the insulating films 412 and 413 and conductive films 414b and 414c are electrically connected to the oxide semiconductor film 409a through the opening. The conductive films 414b and 414c function as a source electrode and a drain electrode of the transistor Tr4.

The transistor Tr4 is a multi-gate transistor like the transistor Tr3 which is described above. A multi-gate transistor is preferably used in the gate driver circuit portion 504a because the current drive capability can be improved. Since the use of a multi-gate transistor can improve the current drive capability, the width of the driver circuit can be reduced.

The insulating films 416 and 418 are provided over the transistor Tr4. The insulating film 418 is adhered to the substrate 452 with the sealant 454 placed therebetween.

A light-blocking film 602, the insulating film 606, and the conductive film 608 are provided over the substrate 652 which faces the substrate 452.

A structure body 610a is formed in a position overlapping with the transistor Tr4 over the conductive film 608. The structure body 610a has a function of controlling the thickness of the liquid crystal layer 620. The alignment films 618a and 618b are formed between the structure body 610a and the insulating film 404 in FIG. 7. Note that the alignment films 618a and 618b are not necessarily formed between the structure body 610a and the insulating film 404.

A sealant 622 is provided at an end portion of the substrate 652. Note that the sealant 622 is provided between the substrate 652 and the conductive film 403a.

### [Connection Region and Region In the Vicinity of End Portion]

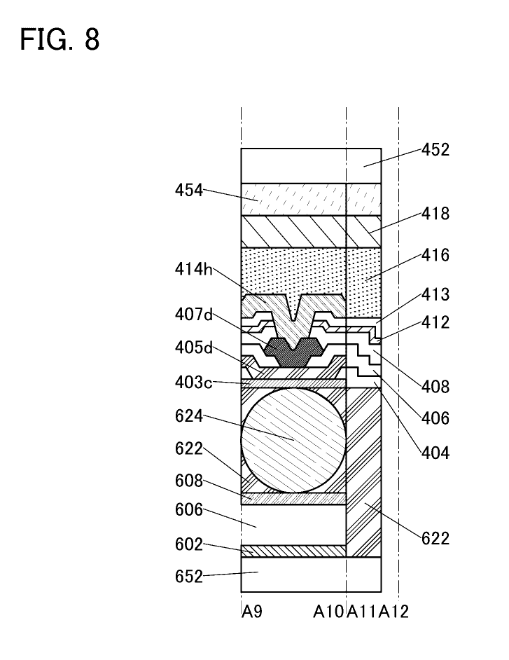

The cross sections taken along the dashed-dotted line A9-A10 and the dashed-dotted line A11-A12 in FIG. 5 are described with reference to FIG. 8. FIG. 8 corresponds to an enlarged cross-sectional view of components taken along the dashed-dotted lines A9-A10 and A11-A12 in FIG. 5. Further, the enlarged cross-sectional view is reversed upside down. Note that in FIG. 8, some components are not illustrated in order to avoid complexity of the drawing.

In FIG. 8, the conductive film 608 is electrically connected to a conductive film 403c via a conductor 624. The conductor 624 is included in the sealant 622. The conductive film 608 is provided over the substrate 652, the light-blocking film 602, and the insulating film 606.

The insulating film 404 is provided over the conductive film 403c. An opening reaching the conductive film 403c is provided in the insulating film 404, and the conductive film 403c and a conductive film 405d are electrically connected to each other through the opening. The insulating film 406 is provided over the conductive film 405d. An opening reaching the conductive film 405d is provided in the insulating film 406, and the conductive film 405d and a conductive film 407d are electrically connected to each other through the opening.

The insulating films 408, 412, and 413 are provided over the conductive film 407d. An opening reaching the conductive film 407d is provided in the insulating films 408, 412, and 413 and the conductive film 407d and a conductive film 414h are electrically connected to each other through the opening. The insulating films 416 and 418 are provided over the conductive film 414h. The insulating film 418 is adhered to the substrate 452 with the sealant 454 placed therebetween.

The sealant 622 is provided at end portions of the substrate 452 and 652. Note that the sealant 622 is provided between the substrate 652 and the insulating film 404.

### <1-9. Manufacturing Method of Display Device>

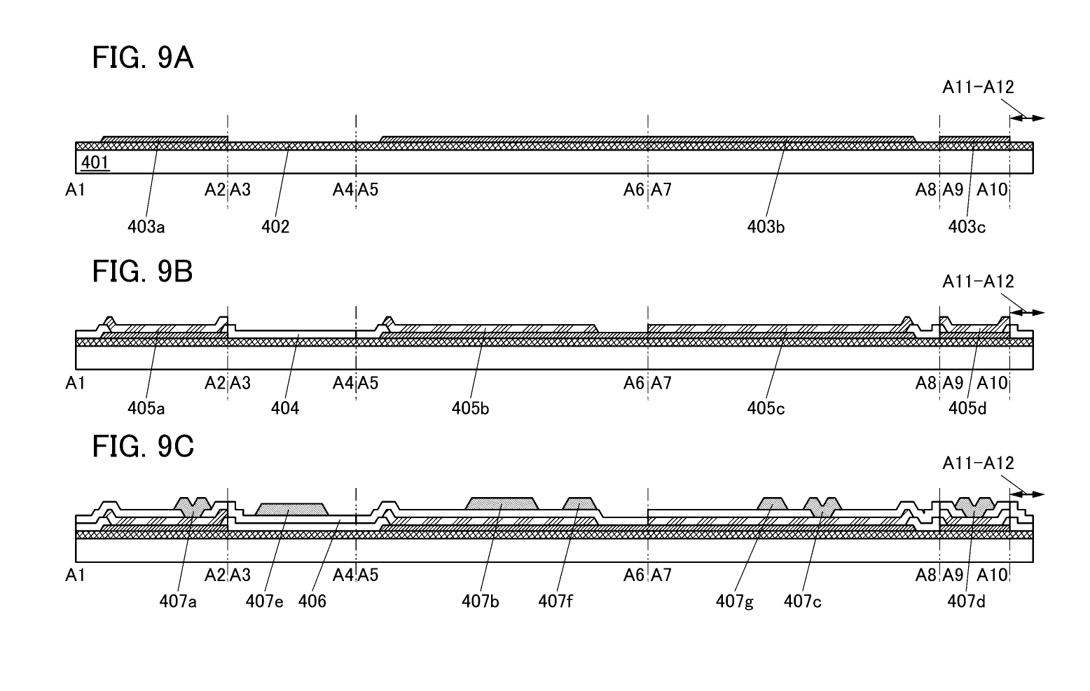

Next, a method for manufacturing the display device 500 illustrated in FIG. 5 is described with reference to FIGS. 9A to 9C, FIGS. 10A to 10C, FIGS. 11A to 11C, FIGS. 12A to 12C, FIGS. 13A and 13B, and FIG. 14. FIGS. 9A to 9C, FIGS. 10A to 10C, FIGS. 11A to 11C, FIGS. 12A to 12C, FIGS. 13A and 13B, and FIG. 14 are cross-sectional views illustrating a method for manufacturing the display device 500.

First, a conductive film 402 is formed over a substrate 401. Then, a conductive film is formed over the conductive film 402 and processed into island shapes, whereby the conductive films 403a, 403b, and 403c are formed (see FIG. 9A).

The conductive film 402 has a function of a separation layer, the conductive films 403a and 403c each have a function of a connection electrode, and the conductive film 403b has a function of a pixel electrode. In this embodiment, a tungsten film is used as the conductive film 402 and an In—Ga—Zn oxide is used as the conductive films 403a, 403b, and 403c. As the In—Ga—Zn oxide, an IGZO film (In:Ga:Zn=4:2:4.1 [atomic ratio]) is used.

An insulating film is formed over the conductive films 402, 403a, 403b, and 403c and openings are formed in desired regions of the insulating film, whereby the insulating film 404 is formed. Then, a conductive film is formed over the conductive films 403a, 403b, and 403c and the insulating film 404 and processed into island shapes, whereby the conductive films 405a, 405b, 405c, and 405d are formed (see FIG. 9B).

The insulating film 404 has openings in regions overlapping with the conductive films 403a, 403b, and 403c. The conductive film 403a is electrically connected to the conductive film 405a through the opening, the conductive film 403b is electrically connected to the conductive films 405b and 405c through the openings, and the conductive film 403c is electrically connected to the conductive film 405d through the opening. In this embodiment, a silicon oxynitride film is used as the insulating film 404 and alloy films of silver, palladium, and copper are used as the conductive films 405a, 405b, 405c, and 405d. Thus, metal films with high reflectivity (e.g., a film containing silver) are preferably used as the conductive films 405a, 405b, 405c, and 405d so that they can function as reflective films.

An insulating film is formed over the insulating film 404 and the conductive films 405a, 405b, 405c, and 405d and openings are formed in desired regions of the insulating film, whereby the insulating film 406 is formed. A conductive film is formed over the conductive films 405a, 405b, 405c, and 405d and the insulating film 406 and processed into island shapes, whereby the conductive films 407a, 407b, 407c, 407d, 407e, 407f, and 407g are formed (see FIG. 9C).

The insulating film 406 has openings in regions overlapping with the conductive films 405a, 405c, and 405d. Through the openings, the conductive film 405a, the conductive film 405c, and the conductive film 405d are electrically connected to the conductive film 407a, the conductive film 407c, and the conductive film 407d, respectively. In this embodiment, a silicon oxynitride film is used as the insulating film 406, and a stack of a tantalum nitride film and a copper film is used as each of the conductive films 407a, 407b, 407c, 407d, 407e, 407f, and 407g.

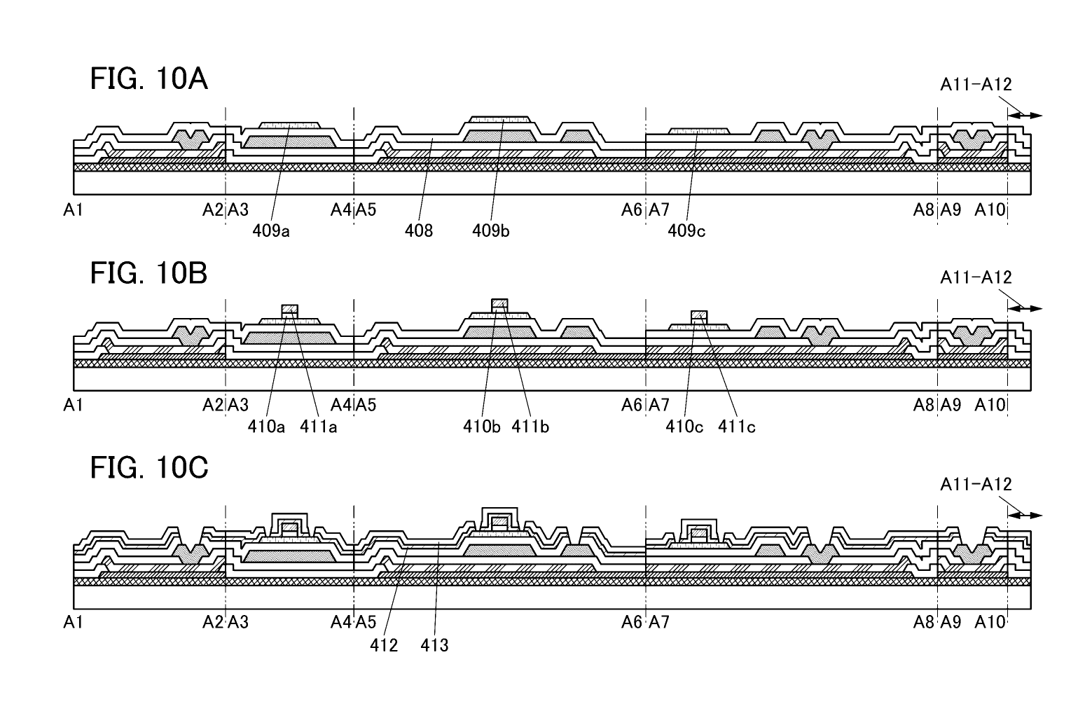

Next, the insulating film 408 is formed over the insulating film 406 and the conductive films 407a, 407b, 407c, 407d, 407e, 407f, and 407g. Then, an oxide semiconductor film is formed over the insulating film 408 and processed into island shapes, whereby the oxide semiconductor films 409a, 409b, and 409c are formed (see FIG. 10A).

In this embodiment, a silicon oxynitride film is used as the insulating film 408 and an In—Ga—Zn oxide is used for the oxide semiconductor films 409a, 409b, and 409c. The In—Ga—Zn oxide preferably has the same composition as the oxide semiconductor film used as the conductive films 403a, 403b, and 403c. When the oxide semiconductor film having the same composition is used as the oxide semiconductor films 409a, 409b, and 409c and the conductive films 403a, 403b, and 403c, the manufacturing cost can be reduced.

Next, an insulating film and an oxide semiconductor film are formed over the insulating film 408 and the oxide semiconductor films 409a, 409b, and 409c and processed into desired shapes, whereby the island-shaped insulating films 410a, 410b, and 410c and the island-shaped oxide semiconductor films 411a, 411b, and 411c are formed (see FIG. 10B).

In this embodiment, a silicon oxynitride film is used as the insulating films 410a, 410b, and 410c and an In—Ga—Zn oxide is used as oxide semiconductor films 411a, 411b, and 411c. The In—Ga—Zn oxide preferably has the same composition as the oxide semiconductor film used as the conductive films 403a, 403b, and 403c and the oxide semiconductor films 409a, 409b, and 409c. With use of the oxide semiconductor film having the same composition as the oxide semiconductor films 411a, 411b, and 411c, and oxide semiconductor films 409a, 409b, and 409c and the conductive films 403a, 403b, and 403c, the manufacturing cost can be reduced.

Next, insulating films are formed over the insulating film 408 and the oxide semiconductor films 409a, 409b, and 409c and openings are formed in desired regions of the insulating films, whereby the insulating films 412 and 413 are formed (see FIG. 10C).

Although a stacked-layer structure of two layers of the insulating films 412 and 413 is illustrated in FIG. 10C, the present invention is not limited thereto. For example, a single-layer structure of the insulating film 412, a single-layer structure of the insulating film 413, or a stacked-layer structure of three or more layers in which the insulating films 412 and 413 and another insulating film are stacked may be used. In this embodiment, a silicon nitride film is used as the insulating film 412 and a silicon nitride oxide film is used as the insulating film 413.

Openings are formed in part of the insulating film 408 when openings are formed in the insulating films 412 and 413. Openings formed in the insulating films 408, 412, and 413 reach the conductive films 407a, 407c, 407d, and 407f.

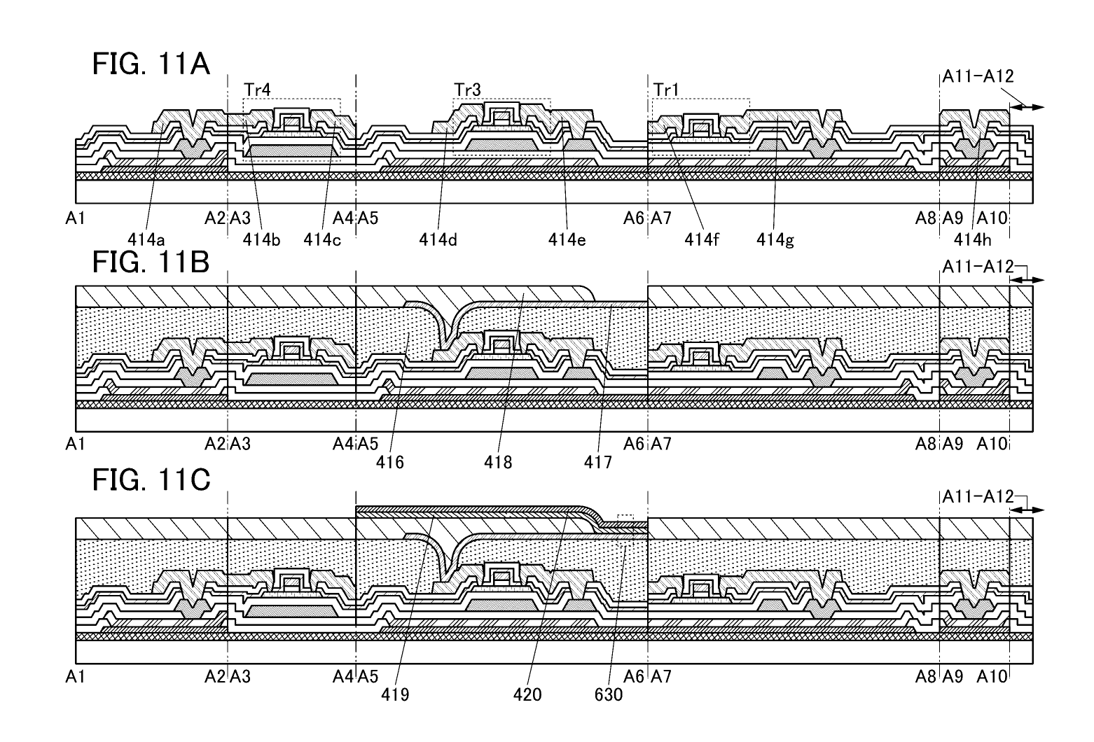

Next, a conductive film is formed over the insulating film 413 and processed into desired shapes, whereby the conductive films 414a, 414b, 414c, 414d, 414e, 414f, 414g, and 414h are formed (see FIG. 11A).

The conductive films 414b and 414c function as a source electrode and a drain electrode of the transistor Tr4. The conductive films 414d and 414e function as a source electrode and a drain electrode of the transistor Tr3. The conductive films 414f and 414g function as a source electrode and a drain electrode of the transistor Tr1.

In the transistor Tr1, the conductive film 414g is electrically connected to the conductive film 403b with the conductive films 407c and 405c placed therebetween. The transistor Tr1 can control the potential of the conductive film 403b.

In this embodiment, a stack of tantalum nitride and copper is preferably used as each of the conductive films 414a, 414b, 414c, 414d, 414e, 414f, 414g, and 414h. The conductive films 407a, 407b, 407c, 407d, 407e, 407f, and 407g are preferably formed using the same material as the conductive films 414a, 414b, 414c, 414d, 414e, 414f, 414g, and 414h because the manufacturing cost can be reduced. In the structure where the conductive film contains copper, a signal delay or the like can be suppressed even when a large substrate (e.g., an 8th generation mother glass (2160 mm×2460 mm), a 9th generation mother glass (2400 mm×2800 mm or 2450 mm×3050 mm), or a 10 th generation mother glass (2950 mm×3400 mm)) is used.

Next, the insulating film 416 is formed so as to cover the transistors Tr1, Tr3, and Tr4. The insulating film 416 has an opening in a region overlapping with the conductive film 414d. Next, a conductive film is formed over the insulating film 416 and the conductive film 414d and processed into a desired shape, whereby the conductive film 417 is formed. Then, the insulating film 418 is formed in a desired region over the insulating film 416 and the conductive film 417 (see FIG. 11B).

The insulating film 418 has an opening in a region overlapping with the conductive film 417. In this embodiment, an acrylic resin film is used as the insulating film 416, an In—Sn—Si oxide (also referred to as ITSO) is used as the conductive film 417, and a polyimide resin film is used as the insulating film 418.

Next, the EL layer 419 is formed over the conductive film 417 and the insulating film 418, and the conductive film 420 is formed over the EL layer 419 (see FIG. 11C).

The display element 630 is formed of the conductive film 417, the EL layer 419, and the conductive film 420. Note that the conductive film 417 functions as one of the pair of electrodes of the display element 630 and the conductive film 420 functions as the other of the pair of electrodes of the display element 630. Although not illustrated, the EL layer 419 is formed differently based on color elements (RGB). In this embodiment, a phosphorescent material is used for light-emitting layers of R and G, and a fluorescent material is used for a light-emitting layer of B. In this embodiment, an alloy film of silver and magnesium is used as the conductive film 420.

Through the above steps, an element formed over the substrate 401 can be fabricated.

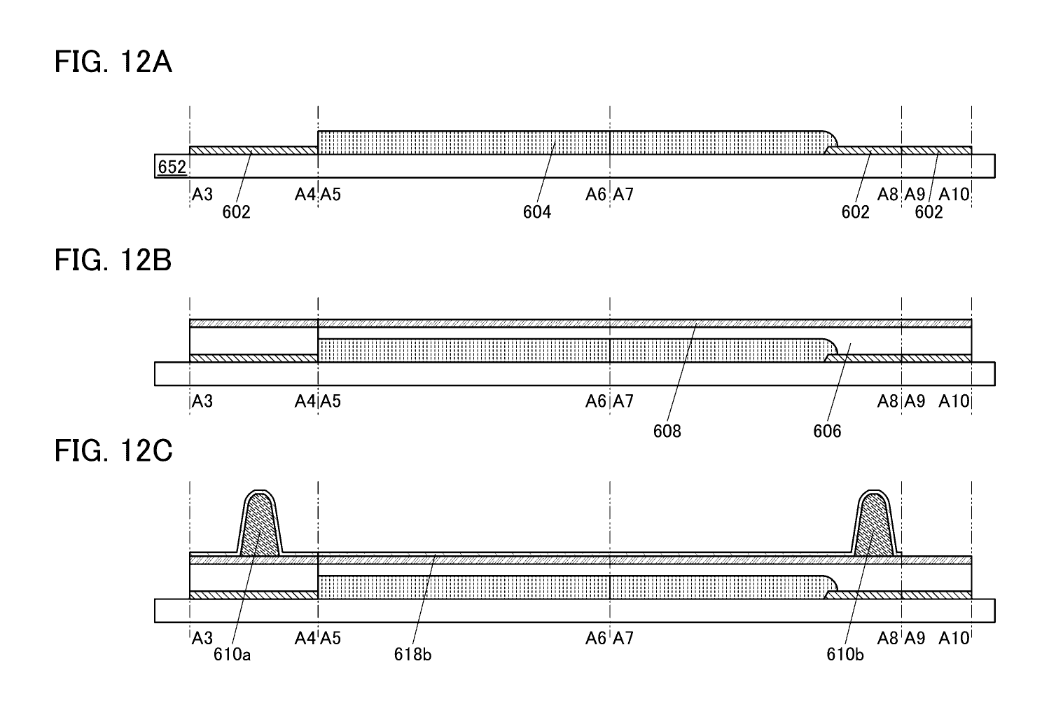

A method for manufacturing the substrate 652 placed to face the substrate 452 is described with reference to FIGS. 12A to 12C.

First, the light-blocking film 602 is formed over the substrate 652. After that, the coloring film 604 is formed over the substrate 652 and the light-blocking film 602 (see FIG. 12A).

In this embodiment, a titanium film is used as the light-blocking film 602 and an acrylic resin film containing pigment is used as the coloring film 604.

Next, the insulating film 606 is formed over the light-blocking film 602 and the coloring film 604. Then, the conductive film 608 is formed over the insulating film 606 (see FIG. 12B).

In this embodiment, an acrylic resin film is used as the insulating film 606 and an ITSO film is used as the conductive film 608.

Next, the structure bodies 610a and 610b are formed in desired regions over the conductive film 608. Then, the alignment film 618b is formed over the conductive film 608 and the structure bodies 610a and 610b (see FIG. 12C).

Note that a structure without the alignment film 618b may be employed. In this embodiment, acrylic resin films are used as the structure bodies 610a and 610b and a polyimide resin film is used as the alignment film 618b. Although the structure bodies 610a and 610b are formed over the substrate 652 in this embodiment, the present invention is not limited thereto. For example, the structure bodies 610a and 610b may be formed over the element which is formed over the substrate 401 described above.

Through the above steps, an element formed over the substrate 652 can be fabricated.

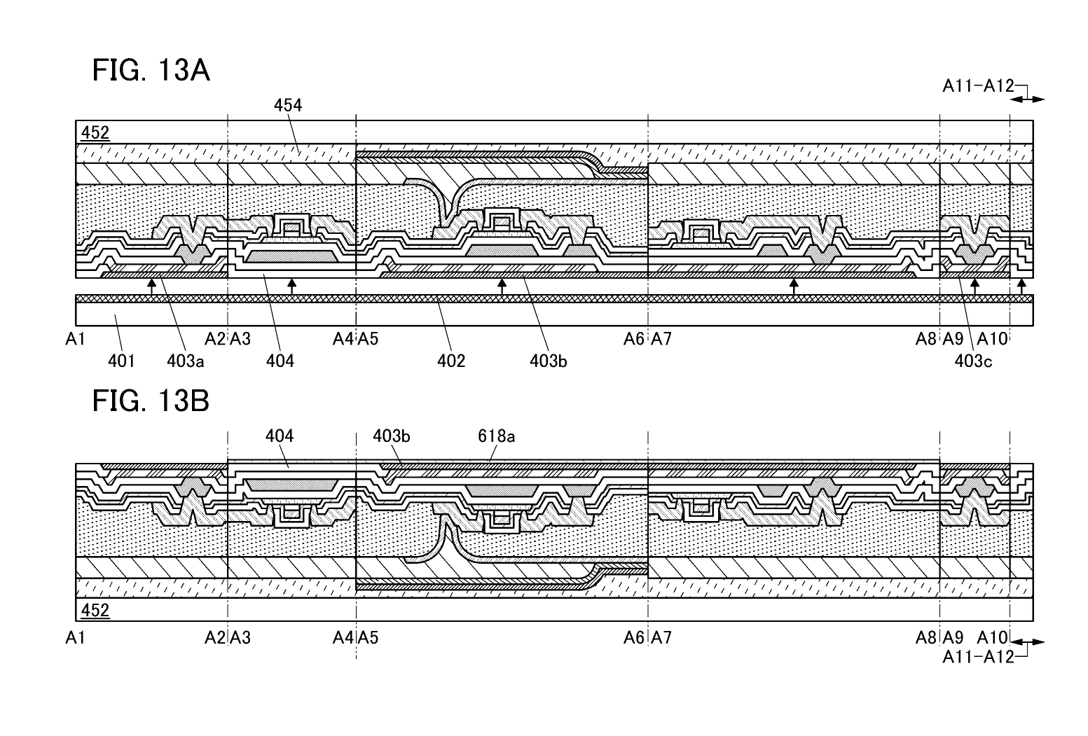

Next, the element formed over the substrate 401 is separated from the substrate 401. Specifically, separation is conducted at an interface between the conductive film 402 formed over the substrate 401 and the conductive films 403a, 403b, and 403c and the insulating film 404 which are formed over the conductive film 402. For the separation, the sealant 454 is formed over the element which is formed over the substrate 401. Then, the substrate 452 is attached to the sealant 454 and the element is separated from the interface between the element and the conductive film 402 (see FIG. 13A).

When the element is separated from the interface between the element and the conductive film 402, surfaces of the conductive films 403a, 403b, and 403c (rear surfaces of the conductive films 403a, 403b, and 403c in FIG. 13A) are exposed. In the case where an insulating film, a foreign substance, or the like is attached to the surfaces of the conductive films 403a, 403b, and 403c, the insulating film, the foreign substance, or the like is preferably removed by cleaning treatment, ashing treatment, etching treatment, or the like.

When the element is separated from the interface between the element and the conductive film 402, a polar solvent (typically water), a nonpolar solvent, or the like is preferably added to the interface between the conductive film 402 and the conductive films 403a, 403b, and 403c and the insulating film 404 which are formed over the conductive film 402. For example, it is preferable to use water in separating the element from the interface between the element and the conductive film 402 because damage caused by electrification in separation can be reduced.

As the conductive film 402, any of the following materials can be used. The conductive film 402 can have a single-layer structure or a stacked-layer structure containing an element selected from tungsten, molybdenum, titanium, tantalum, niobium, nickel, cobalt, zirconium, zinc, ruthenium, rhodium, palladium, osmium, iridium, and silicon; an alloy material containing any of the elements; or a compound material containing any of the elements. In the case of a layer containing silicon, a crystal structure of the layer containing silicon may be amorphous, microcrystal, polycrystal, or single crystal.

When the conductive film 402 is formed as a stacked layer structure including a layer which includes tungsten and a layer which includes an oxide of tungsten, the layer which includes tungsten may be formed and an insulating layer which includes an oxide may be formed thereover so that the layer which includes an oxide of tungsten is formed at the interface of the tungsten layer and the insulating layer. Alternatively, the layer containing an oxide of tungsten may be formed by performing thermal oxidation treatment, oxygen plasma treatment, dinitrogen monoxide (N₂O) plasma treatment, treatment with a highly oxidizing solution such as ozone water, or the like on the surface of the layer containing tungsten. Plasma treatment or heat treatment may be performed in an atmosphere of oxygen, nitrogen, or dinitrogen monoxide alone, or a mixed gas of any of these gasses and another gas. The surface condition of the conductive film 402 is changed by the plasma treatment or the heat treatment, whereby adhesion between the conductive film 402 and the conductive films 403a, 403b, and 403c and the insulating film 404 which are formed later can be controlled.

Although the structure where the conductive film 402 is provided is described in this embodiment, the present invention is not limited thereto. Note that a structure where the conductive film 402 is not provided may be employed. In that case, an organic resin film may be formed in a region in which the conductive film 402 is formed. As the organic resin film, for example, a polyimide resin film, a polyamide resin film, an acrylic resin film, an epoxy resin film, or a phenol resin film can be used.

In the case where the organic resin film is used instead of the conductive film 402, as a method for separating the element formed over the substrate 401, a laser light is irradiated from the lower side of the substrate 401 to weaken the organic resin film, whereby separation is conducted at an interface between the substrate 401 and the organic resin film or the interface between the organic resin film and the conductive films 403a, 403b, and 403c and the insulating film 404.

In the case where the laser light is irradiated, a region having strong adhesion and a region having weak adhesion are formed between the substrate 401 and the conductive films 403a, 403b, and 403c and the insulating film 404 by adjustment of the irradiation energy density of the laser light. After the region having strong adhesion and the region having weak adhesion are formed, only the region having weak adhesion may be separated.

Next, the element is reversed so that the substrate 452 is placed at the bottom, and the alignment film 618a is formed over the insulating film 404 and the conductive film 403b (see FIG. 13B).

For the alignment film 618a, a material similar to that of the alignment film 618b may be used.

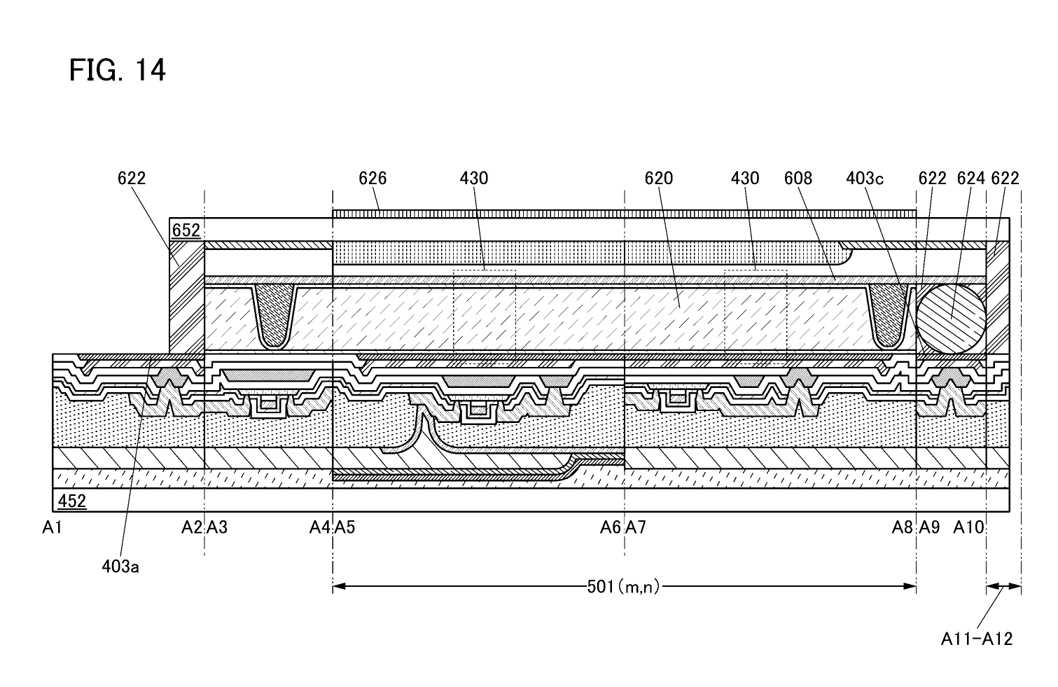

Next, an element over the substrate 452 and an element over the substrate 652 are attached to each other and sealed with the sealant 622. After that, the liquid crystal layer 620 is formed between the substrates 452 and 652, whereby the display element 430 is formed (see FIG. 14).

Note that the conductor 624 is provided in the sealant 622 over the conductive film 403c. As the conductor 624, conductive particles may be providedinto a desired region in the sealant 622 using a dispenser method or the like. The conductive film 403c and the conductive film 608 are electrically connected to each other via the conductor 624.

Next, the functional film 626 is formed over the substrate 652 (see FIG. 14).

Note that the functional film 626 is not necessarily formed.

After that, the FPC is bonded to the conductive film 403a with the ACF placed therebetween. Note that an anisotropic conductive paste (ACP) may be used instead of the ACF.

Through the above steps, the display device 500 illustrated in FIG. 5 can be manufactured.

### <1-10. Modification Example 1 of Display Device>

A touch panel may be provided in the display device 500 illustrated in FIG. 5. As the touch panel, a capacitive touch panel (a surface capacitive touch panel or a projected capacitive touch panel) can be preferably used.

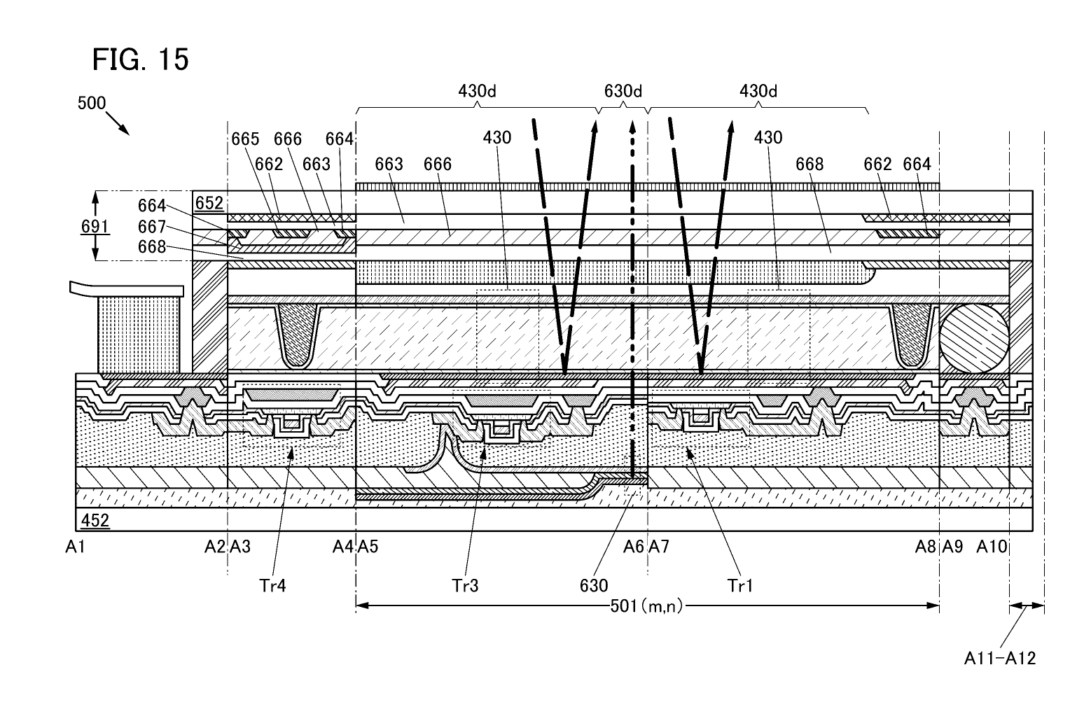

A structure in which a touch panel is provided in the display device 500 is described with reference to FIGS. 15, 16, and 17.

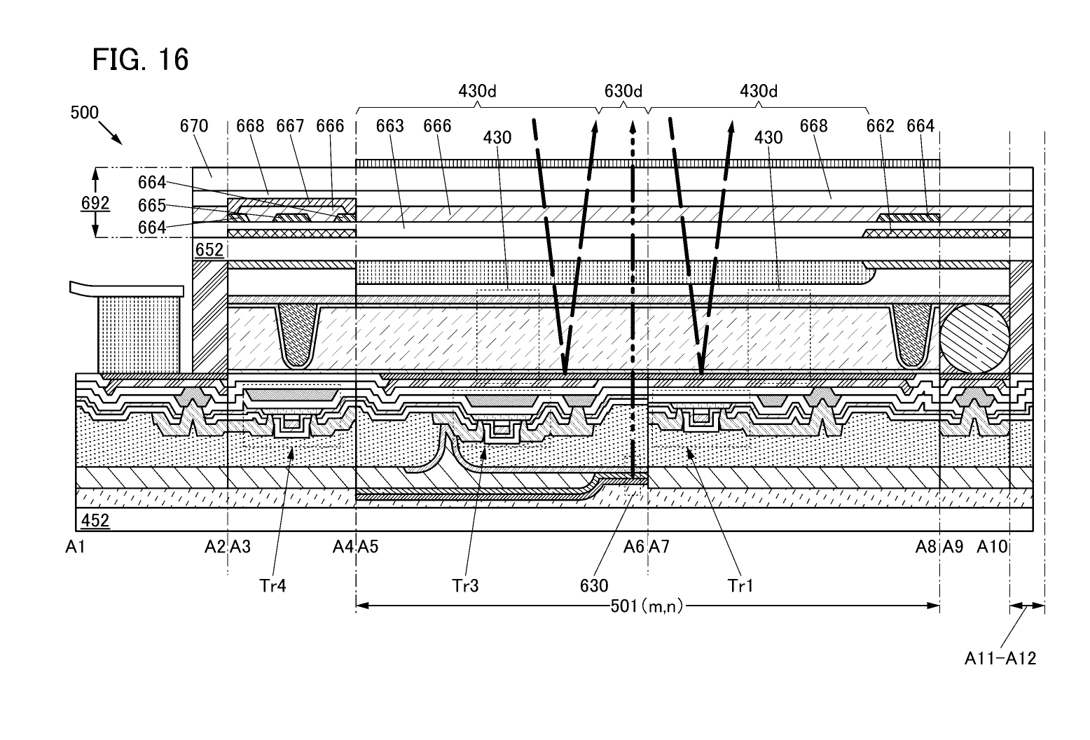

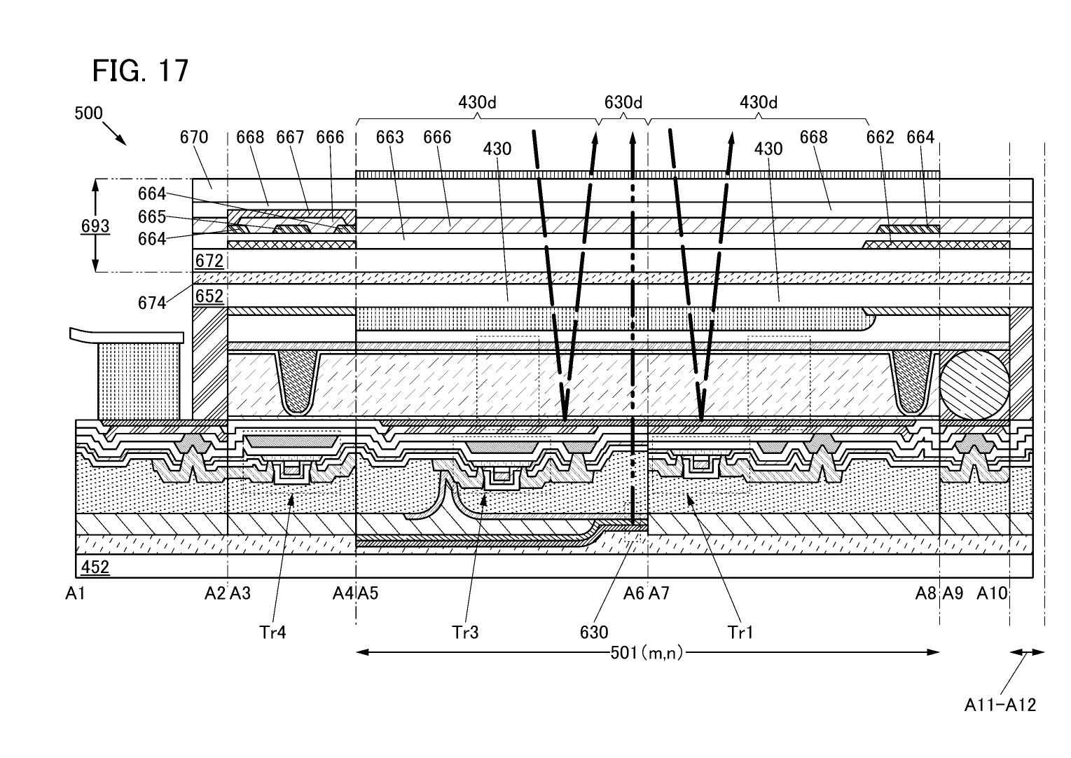

FIG. 15 is a cross-sectional view of a structure in which a touch panel 691 is provided in the display device 500. FIG. 16 is a cross-sectional view of a structure in which a touch panel 692 is provided in the display device 500. FIG. 17 is a cross-sectional view of a structure in which a touch panel 693 is provided in the display device 500.

The touch panel 691 illustrated in FIG. 15 is a so-called in-cell touch panel which is provided between the substrate 652 and the coloring film 604. The touch panel 691 is formed over the substrate 652 before the light-blocking film 602 and the coloring film 604 are formed.

The touch panel 691 includes a light-blocking film 662, an insulating film 663, a conductive film 664, a conductive film 665, an insulating film 666, a conductive film 667, and an insulating film 668. Changes in the mutual capacitance in the conductive films 664 and 665 can be detected when an object such as a finger or a stylus approaches, for example.

An intersection portion of the conductive film 664 and the conductive film 665 is shown above the transistor Tr4 illustrated in FIG. 15. The conductive film 667 is electrically connected to the two conductive films 664 between which the conductive film 665 is sandwiched through openings provided in the insulating film 666. Although a region in which the conductive film 667 is provided is located in a region corresponding to the gate driver circuit portion 504a in FIG. 15, it is not limited thereto, and the region in which the conductive film 667 is provided may be provided in a region in which the pixel circuit 501 (m, n) is provided, for example.

The conductive films 664 and 665 are provided in a region overlapping with the light-blocking film 662. As illustrated in FIG. 15, it is preferable that the conductive film 664 do not overlap with the display element 630. In other words, the conductive film 664 has openings in regions overlapping with the display element 630. That is, the conductive film 664 has a mesh shape. With this structure, the conductive film 664 does not block light emitted from the display element 630. Therefore, since luminance is hardly reduced even when the touch panel 691 is provided, a display device with high visibility and low power consumption can be obtained. Note that the conductive film 665 can have a structure similar to that of the conductive film 664.

Since the conductive films 664 and 665 do not overlap with the display element 630, a metal material whose transmittance of visible light is low can be used for the conductive films 664 and 665. Therefore, as compared to the case of using an oxide material whose transmittance of visible light is high, resistance of the conductive films 664 and 665 can be reduced, whereby sensitivity of the sensor of the touch panel can be increased.

Note that a material that can be used for the light-blocking film 602 described later can be used for the light-blocking film 662. For the insulating films 663, 666, and 668, a material that can be used for the insulating films 404, 406, 408, 410a, 410b, 410c, 412, 413, 416, 418, and 606 described later can be used. For the conductive films 664, 665, and 667, a material that can be used for the conductive films 402, 403a, 403b, 403c, 405a, 405b, 405c, 405d, 407a, 407b, 407c, 407d, 407e, 414a, 414b, 414c, 414d, 414e, 414f, 414g, 414h, 417, 420, and 608 and the oxide semiconductor films 411a, 411b, and 411c described later can be used.

Conductive nanowires may be used for the conductive films 664, 665, and 667. The nanowires may have a mean diameter of greater than or equal to 1 nm and less than or equal to 100 nm, preferably greater than or equal to 5 nm and less than or equal to 50 nm, further preferably greater than or equal to 5 nm and less than or equal to 25 nm. As the nanowire, a carbon nanotube or a metal nanowire such as an Ag nanowire, a Cu nanowire, or an Al nanowire may be used. For example, in the case of using an Ag nanowire for one or all of the conductive films 664, 665, and 667, a visible light transmittance of 89% or more and a sheet resistance of 40 Ω/square or more and 100 Ω/square or less can be achieved.

The touch panel 692 illustrated in FIG. 16 is a so-called on-cell touch panel which is provided above the substrate 652. The touch panel 692 has a similar structure to that of the touch panel 691.

The touch panel 693 illustrated in FIG. 17 is provided over a substrate 672 and is bonded to the substrate 652 with an adhesive agent 674. The touch panel 693 is a so-called out-cell touch panel (also referred to as an externally attached touch panel). The touch panel 693 has a structure similar to that of the touch panel 691. In this manner, the display device of one embodiment of the present invention can be combined with various types of touch panels.

### <1-11. Modification Example 2 of Display Device>

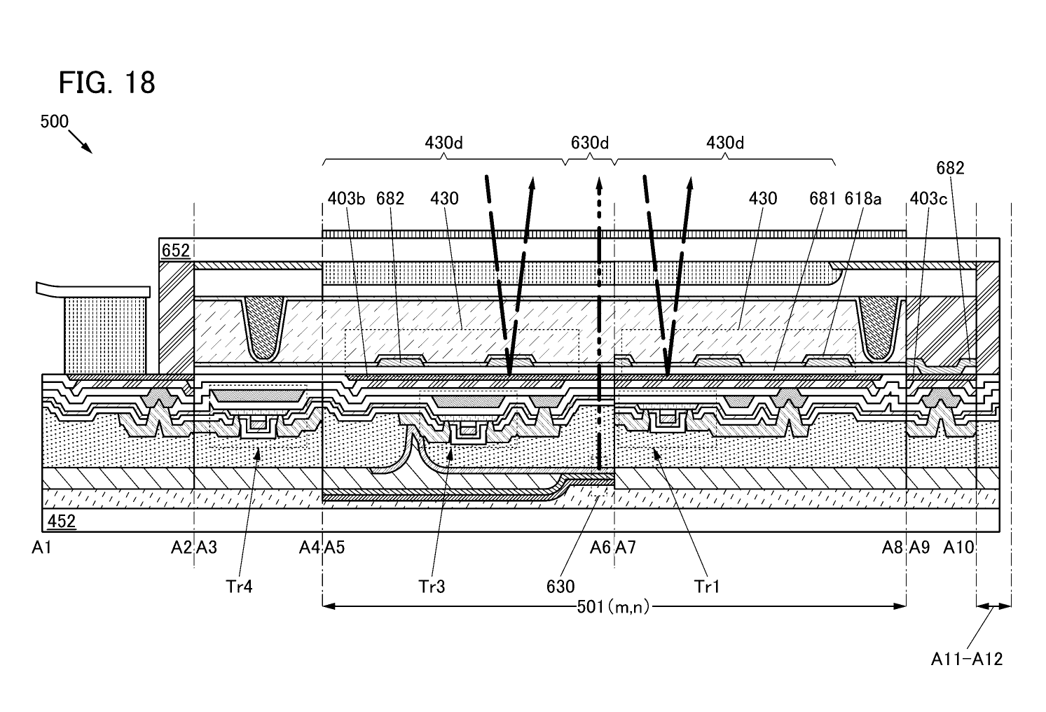

An example of a structure where the liquid crystal element of the display device 500 illustrated in FIG. 5 is a horizontal electric field mode liquid crystal element, (here, an FFS mode liquid crystal element) is shown in FIG. 18.

The display device 500 illustrated in FIG. 18 includes an insulating film 681 over the conductive films 403b and 403c and a conductive film 682 over the insulating film 681 in addition to the above-mentioned components.

The insulating film 681 has an opening in a connection region taken along the dashed-dotted line A9-A10, and the conductive film 682 is electrically connected to the conductive film 403c through the opening. In FIG. 18, the conductor 624 included in the sealant 622 in FIG. 14 is not provided.

The conductive film 682 functions as a common electrode. The conductive film 682 may have a comb-like shape or a shape having a slit when seen from the above. Since the conductive film 682 is provided in the display device 500 illustrated in FIG. 18, the conductive film 608 provided on the substrate 652 side in FIG. 14 is not provided. Note that the conductive film 682 may be provided and the conductive film 608 may be further provided on the substrate 652 side.

For the insulating film 681, a material that can be used for the insulating films 404, 406, 408, 410a, 410b, 410c, 412, 413, 416, 418, and 606 described later can be used. For the conductive film 682, a material that can be used for the conductive film 402, 403a, 403b, 403c, 405a, 405b, 405c, 405d, 407a, 407b, 407c, 407d, 407e, 411a, 411b, 411c, 414d, 414e, 414f, 414g, 414h, 417, 420, and 608 and the oxide semiconductor films 411a, 411b, and 411c described later can be used.

When the conductive film 682 is formed using a light-transmitting material, a light-transmitting capacitor can be formed. The light-transmitting capacitor includes the conductive film 682, the insulating film 681 overlapping with the conductive film 682, and the conductive film 403c. This structure is preferable because the amount of charge accumulated in the capacitor can be increased.

### <1-12. Components of Display Device>

Next, the components of the display device 500 and the manufacturing method thereof illustrated in FIG. 5 to FIG. 14 are described below.

### [Substrate]

The substrates 401, 452, and 652 can be formed using a material having heat resistance high enough to withstand heat treatment in the manufacturing process.

Specifically, non-alkali glass, soda-lime glass, potash glass, crystal glass, quartz, sapphire, or the like can be used. Alternatively, an inorganic insulating film may be used. Examples of the inorganic insulating film include a silicon oxide film, a silicon nitride film, a silicon oxynitride film, and an alumina film.

The non-alkali glass preferably has a thickness of greater than or equal to 0.2 nm and less than or equal to 0.7 mm, for example. The non-alkali glass may be polished to obtain the above thickness.

For example, a large-sized glass substrate having any of the following sizes can be used as each of the substrates 401, 452, and 652: the 6th generation (1500 mm×1850 mm), the 7th generation (1870 mm×2200 mm), the 8th generation (2200 mm×2400 mm), the 9th generation (2400 mm×2800 mm), and the 10 th generation (2950 mm×3400 mm). Thus, a large-sized display device can be manufactured.

Alternatively, as the substrates 401, 452, and 652, a single crystal semiconductor substrate or a polycrystalline semiconductor substrate made of silicon or silicon carbide, a compound semiconductor substrate made of silicon germanium or the like, an SOI substrate, or the like may be used.

Alternatively, for the substrates 401, 452, and 652, an inorganic material such as a metal may be used. Examples of the inorganic material such as a metal include stainless steel or aluminum.

Alternatively, for the substrates 401, 452, and 652, an organic material such as a resin, a resin film, or plastic may be used. Examples of the resin film include polyester, polyolefin, polyamide (e.g., nylon or aramid), polyimide, polycarbonate, polyurethane, an acrylic resin, an epoxy resin, polyethylene terephthalate (PET), polyethylene naphthalate (PEN), polyether sulfone (PES), and a resin having a siloxane bond.

Alternatively, for the substrates 401, 452, and 652, a composite material of a combination of an inorganic material and an organic material may be used. Examples of the composite material include a resin film to which a metal plate or a thin glass plate is bonded, a resin film into which a fibrous or particulate metal or a fibrous or particulate glass is dispersed, and an inorganic material into which a fibrous or particulate resin is dispersed.

### [Conductive Film]

A metal film having conductivity, a conductive film having a function of reflecting visible light, or a conductive film having a function of transmitting visible light may be used as the conductive films 402, 403a, 403b, 403c, 405a, 405b, 405c, 405d, 407a, 407b, 407c, 407d, 407e, 414a, 414b, 414c, 414d, 414e, 414f, 414g, 414h, 417, 420, and 608 and the oxide semiconductor films 411a, 411b, and 411c.

A material containing a metal element selected from aluminum, gold, platinum, silver, copper, chromium, tantalum, titanium, molybdenum, tungsten, nickel, iron, cobalt, palladium, and manganese can be used for the metal film having conductivity. Alternatively, an alloy containing any of the above metal elements may be used.

For the metal film having conductivity, specifically a two-layer structure in which a copper film is stacked over a titanium film, a two-layer structure in which a copper film is stacked over a titanium nitride film, a two-layer structure in which a copper film is stacked over a tantalum nitride film, or a three-layer structure in which a titanium film, a copper film, and a titanium film are stacked in this order may be used. In particular, a conductive film containing a copper element is preferably used because the resistance can be reduced. As an example of the conductive film containing a copper element, an alloy film containing copper and manganese is given. The alloy film is preferable because it can be processed by a wet etching method.

As the metal film having conductivity, a conductive macromolecule or a conductive polymer may be used.

For the conductive film having a function of reflecting visible light, a material containing a metal element selected from gold, silver, copper, and palladium can be used. In particular, a conductive film containing a silver element is preferably used because reflectance of visible light can be improved.

For the conductive film having a function of transmitting visible light, a material containing an element selected from indium, tin, zinc, gallium, and silicon can be used. Specifically, an In oxide, a Zn oxide, an In—Sn oxide (also referred to as ITO), an In—Sn—Si oxide (also referred to as ITSO), an In—Zn oxide, an In—Ga—Zn oxide, or the like can be used.

As the conductive film having a function of transmitting visible light, a film containing graphene or graphite may be used. The film containing graphene can be formed in the following manner: a film containing graphene oxide is formed and is reduced. As a reducing method, a method with application of heat, a method using a reducing agent, or the like can be employed.

Note that the conductive films 403c and 417 each having a function of a pixel electrode contain at least one metal element contained in the oxide semiconductor films 409a, 409b, and 409c. For example, in the case where the oxide semiconductor films 409a, 409b, and 409c include a metal oxide such as an In—M—Zn oxide (M is Al, Ga, Y, or Sn), the conductive film 403c and the conductive film 417 each contain any one of In, M (M is Al, Ga, Y, or Sn), and Zn.

### [Insulating Film]

For the insulating films 404, 406, 408, 410a, 410b, 410c, 412, 413, 416, 418, and 606, an inorganic insulating material, an organic insulating material, or an insulating composite material including an insulating inorganic material and an insulating organic material can be used.

Examples of the insulating inorganic material include a silicon oxide film, a silicon nitride film, a silicon oxynitride film, a silicon nitride oxide film, and an aluminum oxide film. Alternatively, a plurality of the above inorganic materials may be stacked.

As the above insulating organic material, for example, materials that include polyester, polyolefin, polyamide (e.g., nylon or aramid), polyimide, polycarbonate, polyurethane, an acrylic resin, an epoxy resin, or a resin having a siloxane bond can be used. As the insulating organic material, a photosensitive material may be used.

### [Oxide Semiconductor Film]

The oxide semiconductor films 409a, 409b, and 409c are formed using a metal oxide such as an In—M—Zn oxide (M is Al, Ga, Y, or Sn). Alternatively, an In—Ga oxide or an In—Zn oxide may be used for the oxide semiconductor films 409a, 409b, and 409c.

In the case where the oxide semiconductor films 409a, 409b, and 409c include an In—M—Zn oxide, the proportions of In and M, the summation of which is assumed to be 100 atomic %, are as follows: the proportion of In is higher than 25 atomic % and the proportion of M is lower than 75 atomic %, or the proportion of In is higher than 34 atomic % and the proportion of M is lower than 66 atomic %.

The energy gap of the oxide semiconductor films 409a, 409b, and 409c is preferably 2 eV or more, 2.5 eV or more, or 3 eV or more.

The thickness of the oxide semiconductor films 409a, 409b, and 409c is greater than or equal to 3 nm and less than or equal to 200 nm, preferably greater than or equal to 3 nm and less than or equal to 100 nm, further preferably greater than or equal to 3 nm and less than or equal to 60 nm.

In the case where the oxide semiconductor films 409a, 409b, and 409c include an In—M—Zn oxide, the atomic ratio of metal elements in a sputtering target used for depositing the In—M—Zn oxide preferably satisfies In≧M and Zn≧M. As the atomic ratio of metal elements in such a sputtering target, In:M:Zn=1:1:1, In:M:Zn=1:1:1.2, In:M:Zn=2:1:1.5, In:M:Zn=2:1:2.3, In:M:Zn=2:1:3, In:M:Zn=3:1:2, In:M:Zn=4:2:4.1, In:M:Zn=5:1:7, or the like is preferable. Note that the atomic ratio of metal elements in the deposited oxide semiconductor film 108 may vary from the above atomic ratio of metal elements in the sputtering target within a range of approximately ±40%. For example, when a sputtering target whose atomic ratio of In to Ga and Zn is 4:2:4.1 is used, the atomic ratio of In to Ga and Zn in the deposited oxide semiconductor film may be approximately 4:2:3. In the case where a sputtering target whose atomic ratio of In to Ga and Zn is 5:1:7 is used, the atomic ratio of In to Ga and Zn in the deposited oxide semiconductor film may be approximately 5:1:6.

When contained in the oxide semiconductor films 409a, 409b, and 409c, silicon or carbon, which are elements belonging to Group 14, may cause oxygen vacancies to be increased and the oxide semiconductor film to have n-type conductivity. Thus, the concentration of silicon or carbon in the oxide semiconductor film 108, particularly in the channel region 108i, is set to be lower than or equal to 2×10¹⁸ atoms/cm³ or lower than or equal to 2×10¹⁷ atoms/cm³. As a result, the transistor has a positive threshold voltage (normally-off characteristics). Note that the concentration of silicon or carbon can be measured by secondary ion mass spectrometry (SIMS), for example.

Furthermore, the concentration of alkali metal or alkaline earth metal in the oxide semiconductor films 409a, 409b, and 409c, which is measured by SIMS, can be lower than or equal to 1×10¹⁸ atoms/cm³ or lower than or equal to 2×10¹⁶ atoms/cm³. Alkali metal and alkaline earth metal might generate carriers when bonded to an oxide semiconductor, in which case the off-state current of the transistor might be increased. Therefore, it is preferable to reduce the concentration of alkali metal or alkaline earth metal in the oxide semiconductor films 409a, 409b, and 409c. As a result, the transistor has a positive threshold voltage (normally-off characteristics).

Furthermore, when contained in the oxide semiconductor films 409a, 409b, and 409c, nitrogen may generate electrons serving as carriers and cause carrier density to be increased and the oxide semiconductor films 409a, 409b, and 409c to have n-type conductivity. Thus, a transistor including an oxide semiconductor film which contains nitrogen is likely to have normally-on characteristics. For this reason, nitrogen in the oxide semiconductor films 409a, 409b, and 409c is preferably reduced as much as possible. For example, the nitrogen concentration measured by SIMS may be 5×10¹⁸ atoms/cm³ or lower.

When the impurity elements in the oxide semiconductor films 409a, 409b, and 409c are reduced, the carrier density of the oxide semiconductor films can be lowered. Therefore, the oxide semiconductor films 409a, 409b, and 409c can have a carrier density less than or equal to 1×10¹⁷ cm⁻³, less than or equal to 1×10¹⁵ cm⁻³, less than or equal to 1×10¹³ cm⁻³, or less than or equal to 1×10¹¹ cm⁻³.

When an oxide semiconductor film with a low impurity concentration and a low density of defect states is used as the oxide semiconductor films 409a, 409b, and 409c, the transistor can have more excellent electrical characteristics. Here, the state in which the impurity concentration is low and the density of defect states is low (the number of oxygen vacancies is small) is referred to as “highly purified intrinsic”, “substantially highly purified intrinsic”, “intrinsic”, or “substantially intrinsic”. A highly purified intrinsic or substantially highly purified intrinsic oxide semiconductor has few carrier generation sources and thus can have a low carrier density in some cases. Thus, a transistor whose channel region is formed in the oxide semiconductor film is likely to have a positive threshold voltage (normally-off characteristics). The highly purified intrinsic or substantially highly purified intrinsic oxide semiconductor film has a low density of defect states and accordingly has a low density of trap states in some cases. Furthermore, the highly purified intrinsic or substantially highly purified intrinsic oxide semiconductor film enables extremely low off-state current. Thus, the transistor whose channel region is formed in the oxide semiconductor film has little variation in electrical characteristics and high reliability in some cases.

Each of the oxide semiconductor films 409a, 409b, and 409c may have a non-single-crystal structure. The non-single-crystal structure includes a c-axis aligned crystalline oxide semiconductor (CAAC-OS) described later, a polycrystalline structure, a microcrystalline structure described later, or an amorphous structure, for example. Among the non-single-crystal structures, the amorphous structure has the highest density of defect states, whereas the CAAC-OS has the lowest density of defect states.

Note that each of the oxide semiconductor films 409a, 409b, and 409c may be a single film or stacked films including two or more of the following regions: a region having an amorphous structure, a region having a microcrystalline structure, a region having a polycrystalline structure, a CAAC-OS region, and a region having a single-crystal structure.

### [Liquid Crystal Layer]

As examples of the liquid crystal layer 620, thermotropic liquid crystal, low-molecular liquid crystal, high-molecular liquid crystal, polymer dispersed liquid crystal, ferroelectric liquid crystal, and anti-ferroelectric liquid crystal can be given. Alternatively, a liquid crystal material which exhibits a cholesteric phase, a smectic phase, a cubic phase, a chiral nematic phase, an isotropic phase, or the like may be used. Further, a liquid crystal material exhibiting a blue phase may be used.

For a driving method of the liquid crystal layer 620, an in-plane switching (IPS) mode, a twisted nematic (TN) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, or the like can be used. In addition, the liquid crystal layer 620 can be driven by, for example, a vertical alignment (VA) mode such as a multi-domain vertical alignment (MVA) mode, a patterned vertical alignment (PVA) mode, an electrically controlled birefringence (ECB) mode, a continuous pinwheel alignment (CPA) mode, or an advanced super view (ASV) mode can be used.

### [EL Layer]

The EL layer 419 includes at least a light-emitting material. Examples of the light-emitting material include an organic compound and an inorganic compound such as a quantum dot.

The organic compound and the inorganic compound can be formed by an evaporation method (including a vacuum evaporation method), an ink-jet method, a coating method, gravure printing, or the like, for example.

Examples of materials that can be used for the organic compound include a fluorescent material and a phosphorescent material. A fluorescent material is preferably used in terms of the lifetime, while a fluorescent material is preferably used in terms of the efficiency. Furthermore, both of a phosphorescent material and a phosphorescent material may be used.

A quantum dot is a semiconductor nanocrystal with a size of several nanometers and contains approximately 1×10³ to 1×10⁶ atoms. Since energy shift of quantum dots depend on their size, quantum dots made of the same substance emit light with different wavelengths depending on their size; thus, emission wavelengths can be easily adjusted by changing the size of quantum dots.

Since a quantum dot has an emission spectrum with a narrow peak, emission with high color purity can be obtained. In addition, a quantum dot is said to have a theoretical internal quantum efficiency of approximately 100%, which far exceeds that of a fluorescent organic compound, i.e., 25%, and is comparable to that of a phosphorescent organic compound. Therefore, a quantum dot can be used as a light-emitting material to obtain a light-emitting element having high light-emitting efficiency. Furthermore, since a quantum dot which is an inorganic compound has high inherent stability, a light-emitting element which is favorable also in terms of lifetime can be obtained.

Examples of a material of a quantum dot include a Group 14 element in the periodic table, a Group 15 element in the periodic table, a Group 16 element in the periodic table, a compound of a plurality of Group 14 elements in the period table, a compound of an element belonging to any of Groups 4 to 14 in the periodic table and a Group 16 element in the period table, a compound of a Group 2 element in the periodic table and a Group 16 element in the period table, a compound of a Group 13 element in the period table and a Group 15 element in the period table, a compound of a Group 13 element in the period table and a Group 17 element in the period table, a compound of a Group 14 element in the period table and a Group 15 element in the period table, a compound of a Group 11 element in the period table and a Group 17 element in the period table, iron oxides, titanium oxides, spinel chalcogenides, and semiconductor clusters.

Specific examples include, but are not limited to, cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; triiron tetraoxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and combinations thereof. What is called an alloyed quantum dot, whose composition is represented by a given ratio, may be used. For example, an alloyed quantum dot of cadmium, selenium, and sulfur is a means effective in obtaining blue light because the emission wavelength can be changed by changing the content ratio of elements.

As the quantum dot, any of a core-type quantum dot, a core-shell quantum dot, a core-multishell quantum dot, and the like can be used. Note that when a core is covered with a shell formed of another inorganic material having a wider band gap, the influence of defects and dangling bonds existing at the surface of a nanocrystal can be reduced. Since such a structure can significantly improve the quantum efficiency of light emission, it is preferable to use a core-shell or core-multishell quantum dot. Examples of the material of a shell include zinc sulfide and zinc oxide.

Quantum dots have a high proportion of surface atoms and thus have high reactivity and easily cohere together. For this reason, it is preferable that a protective agent be attached to, or a protective group be provided at the surfaces of quantum dots. The attachment of the protective agent or the provision of the protective group can prevent cohesion and increase solubility in a solvent. It can also reduce reactivity and improve electrical stability. Examples of the protective agent (or the protective group) include polyoxyethylene alkyl ethers such as polyoxyethylene lauryl ether, polyoxyethylene stearyl ether, and polyoxyethylene oleyl ether; trialkylphosphines such as tripropylphosphine, tributylphosphine, trihexylphosphine, and trioctylphoshine; polyoxyethylene alkylphenyl ethers such as polyoxyethylene n-octylphenyl ether and polyoxylethylene n-nonylphenyl ether; tertiary amines such as tri(n-hexyl)amine, tri(n-octyl)amine, and tri(n-decyl)amine; organophosphorus compounds such as tripropylphosphine oxide, tributylphosphine oxide, trihexylphosphine oxide, trioctylphosphine oxide, and tridecylphosphine oxide; polyethylene glycol diesters such as polyethylene glycol dilaurate and polyethylene glycol distearate; organic nitrogen compounds such as nitrogen-containing aromatic compounds, e.g., pyridines, lutidines, collidines, and quinolones; animoalkanes such as hexylamine, octylamine, decylamine, dodecylamine, tetradecylamine, hexadecylamine, and octadecylamine; dialkylsulfides such as dibutylsulfide; dialkylsulfoxides such as dimethylsulfoxide and dibutylsulfoxide; organic sulfur compounds such as sulfur-containing aromatic compounds, e.g., thiophene; higher fatty acids such as a palmitin acid, a stearic acid, and an oleic acid; alcohols; sorbitan fatty acid esters; fatty acid modified polyesters; tertiary amine modified polyurethanes; and polyethyleneimines.

Since band gaps of quantum dots are increased as their size is decreased, the size is adjusted as appropriate so that light with a desired wavelength can be obtained. Light emission from the quantum dots is shifted to a blue color side, i.e., a high energy side, as the crystal size is decreased; thus, emission wavelengths of the quantum dots can be adjusted over wavelength regions of spectra of an ultraviolet region, a visible light region, and an infrared region by changing the size of quantum dots. The range of size (diameter) of quantum dots which is usually used is 0.5 nm to 20 nm, preferably 1 nm to 10 nm. The emission spectra are narrowed as the size distribution of the quantum dots gets smaller, and thus light can be obtained with high color purity. The shape of the quantum dots is not particularly limited and may be spherical shape, a rod shape, a circular shape, or the like. Quantum rods which are rod-like shape quantum dots emit directional light polarized in the c-axis direction; thus, quantum rods can be used as a light-emitting material to obtain a light-emitting element with higher external quantum efficiency.

In most EL elements, to improve luminous efficiency, light-emitting materials are dispersed in host materials and the host materials need to be substances each having a singlet excitation energy or a triplet excitation energy higher than or equal to that of the light-emitting material. In the case of using a blue phosphorescent material, it is particularly difficult to develop a host material which has a triplet excitation energy higher than or equal to that of the blue phosphorescent material and which is excellent in terms of a lifetime. On the other hand, even when a light-emitting layer is composed of quantum dots and made without a host material, the quantum dots enable luminous efficiency to be ensured; thus, a light-emitting element which is favorable in terms of a lifetime can be obtained. In the case where the light-emitting layer is composed of quantum dots, the quantum dots preferably have core-shell structures (including core-multishell structures).

### [Alignment Film]

For the alignment films 618a and 618b, a material containing polyimide or the like can be used. Specifically, a material containing polyimide or the like may be subjected to a rubbing process or an optical alignment process to have alignment in a predetermined direction.

### [Light-Blocking Film]

The light-blocking film 602 functions as a so-called black matrix. For the light-blocking film 602, a material that prevents light transmission is used. Examples of the material that prevents light transmission include a metal material and an organic resin material containing a black pigment.

### [Coloring Film]

The coloring film 604 functions as a so-called color filter. For the coloring film 604, a material transmitting light of a predetermined color (e.g., a material transmitting light of blue, green, red, yellow, or white) is used.

### [Structure Body]

The structure bodies 610a and 610b have a function of providing a certain space between components between which the structure bodies 610a and 610b are interposed. For each of the structure bodies 610a and 610b, an organic material, an inorganic material, or a composite material of an organic material and an inorganic material can be used. For the inorganic material and the organic material, the materials for the insulating films 404, 406, 408, 410a, 410b, 410c, 412, 413, 416, 418, and 606 can be used.

### [Functional Film]

As the functional film 626, a polarizing plate, a retardation plate, a diffusing film, an anti-reflective film, a condensing film, or the like can be used. As the functional film 626, an antistatic film preventing the attachment of a foreign substance, a water repellent film suppressing the attachment of stain, a hard coat film suppressing generation of a scratch in use, or the like can be used.

### [Sealant]

For the sealant 454, an inorganic material, an organic material, a composite material of an inorganic material and an organic material, or the like can be used. Examples of the organic material include a thermally fusible resin and a curable resin. As the sealant 454, an adhesive including a resin material (e.g., a reactive curable adhesive, a photocurable adhesive, a thermosetting adhesive, or an anaerobic adhesive) may be used. Examples of such resin materials include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin.

### [Sealant]

For the sealant 622, the materials for the sealant 454 can be used. For the sealant 622, a material such as glass frit may be used in addition to the above materials. For a material used for the sealant 622, a material which is impermeable to moisture or oxygen is preferably used.

As described above, the display device of one embodiment of the present invention includes two display elements. Furthermore, the display device includes two transistors for driving the two display elements. One display element functions as a reflective liquid crystal element and the other display element functions as a transmissive EL element; thus, a novel display device that is highly convenient or reliable can be provided. With use of oxide semiconductor films for channel regions of the transistors for driving the display elements and one electrode of each of the two display elements, a novel display device in which manufacturing cost is reduced can be provided. In addition, when each of the transistors has a staggered structure, parasitic capacitance generated between the gate electrode and the source and drain electrodes can be reduced, whereby a novel display device with low power consumption can be provided.

Note that the structure described in this embodiment can be used in appropriate combination with the structure described in any of the other embodiments.

### Embodiment 2

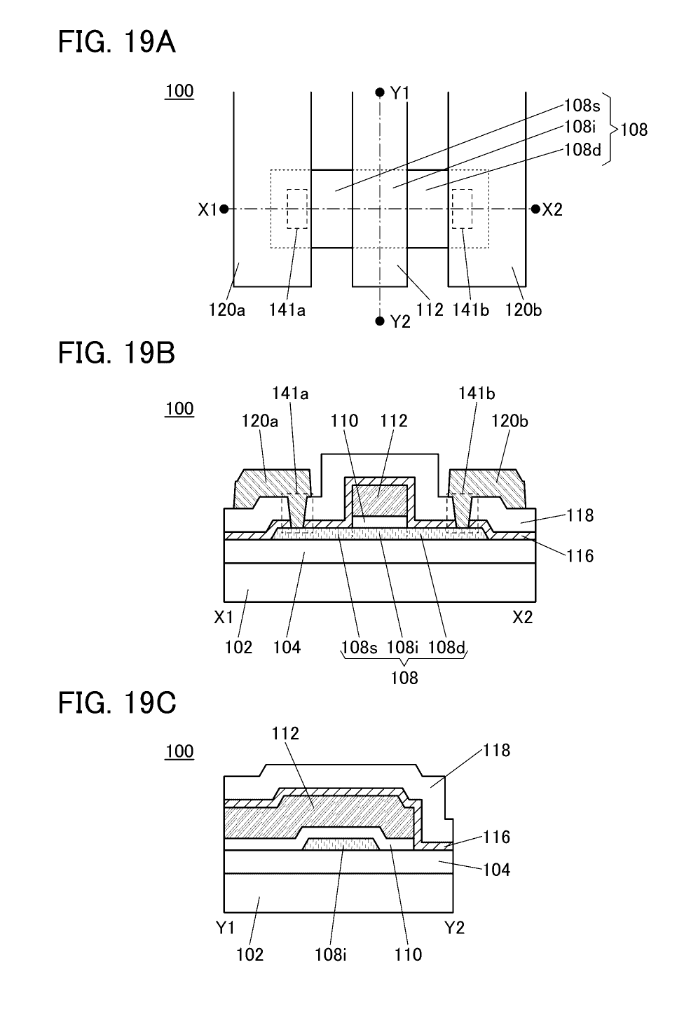

In this embodiment, a transistor that can be used for the display device of one embodiment of the present invention and a method for manufacturing the transistor will be described with reference to FIGS. 19A to 19C, FIGS. 20A to 20C, FIGS. 21A and 21B, FIGS. 22A and 22B, FIGS. 23A and 23B, FIGS. 24A and 24B, FIGS. 25A and 25B, FIGS. 26A and 26B, FIGS. 27A and 27B, FIGS. 28A and 28B, FIGS. 29A and 29B, FIGS. 30A to 30C, FIGS. 31A to 31D, FIGS. 32A to 32C, FIGS. 33A and 33B, FIGS. 34A to 34D, FIGS. 35A to 35C, and FIGS. 36A to 36C.

### <2-1. Structure Example 1 of Transistor>

FIGS. 19A to 19C show an example of a transistor. Note that the transistor in FIGS. 19A to 19C has a staggered (top-gate) structure.

FIG. 19A is a top view of a transistor 100. FIG. 19B is a cross-sectional view taken along a dashed-dotted line X1-X2 in FIG. 19A. FIG. 19C is a cross-sectional view taken along a dashed-dotted line Y1-Y2 in FIG. 19A. For clarity, FIG. 19A does not illustrate some components such as an insulating film 110. As in FIG. 19A, some components are not illustrated in some cases in top views of transistors described below. Furthermore, the direction of the dashed-dotted line X1-X2 may be referred to as a channel length (L) direction, and the direction of the dashed-dotted line Y1-Y2 may be referred to as a channel width (W) direction.

The transistor 100 illustrated in FIGS. 19A to 19C includes an insulating film 104 over a substrate 102; an oxide semiconductor film 108 over the insulating film 104; the insulating film 110 over the oxide semiconductor film 108; a conductive film 112 over the insulating film 110; and an insulating film 116 over the insulating film 104, the oxide semiconductor film 108, and the conductive film 112. Note that the oxide semiconductor film 108 includes a channel region 108i overlapping with the conductive film 112, a source region 108s in contact with the insulating film 116, and a drain region 108d in contact with the insulating film 116.

Furthermore, the insulating film 116 contains nitrogen or hydrogen. The insulating film 116 is in contact with the source region 108s and the drain region 108d, so that nitrogen or hydrogen that is contained in the insulating film 116 is added to the source region 108s and the drain region 108d. The source region 108s and the drain region 108d each have a high carrier density when nitrogen or hydrogen is added thereto.

The transistor 100 may further include an insulating film 118 over the insulating film 116, a conductive film 120a electrically connected to the source region 108s through an opening 141a provided in the insulating films 116 and 118, and a conductive film 120b electrically connected to the drain region 108d through an opening 141b provided in the insulating films 116 and 118.

In this specification and the like, the insulating film 104 may be referred to as a first insulating film, the insulating film 110 may be referred to as a second insulating film, the insulating film 116 may be referred to as a third insulating film, and the insulating film 118 may be referred to as a fourth insulating film. The conductive film 112 functions as a gate electrode, the conductive film 120a functions as a source electrode, and the conductive film 120b functions as a drain electrode.

The insulating film 110 functions as a gate insulating film. The insulating film 110 includes an excess oxygen region. Since the insulating film 110 includes the excess oxygen region, excess oxygen can be supplied to the channel region 108i included in the oxide semiconductor film 108. As a result, oxygen vacancies that might be formed in the channel region 108i can be filled with excess oxygen, which can provide a highly reliable semiconductor device.

To supply excess oxygen to the oxide semiconductor film 108, excess oxygen may be supplied to the insulating film 104 that is formed under the oxide semiconductor film 108. However, in that case, excess oxygen contained in the insulating film 104 might also be supplied to the source region 108s and the drain region 108d included in the oxide semiconductor film 108. When excess oxygen is supplied to the source region 108s and the drain region 108d, the resistance of the source region 108s and the drain region 108d might be increased.

In contrast, in the structure in which the insulating film 110 formed over the oxide semiconductor film 108 contains excess oxygen, excess oxygen can be selectively supplied only to the channel region 108i. Alternatively, the carrier density of the source and drain regions 108s and 108d can be selectively increased after excess oxygen is supplied to the channel region 108i and the source and drain regions 108s and 108d, in which case an increase in the resistance of the source and drain regions 108s and 108d can be prevented.

Furthermore, each of the source region 108s and the drain region 108d included in the oxide semiconductor film 108 preferably contains an element that forms an oxygen vacancy or an element that is bonded to an oxygen vacancy. Typical examples of the element that forms an oxygen vacancy or the element that is bonded to an oxygen vacancy include hydrogen, boron, carbon, nitrogen, fluorine, phosphorus, sulfur, chlorine, titanium, and a rare gas. Typical examples of the rare gas element are helium, neon, argon, krypton, and xenon. The element that forms an oxygen vacancy is diffused from the insulating film 116 to the source region 108s and the drain region 108d in the case where the insulating film 116 contains one or more such elements. In addition or alternatively, the element that forms an oxygen vacancy is added to the source region 108s and the drain region 108d by impurity addition treatment.

An impurity element added to the oxide semiconductor film cuts a bond between a metal element and oxygen in the oxide semiconductor film, so that an oxygen vacancy is formed. Alternatively, when an impurity element is added to the oxide semiconductor film, oxygen bonded to a metal element in the oxide semiconductor film is bonded to the impurity element and detached from the metal element, so that an oxygen vacancy is formed. As a result, the oxide semiconductor film has a higher carrier density, and thus, the conductivity thereof becomes higher.

Next, details of the components of the semiconductor device in FIGS. 19A to 19C will be described.

### [Substrate]

As the substrate 102, any of a variety of substrates can be used without particular limitation. The substrate 102 can be formed using a material similar to that of the substrates 401, 452, and 652 described in Embodiment 1.

### [First Insulating Film]

The insulating film 104 can be formed by a sputtering method, a CVD method, an evaporation method, a pulsed laser deposition (PLD) method, a printing method, a coating method, or the like as appropriate. For example, the insulating film 104 can be formed to have a single-layer structure or stacked-layer structure of an oxide insulating film and/or a nitride insulating film. To improve the properties of the interface with the oxide semiconductor film 108, at least a region of the insulating film 104 which is in contact with the oxide semiconductor film 108 is preferably formed using an oxide insulating film. When the insulating film 104 is formed using an oxide insulating film from which oxygen is released by heating, oxygen contained in the insulating film 104 can be moved to the oxide semiconductor film 108 by heat treatment.

The thickness of the insulating film 104 can be greater than or equal to 50 nm, greater than or equal to 100 nm and less than or equal to 3000 nm, or greater than or equal to 200 nm and less than or equal to 1000 nm. By increasing the thickness of the insulating film 104, the amount of oxygen released from the insulating film 104 can be increased, and interface states at the interface between the insulating film 104 and the oxide semiconductor film 108 and oxygen vacancies included in the channel region 108i of the oxide semiconductor film 108 can be reduced.

For example, the insulating film 104 can be formed to have a single-layer structure or stacked-layer structure of silicon oxide, silicon oxynitride, silicon nitride oxide, silicon nitride, aluminum oxide, hafnium oxide, gallium oxide, a Ga—Zn oxide, or the like. In this embodiment, the insulating film 104 has a stacked-layer structure of a silicon nitride film and a silicon oxynitride film. With the insulating film 104 having such a stack-layer structure including a silicon nitride film as a lower layer and a silicon oxynitride film as an upper layer, oxygen can be efficiently introduced into the oxide semiconductor film 108.

### [Oxide Semiconductor Film]

The oxide semiconductor film 108 can be formed using a material similar to that of the oxide semiconductor films 409a, 409b, and 409c described in Embodiment 1.

### [Second Insulating Film]

The insulating film 110 functions as a gate insulating film of the transistor 100. In addition, the insulating film 110 has a function of supplying oxygen to the oxide semiconductor film 108, particularly to the channel region 108i. The insulating film 110 can be formed to have a single-layer structure or a stacked-layer structure of an oxide insulating film or a nitride insulating film, for example. To improve the interface properties with the oxide semiconductor film 108, a region which is in the insulating film 110 and in contact with the oxide semiconductor film 108 is preferably formed using at least an oxide insulating film. For example, silicon oxide, silicon oxynitride, silicon nitride oxide, or silicon nitride may be used for the insulating film 110.

The thickness of the insulating film 110 can be greater than or equal to 5 nm and less than or equal to 400 nm, greater than or equal to 5 nm and less than or equal to 300 nm, or greater than or equal to 10 nm and less than or equal to 250 nm.

It is preferable that the insulating film 110 have few defects and typically have as few signals observed by electron spin resonance (ESR) spectroscopy as possible. Examples of the signals include a signal due to an E′ center observed at a g-factor of 2.001. Note that the E′ center is due to the dangling bond of silicon. As the insulating film 110, a silicon oxide film or a silicon oxynitride film whose spin density of a signal due to the E′ center is lower than or equal to 3×10¹⁷ spins/cm³ and preferably lower than or equal to 5×10¹⁶ spins/cm³ may be used.

In addition to the above-described signal, a signal due to nitrogen dioxide (NO₂) might be observed in the insulating film 110. The signal is divided into three signals according to the N nuclear spin; a first signal, a second signal, and a third signal. The first signal is observed at a g-factor of greater than or equal to 2.037 and less than or equal to 2.039. The second signal is observed at a g-factor of greater than or equal to 2.001 and less than or equal to 2.003. The third signal is observed at a g-factor of greater than or equal to 1.964 and less than or equal to 1.966.

It is suitable to use an insulating film whose spin density of a signal due to nitrogen dioxide (NO₂) is higher than or equal to 1×10¹⁷ spins/cm³ and lower than 1×10¹⁸ spins/cm³ as the insulating film 110, for example.

Note that a nitrogen oxide (NO_{X}) such as a nitrogen dioxide (NO₂) forms a level in the insulating film 110. The level is positioned in the energy gap of the oxide semiconductor film 108. Thus, when nitrogen oxide (NOₓ) is diffused to the interface between the insulating film 110 and the oxide semiconductor film 108, an electron might be trapped by the level on the insulating film 110 side. As a result, the trapped electron remains in the vicinity of the interface between the insulating film 110 and the oxide semiconductor film 108, leading to a positive shift of the threshold voltage of the transistor. Accordingly, the use of a film with a low nitrogen oxide content as the insulating film 110 can reduce a shift of the threshold voltage of the transistor.

As an insulating film that releases a small amount of nitrogen oxide (NOₓ), for example, a silicon oxynitride film can be used. The silicon oxynitride film releases more ammonia than nitrogen oxide (NOₓ) in thermal desorption spectroscopy (TDS); the typical released amount of ammonia is greater than or equal to 1×10¹⁸ molecules cm⁻⁻³ and less than or equal to 5×10¹⁹ molecules cm⁻⁻³. Note that the released amount of ammonia is the total amount of ammonia released by heat treatment in a range of 50° C. to 650° C. or 50° C. to 550° C. in TDS.

Since nitrogen oxide (NOₓ) reacts with ammonia and oxygen in heat treatment, the use of an insulating film that releases a large amount of ammonia reduces nitrogen oxide (NOₓ).

Note that in the case where the insulating film 110 is analyzed by SIMS, nitrogen concentration in the film is preferably lower than or equal to 6×10²⁰ atoms/cm³.

The insulating film 110 may be formed using a high-k material such as hafnium silicate (HfSiOₓ), hafnium silicate to which nitrogen is added (HfSiₓO_{y}N_{z}), hafnium aluminate to which nitrogen is added (HfAlₓO_{y}N_{z}), or hafnium oxide. The use of such a high-k material enables a reduction in gate leakage current of a transistor.

### [Third Insulating Film]

The insulating film 116 contains nitrogen or hydrogen. The insulating film 116 may contain fluorine. As the insulating film 116, for example, a nitride insulating film can be used. The nitride insulating film can be formed using silicon nitride, silicon nitride oxide, silicon oxynitride, silicon nitride fluoride, silicon fluoronitride, or the like. The hydrogen concentration in the insulating film 116 is preferably higher than or equal to 1×10²² atoms/cm³. Furthermore, the insulating film 116 is in contact with the source region 108s and the drain region 108d of the oxide semiconductor film 108. Thus, the concentration of an impurity (nitrogen or hydrogen) in the source region 108s and the drain region 108d in contact with the insulating film 116 is increased, leading to an increase in the carrier density of the source region 108s and the drain region 108d.

### [Fourth Insulating Film]

As the insulating film 118, an oxide insulating film can be used. Alternatively, a stack including an oxide insulating film and a nitride insulating film can be used as the insulating film 118. The insulating film 118 can be formed using, for example, silicon oxide, silicon oxynitride, silicon nitride oxide, aluminum oxide, hafnium oxide, gallium oxide, or Ga—Zn oxide.

Furthermore, the insulating film 118 preferably functions as a barrier film against hydrogen, water, and the like from the outside.

The thickness of the insulating film 118 can be greater than or equal to 30 nm and less than or equal to 500 nm, or greater than or equal to 100 nm and less than or equal to 400 nm.

### [Conductive Film]

The conductive films 112, 120a, and 120b can be formed by a sputtering method, a vacuum evaporation method, a pulsed laser deposition (PLD) method, a thermal CVD method, or the like. The conductive films 112, 120a, and 120b can be formed using materials similar to those of the conductive films 402, 403a, 403b, 403c, 405a, 405b, 405c, 405d, 407a, 407b, 407c, 407d, 407e, 414a, 414b, 414c, 414d, 414e 414f, 414g, 414h, 417, 420, and 608 and the oxide semiconductor films 411a, 411b, and 411c which are described in Embodiment 1.

The conductive films 112, 120a, and 120b can also be formed using a light-transmitting conductive material such as ITO, indium oxide containing tungsten oxide, indium zinc oxide containing tungsten oxide, indium oxide containing titanium oxide, indium tin oxide containing titanium oxide, indium zinc oxide, or ITSO. It is also possible to have a layered structure formed using the above light-transmitting conductive material and the above metal element.

Note that an oxide semiconductor typified by an In—Ga—Zn oxide may be used for the conductive film 112. The oxide semiconductor can have a high carrier density when nitrogen or hydrogen is supplied from the insulating film 116. In other words, the oxide semiconductor functions as an oxide conductor (OC). Accordingly, the oxide semiconductor can be used for a gate electrode.

The conductive film 112 can have, for example, a single-layer structure of an oxide conductor (OC), a single-layer structure of a metal film, or a stacked-layer structure of an oxide conductor (OC) and a metal film.

Note that it is suitable that the conductive film 112 has a single-layer structure of a light-shielding metal film or a stacked-layer structure of an oxide conductor (OC) and a light-shielding metal film because the channel region 108i formed under the conductive film 112 can be shielded from light. In the case where the conductive film 112 has a stacked-layer structure of an oxide semiconductor or an oxide conductor (OC) and a light-shielding metal film, formation of a metal film (e.g., a titanium film or a tungsten film) over the oxide semiconductor or the oxide conductor (OC) produces any of the following effects: the resistance of the oxide semiconductor or the oxide conductor (OC) is reduced by the diffusion of the constituent element of the metal film to the oxide semiconductor or oxide conductor (OC) side, the resistance is reduced by damage (e.g., sputtering damage) during the deposition of the metal film, and the resistance is reduced when oxygen vacancies are formed by the diffusion of oxygen in the oxide semiconductor or the oxide conductor (OC) to the metal film.

The thickness of the conductive films 112, 120a, and 120b can be greater than or equal to 30 nm and less than or equal to 500 nm, or greater than or equal to 100 nm and less than or equal to 400 nm.

### <2-2. Structure Example 2 of Semiconductor Device>

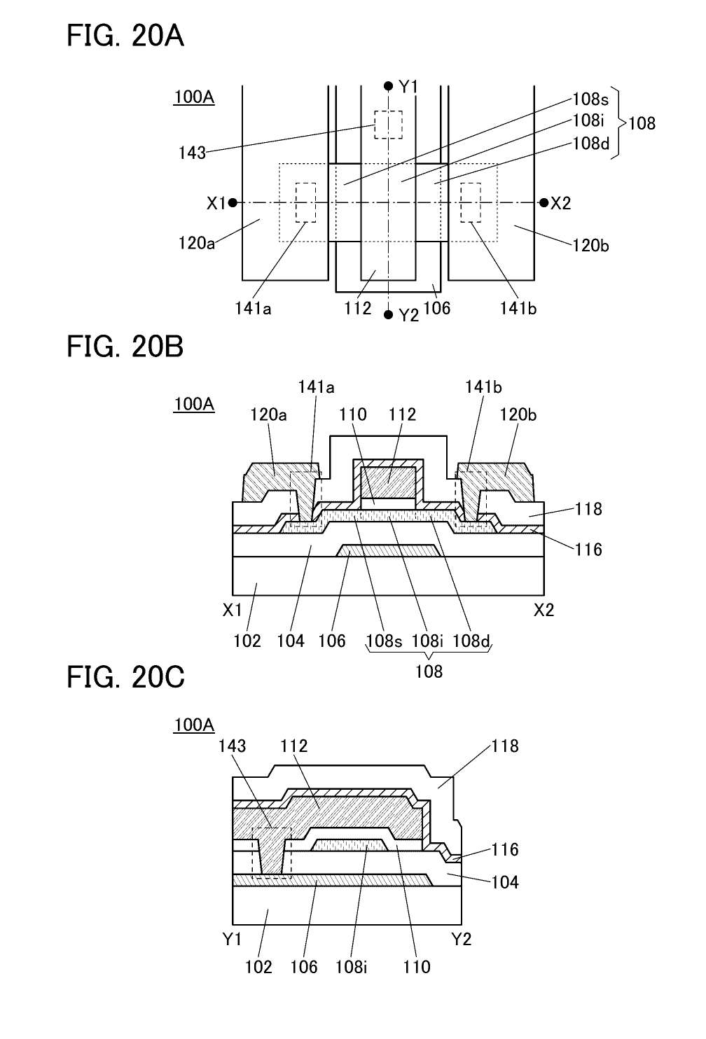

Next, a structure of a transistor different from that in FIGS. 19A to 19C will be described with reference to FIGS. 20A to 20C.

FIG. 20A is a top view of a transistor 100A. FIG. 20B is a cross-sectional view taken along the dashed-dotted line X1-X2 in FIG. 20A. FIG. 20C is a cross-sectional view taken along the dashed-dotted line Y1-Y2 in FIG. 20A.

The transistor 100A illustrated in FIGS. 20A to 20C includes a conductive film 106 over the substrate 102; the insulating film 104 over the conductive film 106; the oxide semiconductor film 108 over the insulating film 104; the insulating film 110 over the oxide semiconductor film 108; the conductive film 112 over the insulating film 110; and the insulating film 116 over the insulating film 104, the oxide semiconductor film 108, and the conductive film 112. Note that the oxide semiconductor film 108 includes the channel region 108i overlapping with the conductive film 112, the source region 108s in contact with the insulating film 116, and the drain region 108d in contact with the insulating film 116.

The transistor 100A includes the conductive film 106 and an opening 143 in addition to the components of the transistor 100 described above.

Note that the opening 143 is provided in the insulating films 104 and 110. The conductive film 106 is electrically connected to the conductive film 112 through the opening 143. Thus, the same potential is applied to the conductive film 106 and the conductive film 112. Note that different potentials may be applied to the conductive film 106 and the conductive film 112 without providing the opening 143. Alternatively, the conductive film 106 may be used as a light-shielding film without providing the opening 143. When the conductive film 106 is formed using a light-shielding material, for example, light irradiating the channel region 108i from the bottom can be reduced.

In the case of the structure of the transistor 100A, the conductive film 106 functions as a first gate electrode (also referred to as a bottom-gate electrode), the conductive film 112 functions as a second gate electrode (also referred to as a top-gate electrode), the insulating film 104 functions as a first gate insulating film, and the insulating film 110 functions as a second gate insulating film.

The conductive film 106 can be formed using a material similar to the above-described materials of the conductive films 112, 120a, and 120b. It is particularly suitable to use a material containing copper for the conductive film 106 because the resistance can be reduced. It is suitable that, for example, each of the conductive films 106, 120a, and 120b has a stacked-layer structure in which a copper film is over a titanium nitride film, a tantalum nitride film, or a tungsten film. In that case, when the transistor 100A is used as a pixel transistor and/or a driving transistor of a display device, parasitic capacitance generated between the conductive films 106 and 120a and between the conductive films 106 and 120b can be reduced. Thus, the conductive films 106, 120a, and 120b can be used not only as the first gate electrode, the source electrode, and the drain electrode of the transistor 100A, but also as power source supply wirings, signal supply wirings, connection wirings, or the like of the display device.

In this manner, unlike the transistor 100 described above, the transistor 100A in FIGS. 20A to 20C has a structure in which a conductive film functioning as a gate electrode is provided over and under the oxide semiconductor film 108. As in the transistor 100A, a semiconductor device of one embodiment of the present invention may have a plurality of gate electrodes.

As illustrated in FIG. 20C, the oxide semiconductor film 108 faces the conductive film 106 functioning as a first gate electrode and the conductive film 112 functioning as a second gate electrode and is positioned between the two conductive films functioning as the gate electrodes.

Furthermore, the length of the conductive film 112 in the channel width direction is larger than the length of the oxide semiconductor film 108 in the channel width direction. In the channel width direction, the whole oxide semiconductor film 108 is covered with the conductive film 112 with the insulating film 110 placed therebetween. Since the conductive film 112 is connected to the conductive film 106 through the opening 143 provided in the insulating films 104 and 110, a side surface of the oxide semiconductor film 108 in the channel width direction faces the conductive film 112 with the insulating film 110 placed therebetween.

In other words, in the channel width direction of the transistor 100A, the conductive films 106 and 112 are connected to each other through the opening 143 provided in the insulating films 104 and 110, and the conductive films 106 and 112 surround the oxide semiconductor film 108 with the insulating films 104 and 110 placed therebetween.

Such a structure enables the oxide semiconductor film 108 included in the transistor 100A to be electrically surrounded by electric fields of the conductive film 106 functioning as a first gate electrode and the conductive film 112 functioning as a second gate electrode. A device structure of a transistor, like that of the transistor 100A, in which electric fields of a first gate electrode and a second gate electrode electrically surround an oxide semiconductor film in which a channel region is formed can be referred to as a surrounded channel (S-channel) structure.

Since the transistor 100A has the S-channel structure, an electric field for inducing a channel can be effectively applied to the oxide semiconductor film 108 by the conductive film 106 or the conductive film 112; thus, the current drive capability of the transistor 100A can be improved and high on-state current characteristics can be obtained. As a result of the high on-state current, it is possible to reduce the size of the transistor 100A. Furthermore, since the transistor 100A has a structure in which the oxide semiconductor film 108 is surrounded by the conductive film 106 and the conductive film 112, the mechanical strength of the transistor 100A can be increased.

When seen in the channel width direction of the transistor 100A, an opening different from the opening 143 may be formed on the side of the oxide semiconductor film 108 on which the opening 143 is not formed.

When a transistor has a pair of gate electrodes between which a semiconductor film is positioned as in the transistor 100A, one of the gate electrodes may be supplied with a signal A, and the other gate electrode may be supplied with a fixed potential V_{b}. Alternatively, one of the gate electrodes may be supplied with the signal A, and the other gate electrode may be supplied with a signal B. Alternatively, one of the gate electrodes may be supplied with a fixed potential Vₐ, and the other gate electrode may be supplied with the fixed potential V_{b}.

The signal A is, for example, a signal for controlling the on/off state. The signal A may be a digital signal with two kinds of potentials, a potential V1 and a potential V2 (V1>V2). For example, the potential V1 can be a high power supply potential, and the potential V2 can be a low power supply potential. The signal A may be an analog signal.

The fixed potential V_{b} is, for example, a potential for controlling a threshold voltage V_{thA} of the transistor. The fixed potential V_{b} may be the potential V1 or the potential V2. In that case, a potential generator circuit for generating the fixed potential V_{b} is not necessary, which is preferable. The fixed potential V_{b} may be different from the potential V1 or the potential V2. When the fixed potential V_{b} is low, the threshold voltage V_{thA} can be high in some cases. As a result, the drain current flowing when the gate-source voltage V_{gs} is 0 V can be reduced, and leakage current in a circuit including the transistor can be reduced in some cases. The fixed potential V_{b} may be, for example, lower than the low power supply potential. Meanwhile, a high fixed potential V_{b} can lower the threshold voltage V_{thA} in some cases. As a result, the drain current flowing when the gate-source voltage V_{gs} is a high power supply potential and the operating speed of the circuit including the transistor can be increased in some cases. The fixed potential V_{b} may be, for example, higher than the low power supply potential.

The signal B is, for example, a signal for controlling the on/off state. The signal B may be a digital signal with two kinds of potentials, a potential V3 and a potential V4 (V3>V4). For example, the potential V3 can be a high power supply potential, and the potential V4 can be a low power supply potential. The signal B may be an analog signal.

When both the signal A and the signal B are digital signals, the signal B may have the same digital value as the signal A. In this case, it may be possible to increase the on-state current of the transistor and the operating speed of the circuit including the transistor. Here, the potential V1 and the potential V2 of the signal A may be different from the potential V3 and the potential V4 of the signal B. For example, if a gate insulating film for the gate to which the signal B is input is thicker than a gate insulating film for the gate to which the signal A is input, the potential amplitude of the signal B (V3-V4) may be larger than the potential amplitude of the signal A (V1-V2). In this manner, the influence of the signal A and that of the signal B on the on/off state of the transistor can be substantially the same in some cases.

When both the signal A and the signal B are digital signals, the signal B may have a digital value different from that of the signal A. In this case, the signal A and the signal B can separately control the transistor, and thus, higher performance can be achieved. The transistor which is, for example, an n-channel transistor can function by itself as a NAND circuit, a NOR circuit, or the like in the following case: the transistor is turned on only when the signal A has the potential V1 and the signal B has the potential V3, or the transistor is turned off only when the signal A has the potential V2 and the signal B has the potential V4. The signal B may be a signal for controlling the threshold voltage V_{thA}. For example, the potential of the signal B in a period in which the circuit including the transistor operates may be different from the potential of the signal B in a period in which the circuit does not operate. The potential of the signal B may vary depending on the operation mode of the circuit. In this case, the potential of the signal B is not changed as frequently as the potential of the signal A in some cases.

When both the signal A and the signal B are analog signals, the signal B may be an analog signal having the same potential as the signal A, an analog signal whose potential is a constant times the potential of the signal A, an analog signal whose potential is higher or lower than the potential of the signal A by a constant, or the like. In this case, it may be possible to increase the on-state current of the transistor and the operating speed of the circuit including the transistor. The signal B may be an analog signal different from the signal A. In this case, the signal A and the signal B can separately control the transistor, and thus, higher performance can be achieved.

The signal A may be a digital signal, and the signal B may be an analog signal. Alternatively, the signal A may be an analog signal, and the signal B may be a digital signal.

When both of the gate electrodes of the transistor are supplied with the fixed potentials, the transistor can function as an element equivalent to a resistor in some cases. For example, in the case where the transistor is an n-channel transistor, the effective resistance of the transistor can be sometimes low (high) when the fixed potential Vₐ or the fixed potential V_{b} is high (low). When both the fixed potential Vₐ and the fixed potential V_{b} are high (low), the effective resistance can be lower (higher) than that of a transistor with only one gate in some cases.

Except for the above-mentioned points, the transistor 100A has a structure and an effect similar to those of the transistor 100 described above.

### <2-3. Structure Example 3 of Semiconductor Device>

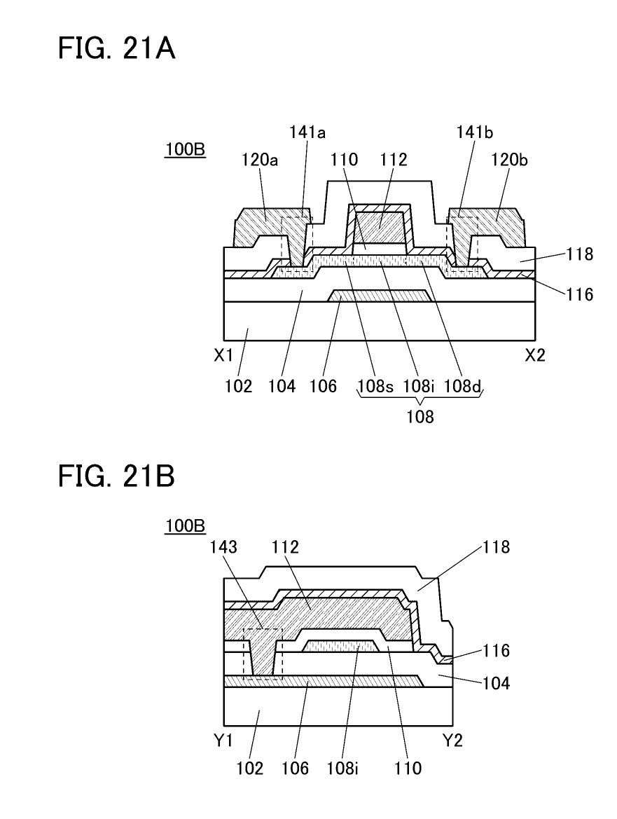

Next, structures of a transistor different from that in FIGS. 20A to 20C will be described with reference to FIGS. 21A and 21B, FIGS. 22A and 22B, FIGS. 23A and 23B, and FIGS. 24A and 24B.

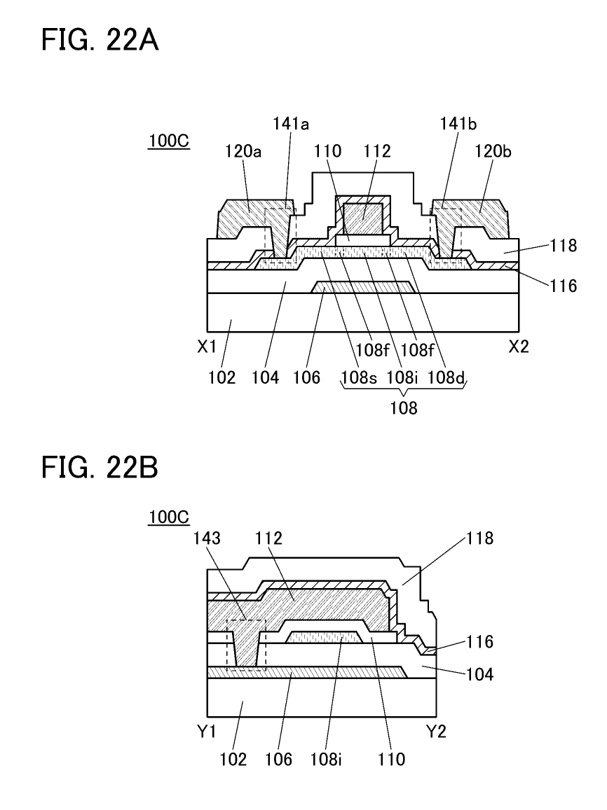

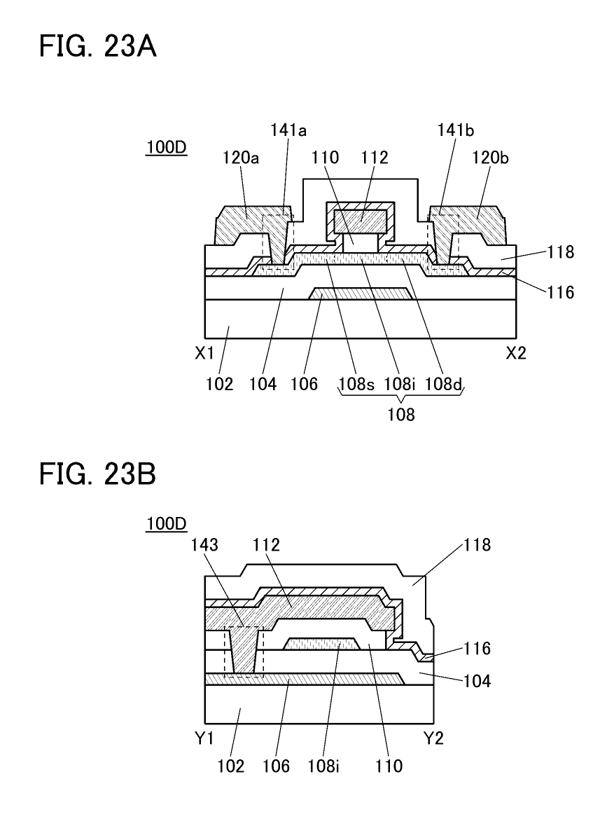

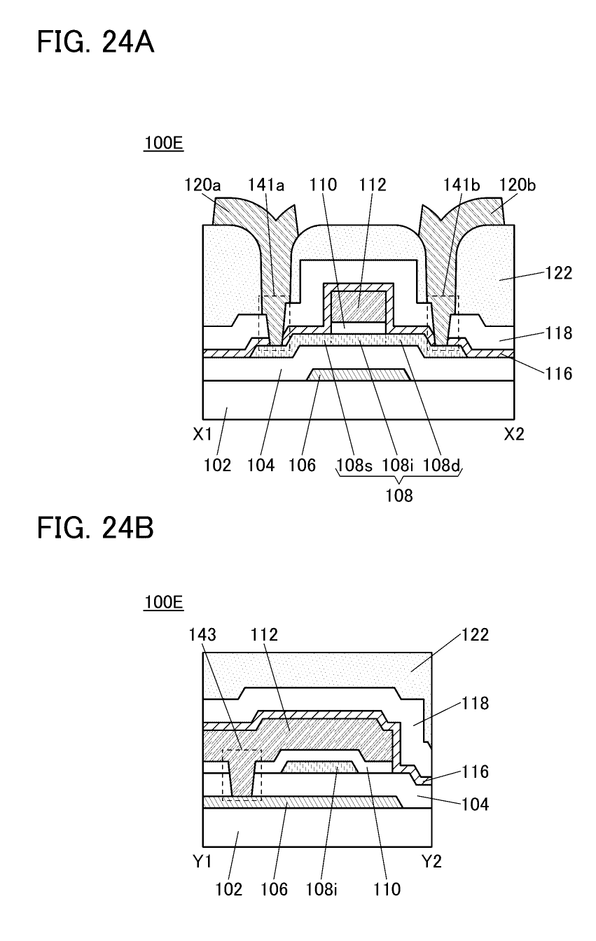

FIGS. 21A and 21B are cross-sectional views of a transistor 100B, FIGS. 22A and 22B are cross-sectional views of a transistor 100C, FIGS. 23A and 23B are cross-sectional views of a transistor 100D, and FIGS. 24A and 24B are cross-sectional views of a transistor 100E. Note that top views of the transistor 100B, the transistor 100C, the transistor 100D, and the transistor 100E are similar to that of the transistor 100A illustrated in FIG. 20A and thus are not described here.

The transistor 100B illustrated in FIGS. 21A and 21B is different from the above-described transistor 100A in the shape of the insulating film 110 and the conductive film 112. Specifically, in the cross section of the transistor in the channel length (L) direction, the shape of the insulating film 110 and the conductive film 112 is a rectangle in the transistor 100A but is a tapered shape in the transistor 100B. More specifically, in the cross section of the transistor in the channel length (L) direction, an upper end portion of the conductive film 112 in the transistor 100A is substantially aligned with a lower end portion of the insulating film 110, whereas an upper end portion of the conductive film 112 in the transistor 100B is located inward from a lower end portion of the insulating film 110. In other words, a side end portion of the insulating film 110 is located outward from a side end portion of the conductive film 112.

To fabricate the transistor 100A, the conductive film 112 and the insulating film 110 are collectively formed by a dry etching method using the same mask. To fabricate the transistor 100B, the conductive film 112 and the insulating film 110 are formed by a combination of a wet etching method and a dry etching method using the same mask.

A structure like that of the transistor 100A is preferable because end portions of the source region 108s and the drain region 108d can be substantially aligned with end portions of the conductive film 112. Meanwhile, a structure like that of the transistor 100B is preferable because the coverage with the insulating film 116 can be improved.

The transistor 100C illustrated in FIGS. 22A and 22B is different from the above-described transistor 100A in the shape of the conductive film 112 and the insulating film 110. Specifically, in the cross section of the transistor 100C in the channel length (L) direction, a lower end portion of the conductive film 112 is not aligned with an upper end portion of the insulating film 110. The lower end portion of the conductive film 112 is located inward from the upper end portion of the insulating film 110.

For example, the structure of the transistor 100C can be obtained in the following manner: the conductive film 112 and the insulating film 110 are formed by a wet etching method and a dry etching method, respectively, using the same mask.

With the structure of the transistor 100C, regions 108f are formed in the oxide semiconductor film 108 in some cases. The regions 108f are formed between the channel region 108i and the source region 108s and between the channel region 108i and the drain region 108d.

The regions 108f function as high-resistance regions or low-resistance regions. The high-resistance regions have the same level of resistance as the channel region 108i and do not overlap with the conductive film 112 functioning as a gate electrode. In the case where the regions 108f are high-resistance regions, the regions 108f function as offset regions. To suppress a decrease in the on-state current of the transistor 100C, the regions 108f functioning as offset regions may each have a length of 1 μm or less in a cross section in the channel length (L) direction.

The low-resistance regions have a resistance that is lower than that of the channel region 108i and higher than that of the source region 108s and the drain region 108d. In the case where the regions 108f are low-resistance regions, the regions 108f function as lightly doped drain (LDD) regions. The regions 108f functioning as LDD regions can relieve an electric field in the drain region, thereby reducing a change in the threshold voltage of the transistor due to the electric field in the drain region.

Note that in the case where the regions 108f serve as LDD regions, for example, the regions 108f are formed by supplying nitrogen or hydrogen from the insulating film 116 to the regions 108f or by adding an impurity element from above the conductive film 112 and the insulating film 110 using the conductive film 112 and the insulating film 110 as a mask so that the impurity element is added to the oxide semiconductor film 108 through the insulating film 110.

The transistor 100D illustrated in FIGS. 23A and 23B is different from the above-described transistor 100A in the shape of the conductive film 112 and the insulating film 110. Specifically, in the cross section of the transistor 100D in the channel length (L) direction, a lower end portion of the conductive film 112 is not aligned with an upper end portion of the insulating film 110. More specifically, the lower end portion of the conductive film 112 is located outward from the upper end portion of the insulating film 110.

For example, the structure of the transistor 100D can be obtained in the following manner: the conductive film 112 and the insulating film 110 are formed by a dry etching method and a wet etching method, respectively, using the same mask.

With the structure of the transistor 100D, parts of the source region 108s and the drain region 108d are provided inward from side surfaces of the conductive film 112 functioning as a gate electrode. Note that a region where the conductive film 112 and the source region 108s overlap with each other and a region where the conductive film 112 and the drain region 108d overlap with each other function as what are called overlap regions (also referred to as Lov regions). Note that the Lov regions overlap with the conductive film 112 functioning as the gate electrode and have lower resistance than the channel region 108i. With the Lov regions, no high-resistance region is formed between the channel region 108i and the source region 108s or the drain region 108d; accordingly, the on-state current of the transistor can be increased.

The transistor 100E illustrated in FIGS. 24A and 24B is different from the above-described transistor 100A in that an insulating film 122 functioning as a planarization film is provided over the insulating film 118. The other components of the transistor 100E are similar to those of the transistor 100A described above and have similar effects.

The insulating film 122 has a function of covering unevenness and the like caused by the transistor or the like. The insulating film 122 has an insulating property and is formed using an inorganic material or an organic material. Examples of the inorganic material include a silicon oxide film, a silicon oxynitride film, a silicon nitride oxide film, a silicon nitride film, an aluminum oxide film, and an aluminum nitride film. Examples of the organic material include photosensitive resin materials such as an acrylic resin and a polyimide resin.

Note that the size of each opening in the insulating film 122 is not limited to that in FIGS. 24A and 24B, in which the openings are larger than the openings 141a and 141b, and may be smaller than or equal to the size of each of the openings 141a and 141b, for example.

In addition, the structure is not limited to the example in FIGS. 24A and 24B, in which the conductive films 120a and 120b are provided over the insulating film 122; for example, the insulating film 122 may be provided over the conductive films 120a and 120b formed over the insulating film 118.

### <2-4. Structure Example 4 of Transistor>

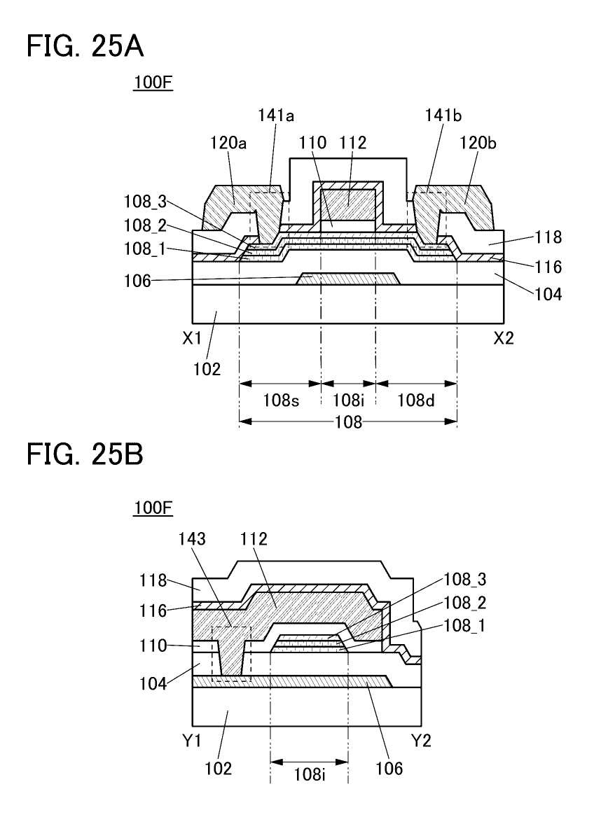

Next, structures of a transistor different from that in FIGS. 20A to 20C will be described with reference to FIGS. 25A and 25B, FIGS. 26A and 26B, FIGS. 27A and 27B, FIGS. 28A and 28B, FIGS. 29A and 29B, and FIGS. 30A to 30C.

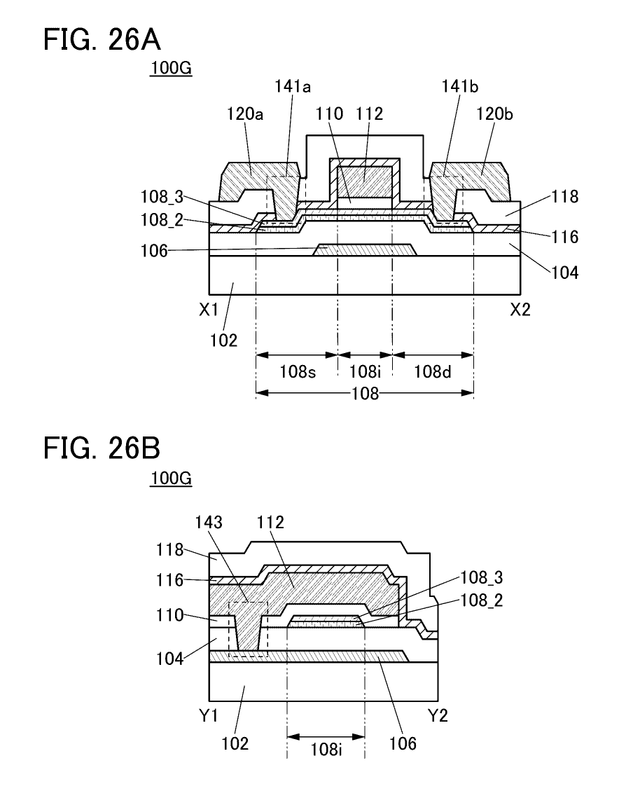

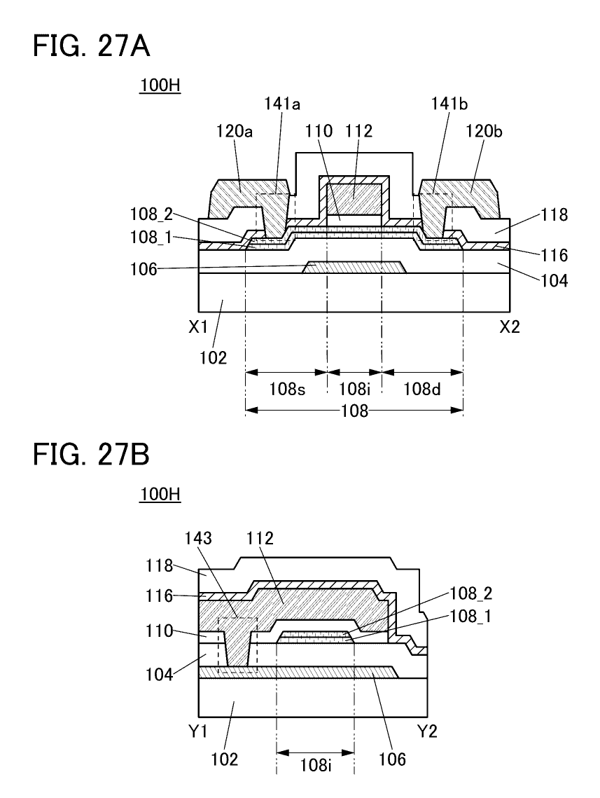

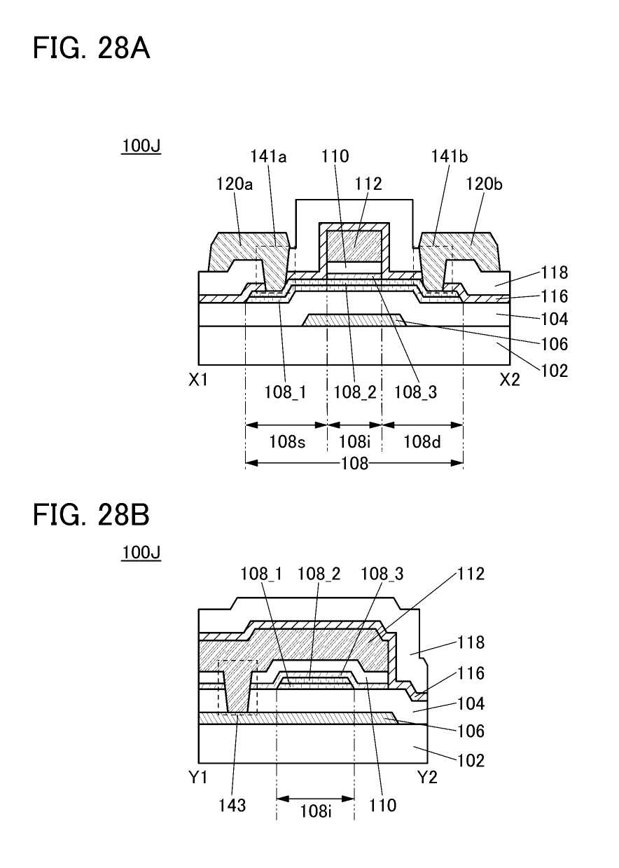

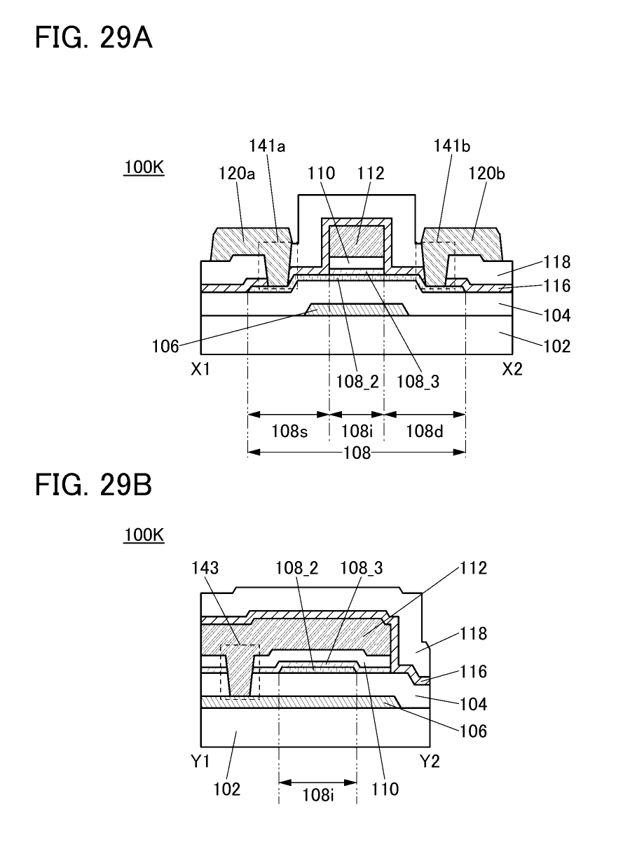

FIGS. 25A and 25B are cross-sectional views of a transistor 100F, FIGS. 26A and 26B are cross-sectional views of a transistor 100G, FIGS. 27A and 27B are cross-sectional views of a transistor 100H, FIGS. 28A and 28B are cross-sectional views of a transistor 100J, and FIGS. 29A and 29B are cross-sectional views of a transistor 100K. Note that top views of the transistor 100F, the transistor 100G, the transistor 100H, the transistor 100J, and the transistor 100K are similar to that of the transistor 100A illustrated in FIG. 20A and thus are not described here.

The transistors 100F, 100G, 100H, 100J, and 100K are different from the above-described transistor 100A in the structure of the oxide semiconductor film 108. The other components of the transistors 100F, 100G, 100H, 100J, and 100K are similar to those of the transistor 100A described above and have similar effects.

The oxide semiconductor film 108 of the transistor 100F illustrated in FIGS. 25A and 25B includes an oxide semiconductor film 108_1 over the insulating film 104, an oxide semiconductor film 108_2 over the oxide semiconductor film 108_1, and an oxide semiconductor film 108_3 over the oxide semiconductor film 108_2. The channel region 108i, the source region 108s, and the drain region 108d each have a three-layer structure of the oxide semiconductor film 108_1, the oxide semiconductor film 108_2, and the oxide semiconductor film 108_3.

The oxide semiconductor film 108 of the transistor 100G illustrated in FIGS. 26A and 26B includes the oxide semiconductor film 108_2 over the insulating film 104, and the oxide semiconductor film 108_3 over the oxide semiconductor film 108_2. The channel region 108i, the source region 108s, and the drain region 108d each have a two-layer structure of the oxide semiconductor film 108_2 and the oxide semiconductor film 108_3.

The oxide semiconductor film 108 of the transistor 100H illustrated in FIGS. 27A and 27B includes the oxide semiconductor film 108_1 over the insulating film 104, and the oxide semiconductor film 108_2 over the oxide semiconductor film 108_1. The channel region 108i, the source region 108s, and the drain region 108d each have a two-layer structure of the oxide semiconductor film 108_1 and the oxide semiconductor film 108_2.

The oxide semiconductor film 108 of the transistor 100J illustrated in FIGS. 28A and 28B includes the oxide semiconductor film 108_1 over the insulating film 104, the oxide semiconductor film 108_2 over the oxide semiconductor film 108_1, and the oxide semiconductor film 108_3 over the oxide semiconductor film 108_2. The channel region 108i has a three-layer structure of the oxide semiconductor film 108_1, the oxide semiconductor film 108_2, and the oxide semiconductor film 108_3. The source region 108s and the drain region 108d each have a two-layer structure of the oxide semiconductor film 108_1 and the oxide semiconductor film 108_2. Note that in the cross section of the transistor 100J in the channel width (W) direction, the oxide semiconductor film 108_3 covers side surfaces of the oxide semiconductor film 108_1 and the oxide semiconductor film 108_2.

The oxide semiconductor film 108 of the transistor 100K illustrated in FIGS. 29A and 29B includes the oxide semiconductor film 108_2 over the insulating film 104, and the oxide semiconductor film 108_3 over the oxide semiconductor film 108_2. The channel region 108i has a two-layer structure of the oxide semiconductor film 108_2 and the oxide semiconductor film 108_3. The source region 108s and the drain region 108d each have a single-layer structure of the oxide semiconductor film 108_2. Note that in the cross section of the transistor 100K in the channel width (W) direction, the oxide semiconductor film 108_3 covers side surfaces of the oxide semiconductor film 108_2.

A side surface of the channel region 108i in the channel width (W) direction or a region in the vicinity of the side surface is easily damaged by processing, resulting in a defect (e.g., oxygen vacancy), or easily contaminated by an impurity attached thereto. Therefore, even when the channel region 108i is substantially intrinsic, stress such as an electric field applied thereto activates the side surface of the channel region 108i in the channel width (W) direction or the region in the vicinity of the side surface and turns it into a low-resistance (n-type) region easily. Moreover, if the side surface of the channel region 108i in the channel width (W) direction or the region in the vicinity of the side surface is an n-type region, a parasitic channel may be formed because the n-type region serves as a carrier path.

Thus, in the transistor 100J and the transistor 100K, the channel region 108i has a stacked-layer structure and side surfaces of the channel region 108i in the channel width (W) direction are covered with one layer of the stacked layers. With such a structure, defects on or in the vicinity of the side surfaces of the channel region 108i can be suppressed or adhesion of an impurity to the side surfaces of the channel region 108i or to regions in the vicinity of the side surfaces can be reduced.

### <2-5. Band Structure>

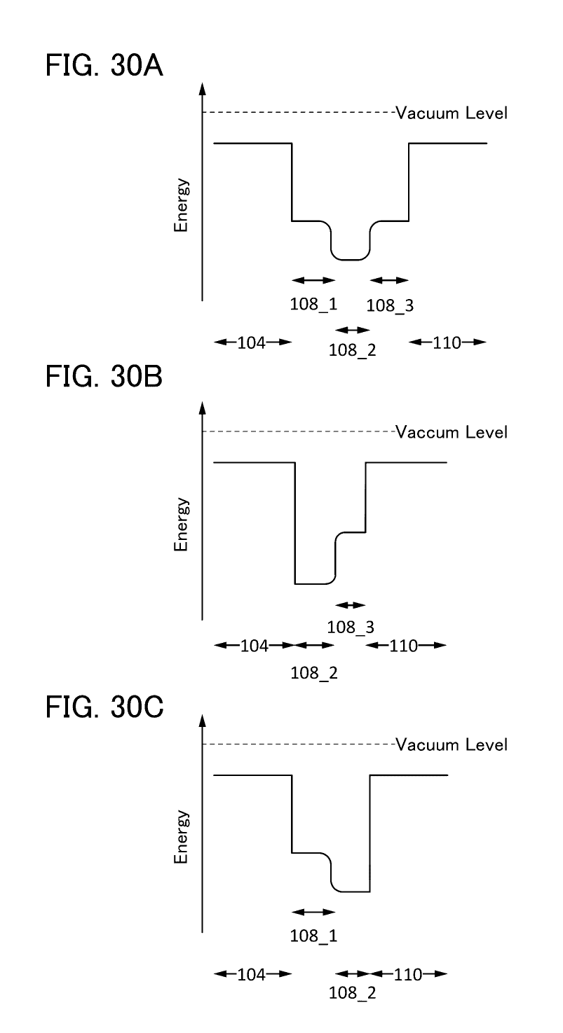

Here, a band structure of the insulating film 104, the oxide semiconductor films 108_1, 108_2, and 108_3, and the insulating film 110, a band structure of the insulating film 104, the oxide semiconductor films 108_2 and 108_3, and the insulating film 110, and a band structure of the insulating film 104, the oxide semiconductor films 108_1 and 108_2, and the insulating film 110 will be described with reference to FIGS. 30A to 30C. Note that FIGS. 30A to 30C are each a band structure of the channel region 108i.

FIG. 30A shows an example of a band structure in the thickness direction of a stack including the insulating film 104, the oxide semiconductor films 108_1, 108_2, and 108_3, and the insulating film 110. FIG. 30B shows an example of a band structure in the thickness direction of a stack including the insulating film 104, the oxide semiconductor films 108_2 and 108_3, and the insulating film 110. FIG. 30C shows an example of a band structure in the thickness direction of a stack including the insulating film 104, the oxide semiconductor films 108_1 and 108_2, and the insulating film 110. For easy understanding, the band structures show the conduction band minimum (E_{c}) of the insulating film 104, the oxide semiconductor films 108_1, 108_2, and 108_3, and the insulating film 110.

In the band structure of FIG. 30A, a silicon oxide film is used as each of the insulating films 104 and 110, an oxide semiconductor film formed using a metal oxide target whose atomic ratio of In to Ga and Zn is 1:3:2 is used as the oxide semiconductor film 108_1, an oxide semiconductor film formed using a metal oxide target whose atomic ratio of In to Ga and Zn is 4:2:4.1 is used as the oxide semiconductor film 108_2, and an oxide semiconductor film formed using a metal oxide target whose atomic ratio of In to Ga and Zn is 1:3:2 is used as the oxide semiconductor film 108_3.

In the band structure of FIG. 30B, a silicon oxide film is used as each of the insulating films 104 and 110, an oxide semiconductor film formed using a metal oxide target whose atomic ratio of In to Ga and Zn is 4:2:4.1 is used as the oxide semiconductor film 108_2, and an oxide semiconductor film formed using a metal oxide target whose atomic ratio of In to Ga and Zn is 1:3:2 is used as the oxide semiconductor film 108_3.

In the band structure of FIG. 30C, a silicon oxide film is used as each of the insulating films 104 and 110, an oxide semiconductor film formed using a metal oxide target whose atomic ratio of In to Ga and Zn is 1:3:2 is used as the oxide semiconductor film 108_1, and an oxide semiconductor film formed using a metal oxide target whose atomic ratio of In to Ga and Zn is 4:2:4.1 is used as the oxide semiconductor film 108_2.

As illustrated in FIG. 30A, the conduction band minimum gradually varies between the oxide semiconductor films 108_1, 108_2, and 108_3. As illustrated in FIG. 30B, the conduction band minimum gradually varies between the oxide semiconductor films 108_2 and 108_3. As illustrated in FIG. 30C, the conduction band minimum gradually varies between the oxide semiconductor films 108_1 and 108_2. In other words, the conduction band minimum is continuously changed or continuously connected. To obtain such a band structure, there exists no impurity, which forms a defect state such as a trap center or a recombination center, at the interface between the oxide semiconductor films 108_1 and 108_2 or the interface between the oxide semiconductor films 108_2 and 108_3.

To form a continuous junction between the oxide semiconductor films 108_1, 108_2, and 108_3, it is necessary to form the films successively without exposure to the air with a multi-chamber deposition apparatus (sputtering apparatus) provided with a load lock chamber.

With the band structure of FIG. 30A, FIG. 30B, or FIG. 30C, the oxide semiconductor film 108_2 serves as a well, and a channel region is formed in the oxide semiconductor film 108_2 in the transistor with the stacked-layer structure.

By providing the oxide semiconductor films 108_1 and 108_3, the oxide semiconductor film 108_2 can be distanced away from trap states.

In addition, the trap states might be more distant from the vacuum level than the conduction band minimum (E_{c}) of the oxide semiconductor film 108_2 functioning as a channel region, so that electrons are likely to be accumulated in the trap states. When the electrons are accumulated in the trap states, the electrons become negative fixed electric charge, so that the threshold voltage of the transistor is shifted in the positive direction. Therefore, it is preferable that the trap states be closer to the vacuum level than the conduction band minimum (E_{c}) of the oxide semiconductor film 108_2. Such a structure inhibits accumulation of electrons in the trap states. As a result, the on-state current and the field-effect mobility of the transistor can be increased.

The conduction band minimum of each of the oxide semiconductor films 108_1 and 108_3 is closer to the vacuum level than that of the oxide semiconductor film 108_2. A typical difference between the conduction band minimum of the oxide semiconductor film 108_2 and the conduction band minimum of each of the oxide semiconductor films 108_1 and 108_3 is 0.15 eV or more or 0.5 eV or more and 2 eV or less or 1 eV or less. That is, the difference between the electron affinity of each of the oxide semiconductor films 108_1 and 108_3 and the electron affinity of the oxide semiconductor film 108_2 is 0.15 eV or more or 0.5 eV or more and 2 eV or less or 1 eV or less.

In such a structure, the oxide semiconductor film 108_2 serves as a main path of a current. In other words, the oxide semiconductor film 108_2 serves as a channel region, and the oxide semiconductor films 108_1 and 108_3 serve as oxide insulating films. It is preferable that the oxide semiconductor films 108_1 and 108_3 each include one or more metal elements constituting a part of the oxide semiconductor film 108_2 in which a channel region is formed. With such a structure, interface scattering hardly occurs at the interface between the oxide semiconductor film 108_1 and the oxide semiconductor film 108_2 or at the interface between the oxide semiconductor film 108_2 and the oxide semiconductor film 108_3. Thus, the transistor can have high field-effect mobility because the movement of carriers is not hindered at the interface.

To prevent each of the oxide semiconductor films 108_1 and 108_3 from functioning as part of a channel region, a material having sufficiently low conductivity is used for the oxide semiconductor films 108_1 and 108_3. Thus, the oxide semiconductor films 108_1 and 108_3 can be referred to as oxide insulating films for such properties and/or functions. Alternatively, a material that has a smaller electron affinity (a difference between the vacuum level and the conduction band minimum) than the oxide semiconductor film 108_2 and has a difference in the conduction band minimum from the oxide semiconductor film 108_2 (band offset) is used for the oxide semiconductor films 108_1 and 108_3. Furthermore, to inhibit generation of a difference in threshold voltage due to the value of the drain voltage, it is preferable to form the oxide semiconductor films 108_1 and 108_3 using a material whose conduction band minimum is closer to the vacuum level than that of the oxide semiconductor film 108_2. For example, a difference between the conduction band minimum of the oxide semiconductor film 108_2 and the conduction band minimum of each of the oxide semiconductor films 108_1 and 108_3 is preferably greater than or equal to 0.2 eV, more preferably greater than or equal to 0.5 eV.

It is preferable that the oxide semiconductor films 108_1 and 108_3 not have a spinel crystal structure. This is because if the oxide semiconductor films 108_1 and 108_3 have a spinel crystal structure, constituent elements of the conductive films 120a and 120b might be diffused into the oxide semiconductor film 108_2 at the interface between the spinel crystal structure and another region. Note that each of the oxide semiconductor films 108_1 and 108_3 is preferably a CAAC-OS film described later, in which case a higher blocking property against constituent elements of the conductive films 120a and 120b, for example, copper elements, can be obtained.

Although the example where an oxide semiconductor film formed using a metal oxide target whose atomic ratio of In to Ga and Zn is 1:3:2, is used as each of the oxide semiconductor films 108_1 and 108_3 is described in this embodiment, one embodiment of the present invention is not limited thereto. For example, an oxide semiconductor film formed using a metal oxide target whose atomic ratio of In to Ga and Zn is 1:1:1, 1:1:1.2, 1:3:4, 1:3:6, 1:4:5, 1:5:6, or 1:10:1 may be used as each of the oxide semiconductor films 108_1 and 108_3. Alternatively, oxide semiconductor films formed using a metal oxide target whose atomic ratio of Ga to Zn is 10:1 may be used as the oxide semiconductor films 108_1 and 108_3. In that case, it is suitable that an oxide semiconductor film formed using a metal oxide target whose atomic ratio of In to Ga and Zn is 1:1:1 is used as the oxide semiconductor film 108_2 because the difference between the conduction band minimum of the oxide semiconductor film 108_2 and the conduction band minimum of the oxide semiconductor film 108_1 or 108_3 can be 0.6 eV or more.

When the oxide semiconductor films 108_1 and 108_3 are formed using a metal oxide target whose atomic ratio of In to Ga and Zn is 1:1:1, the atomic ratio of In to Ga and Zn in the oxide semiconductor films 108_1 and 108_3 might be 1:β1:β2 (0<β1≦2, 0<β2≦2). When the oxide semiconductor films 108_1 and 108_3 are formed using a metal oxide target whose atomic ratio of In to Ga and Zn is 1:3:4, the atomic ratio of In to Ga and Zn in the oxide semiconductor films 108_1 and 108_3 might be 1:β3:β4 (1≦β3≦5, 2≦β4≦6). When the oxide semiconductor films 108_1 and 108_3 are formed using a metal oxide target whose atomic ratio of In to Ga and Zn is 1:3:6, the atomic ratio of In to Ga and Zn in the oxide semiconductor films 108_1 and 108_3 might be 1:β5:β6 (1≦β5≦5, 4≦β6≦8).

### <2-6. Method 1 For Manufacturing Transistor>

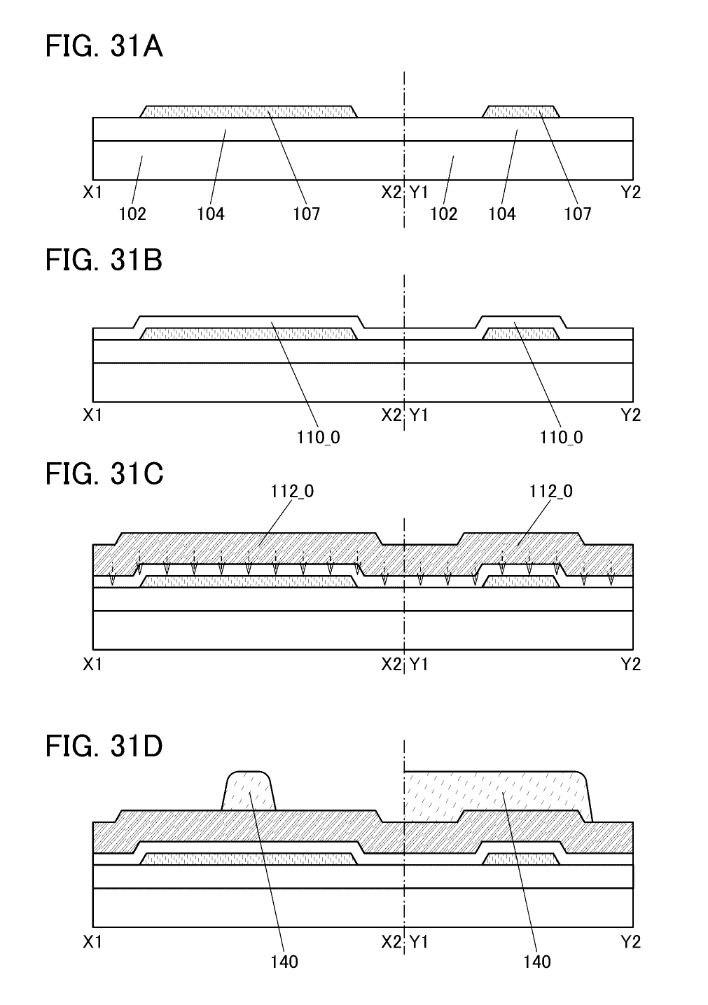

Next, an example of the method for manufacturing the transistor 100 illustrated in FIGS. 19A to 19C will be described with reference to FIGS. 31A to 31D, FIGS. 32A to 32C, and FIGS. 33A and 33B. Note that FIGS. 31A to 31D, FIGS. 32A to 32C, and FIGS. 33A and 33B are cross-sectional views in the channel length (L) direction and the channel width (W) direction and illustrate a method for manufacturing the transistor 100.

First, the insulating film 104 is formed over the substrate 102. Subsequently, an oxide semiconductor film is formed over the insulating film 104. Then, the oxide semiconductor film is processed into an island shape, whereby an oxide semiconductor film 107 is formed (see FIG. 31A).

The insulating film 104 can be formed by a sputtering method, a CVD method, an evaporation method, a pulsed laser deposition (PLD) method, a printing method, a coating method, or the like as appropriate. In this embodiment, as the insulating film 104, a 400-nm-thick silicon nitride film and a 50-nm-thick silicon oxynitride film are formed with a plasma CVD apparatus. Note that the oxide semiconductor film 108 may be formed over the substrate 102 without forming the insulating film 104.

After the insulating film 104 is formed, oxygen may be added to the insulating film 104. As oxygen added to the insulating film 104, an oxygen radical, an oxygen atom, an oxygen atomic ion, an oxygen molecular ion, or the like may be used. Oxygen can be added by an ion doping method, an ion implantation method, a plasma treatment method, or the like. Alternatively, a film that suppresses oxygen release may be formed over the insulating film 104, and then, oxygen may be added to the insulating film 104 through the film.

The film that suppresses oxygen release can be formed using a conductive film or a semiconductor film containing one or more of indium, zinc, gallium, tin, aluminum, chromium, tantalum, titanium, molybdenum, nickel, iron, cobalt, and tungsten.

In the case where oxygen is added by plasma treatment in which oxygen is excited by a microwave to generate high-density oxygen plasma, the amount of oxygen added to the insulating film 104 can be increased.

The oxide semiconductor film 107 can be formed by a sputtering method, a coating method, a pulsed laser deposition method, a laser ablation method, a thermal CVD method, or the like. Note that the oxide semiconductor film can be processed into the oxide semiconductor film 107 in the following manner: a mask is formed over the oxide semiconductor film by a lithography process, and then, the oxide semiconductor film is partly etched using the mask. Alternatively, the isolated oxide semiconductor film 107 may be directly formed by a printing method.

As a power supply device for generating plasma when the oxide semiconductor film is formed by a sputtering method, an RF power supply device, an AC power supply device, a DC power supply device, or the like can be used as appropriate. As a sputtering gas for forming the oxide semiconductor film, a rare gas (typically argon), oxygen, or a mixed gas of a rare gas and oxygen is used as appropriate. In the mixed gas of a rare gas and oxygen, the proportion of oxygen to the rare gas is preferably increased.

To increase the crystallinity of the oxide semiconductor film formed by a sputtering method, for example, the oxide semiconductor film is preferably deposited at a substrate temperature higher than or equal to 150° C. and lower than or equal to 750° C., higher than or equal to 150° C. and lower than or equal to 450° C., or higher than or equal to 200° C. and lower than or equal to 350° C.

In this embodiment, as the oxide semiconductor film 107, a 35-nm-thick oxide semiconductor film is deposited with a sputtering apparatus using an In—Ga—Zn metal oxide (In:Ga:Zn=4:2:4.1 [atomic ratio]) as a sputtering target.

After the oxide semiconductor film 107 is formed, the oxide semiconductor film 107 may be dehydrated or dehydrogenated by heat treatment. The temperature of the heat treatment is typically higher than or equal to 150° C. and lower than the strain point of the substrate, higher than or equal to 250° C. and lower than or equal to 450° C., or higher than or equal to 300° C. and lower than or equal to 450° C.

The heat treatment can be performed in an inert gas atmosphere containing nitrogen or a rare gas such as helium, neon, argon, xenon, or krypton. Alternatively, the heat treatment may be performed in an inert gas atmosphere first, and then, in an oxygen atmosphere. It is preferable that the above inert gas atmosphere and the above oxygen atmosphere do not contain hydrogen, water, and the like. The treatment time may be longer than or equal to 3 minutes and shorter than or equal to 24 hours.

An electric furnace, an RTA apparatus, or the like can be used for the heat treatment. With the use of an RTA apparatus, the heat treatment can be performed at a temperature higher than or equal to the strain point of the substrate if the heating time is short. Therefore, the heat treatment time can be shortened.

By depositing the oxide semiconductor film while it is heated or by performing heat treatment after the formation of the oxide semiconductor film, the hydrogen concentration in the oxide semiconductor film, which is measured by SIMS, can be 5×10¹⁹ atoms/cm³ or lower, 1×10¹⁹ atoms/cm³ or lower, 5×10¹⁸ atoms/cm³ or lower, 1×10¹⁸ atoms/cm³ or lower, 5×10¹⁷ atoms/cm³ or lower, or 1×10¹⁶ atoms/cm³ or lower.

Next, an insulating film 110_0 is formed over the insulating film 104 and the oxide semiconductor film 107 (see FIG. 31B).

For the insulating film 110_0, a silicon oxide film or a silicon oxynitride film can be formed with a plasma-enhanced chemical vapor deposition apparatus (a PECVD apparatus or simply referred to as a plasma CVD apparatus). In this case, a deposition gas containing silicon and an oxidizing gas are preferably used as a source gas. Typical examples of the deposition gas containing silicon include silane, disilane, trisilane, and silane fluoride. As examples of the oxidizing gas, oxygen, ozone, dinitrogen monoxide, and nitrogen dioxide can be given.

A silicon oxynitride film having few defects can be formed as the insulating film 110_0 with the plasma CVD apparatus under the conditions that the flow rate of the oxidizing gas is more than 20 times and less than 100 times, or more than or equal to 40 times and less than or equal to 80 times the flow rate of the deposition gas and that the pressure in a treatment chamber is lower than 100 Pa or lower than or equal to 50 Pa.

As the insulating film 110_0, a dense silicon oxide film or a dense silicon oxynitride film can be formed under the following conditions: the substrate placed in a vacuum-evacuated treatment chamber of the plasma CVD apparatus is held at a temperature higher than or equal to 280° C. and lower than or equal to 400° C., the pressure in the treatment chamber into which a source gas is introduced is set to be higher than or equal to 20 Pa and lower than or equal to 250 Pa, preferably higher than or equal to 100 Pa and lower than or equal to 250 Pa, and a high-frequency power is supplied to an electrode provided in the treatment chamber.

The insulating film 110_0 may be formed by a plasma CVD method using a microwave. A microwave refers to a wave in the frequency range of 300 MHz to 300 GHz. In a microwave, electron temperature and electron energy are low. Furthermore, in supplied power, the proportion of power used for acceleration of electrons is low, and therefore, much more power can be used for dissociation and ionization of molecules. Thus, plasma with a high density (high-density plasma) can be excited. This method causes little plasma damage to the deposition surface or a deposit, so that the insulating film 110_0 having few defects can be formed.

Alternatively, the insulating film 110_0 can also be formed by a CVD method using an organosilane gas. As the organosilane gas, the following silicon-containing compound can be used: tetraethyl orthosilicate (TEOS) (chemical formula: Si(OC₂H₅)₄), tetramethylsilane (TMS) (chemical formula: Si(CH₃)₄), tetramethylcyclotetrasiloxane (TMCTS), octamethylcyclotetrasiloxane (OMCTS), hexamethyldisilazane (HMDS), triethoxysilane (SiH(OC₂H₅)₃), trisdimethylaminosilane (SiH(N(CH₃)₂)₃), or the like. By a CVD method using an organosilane gas, the insulating film 110_0 having high coverage can be formed.

In this embodiment, as the insulating film 110_0, a 100-nm-thick silicon oxynitride film is formed with the plasma CVD apparatus.

Next, a conductive film 112_0 is formed over the insulating film 110_0. In the case where a metal oxide film is used as the conductive film 112_0, for example, oxygen might be added from the conductive film 112_0 to the insulating film 110_0 during the formation of the conductive film 112_0 (see FIG. 31C).

In FIG. 31C, oxygen added to the insulating film 110_0 is schematically shown by arrows.

In the case where a metal oxide film is used as the conductive film 112_0, the conductive film 112_0 is preferably formed by a sputtering method in an atmosphere containing an oxygen gas. Formation of the conductive film 112_0 in an atmosphere containing an oxygen gas allows suitable addition of oxygen to the insulating film 110_0. Note that a method for forming the conductive film 112_0 is not limited to a sputtering method, and other methods such as an ALD method may be used.

In this embodiment, a 100-nm-thick IGZO film containing an In—Ga—Zn oxide (In:Ga:Zn=4:2:4.1 [atomic ratio]) is formed as the conductive film 112_0 by a sputtering method. Note that oxygen addition treatment may be performed on the insulating film 110_0 before or after the formation of the conductive film 112_0. The oxygen addition treatment can be performed similarly to the oxygen addition that can be performed after the formation of the insulating film 104.

Subsequently, a mask 140 is formed by a lithography process in a desired position over the conductive film 112_0 (see FIG. 31D).

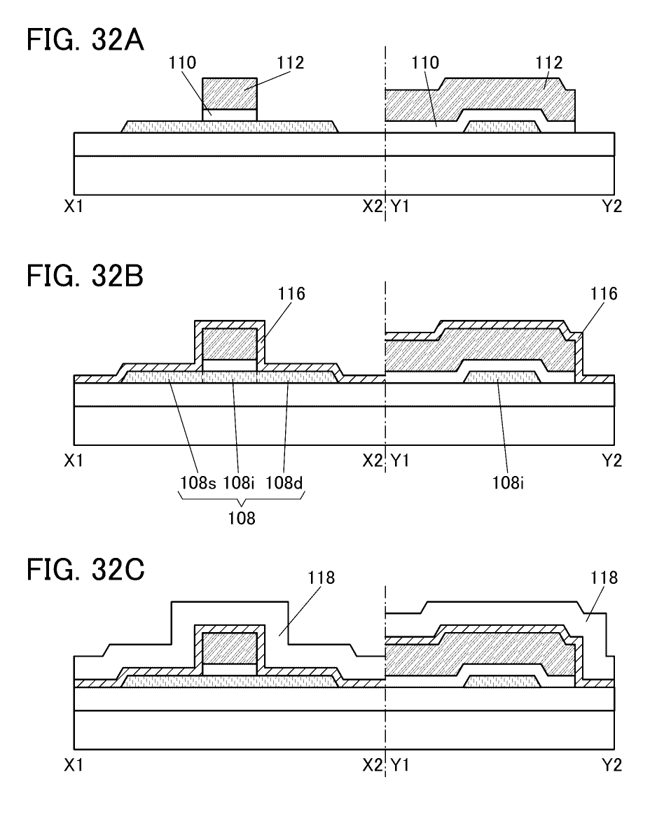

Next, etching is performed from above the mask 140 to process the conductive film 112_0 and the insulating film 110_0. Then, the mask 140 is removed, so that the island-shaped conductive film 112 and the island-shaped insulating film 110 are formed (see FIG. 32A).

In this embodiment, the conductive film 112_0 and the insulating film 110_0 are processed by a dry etching method.

In the processing of the conductive film 112_0 and the insulating film 110_0, the thickness of the oxide semiconductor film 107 in a region not overlapping with the conductive film 112 is decreased in some cases. In other cases, in the processing of the conductive film 112_0 and the insulating film 110_0, the thickness of the insulating film 104 in a region not overlapping with the oxide semiconductor film 107 is decreased. In the processing of the conductive film 112_0 and the insulating film 110_0, an etchant or an etching gas (e.g., chlorine) might be added to the oxide semiconductor film 107 or the constituent element of the conductive film 112_0 or the insulating film 110_0 might be added to the oxide semiconductor film 107.

Then, the insulating film 116 is formed over the insulating film 104, the oxide semiconductor film 107, and the conductive film 112. Note that when the insulating film 116 is formed, the oxide semiconductor film 107 in regions in contact with the insulating film 116 becomes the source region 108s and the drain region 108d. The oxide semiconductor film 107 in a region in contact with the insulating film 110 becomes the channel region 108i. Accordingly, the oxide semiconductor film 108 including the channel region 108i, the source region 108s, and the drain region 108d is formed (see FIG. 32B).

When a silicon nitride oxide film is used for the insulating film 116, nitrogen or hydrogen in the silicon nitride oxide film can be supplied to the source region 108s and the drain region 108d in contact with the insulating film 116.

Note that an impurity element may be added to the oxide semiconductor film 107 before the insulating film 116 is formed. Alternatively, an impurity element may be added to the oxide semiconductor film 107 through the insulating film 116 after the insulating film 116 is formed.

The impurity element can be added by an ion doping method, an ion implantation method, a plasma treatment method, or the like. In a plasma treatment method, an impurity element can be added using plasma generated in a gas atmosphere containing the impurity element. A dry etching apparatus, an ashing apparatus, a plasma CVD apparatus, a high-density plasma CVD apparatus, or the like can be used to generate plasma.

As a source gas of the impurity element, at least one of B₂H₆, PH₃, CH₄, N₂, NH₃, AlH₃, AlCl₃, SiH₄, Si₂H₆, F₂, HF, H₂, and a rare gas can be used. Alternatively, at least one of B₂H₆, PH₃, N₂, NH₃, AlH₃, AlCl₃, F₂, HF, and H₂ which are diluted with a rare gas can be used. Typical examples of the rare gas element include helium, neon, argon, krypton, and xenon.

Alternatively, after a rare gas is added to the oxide semiconductor film 107, at least one of B₂H₆, PH₃, CH₄, N₂, NH₃, AlH₃, AlCl₃, SiH₄, Si₂H₆, F₂, HF, and H₂ may be added thereto. Further alternatively, after at least one of B₂H₆, PH₃, CH₄, N₂, NH₃, AlH₃, AlCl₃, SiH₄, Si₂H₆, F₂, HF, and H₂ is added to the oxide semiconductor film 107, a rare gas may be added thereto.

Next, the insulating film 118 is formed over the insulating film 116 (see FIG. 32C).

The insulating film 118 can be formed using a material selected from the above-mentioned materials. In this embodiment, as the insulating film 118, a 300-nm-thick silicon oxynitride film is formed with a plasma CVD apparatus.

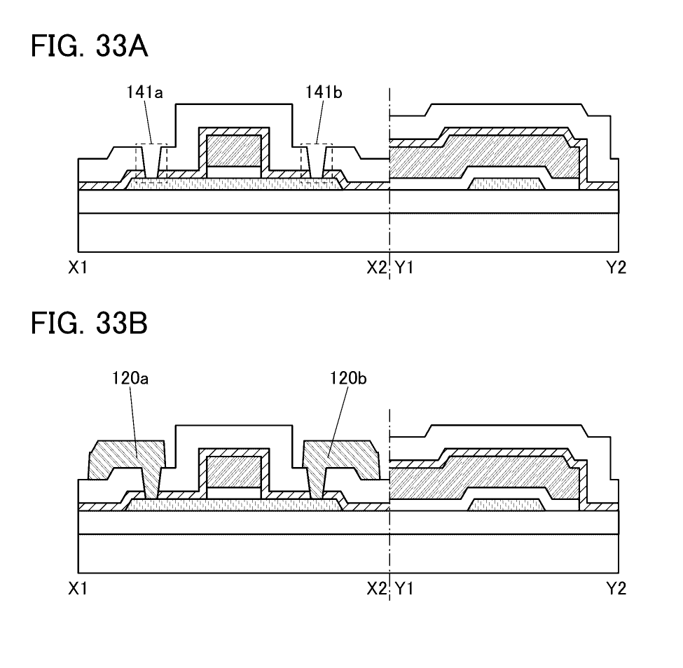

Subsequently, a mask is formed by lithography in a desired position over the insulating film 118, and then, the insulating film 118 and the insulating film 116 are partly etched, so that the opening 141a reaching the source region 108s and the opening 141b reaching the drain region 108d are formed (see FIG. 33A).

To etch the insulating film 118 and the insulating film 116, a wet etching method and/or a dry etching method can be used. In this embodiment, the insulating film 118 and the insulating film 116 are processed by a dry etching method.

Next, a conductive film is formed over the source region 108s, the drain region 108d, and the insulating film 118 so as to cover the openings 141a and 141b and the conductive film is processed into a desired shape, whereby the conductive films 120a and 120b are formed (see FIG. 33B).

The conductive films 120a and 120b can be formed using a material selected from the above-mentioned materials. In this embodiment, for the conductive films 120a and 120b, a stack including a 50-nm-thick tungsten film and a 400-nm-thick copper film is formed with a sputtering apparatus.

To process the conductive film to be the conductive films 120a and 120b, a wet etching method and/or a dry etching method can be used. In this embodiment, in the processing of the conductive film into the conductive films 120a and 120b, the copper film is etched by a wet etching method and then the tungsten film is etched by a dry etching method.

Through the above steps, the transistor 100 in FIGS. 19A to 19C can be manufactured.

Note that the films constituting a part of the transistor 100 (the insulating film, the metal oxide film, the oxide semiconductor film, the conductive film, and the like) can be formed by, other than the above methods, a sputtering method, a chemical vapor deposition (CVD) method, a vacuum evaporation method, a pulsed laser deposition (PLD) method, or an ALD method. Alternatively, a coating method or a printing method can be used. Although a sputtering method and a plasma-enhanced chemical vapor deposition (PECVD) method are typical deposition methods, a thermal CVD method may also be used. As an example of a thermal CVD method, a metal organic chemical vapor deposition (MOCVD) method can be given.

Deposition by a thermal CVD method is performed in the following manner: a source gas and an oxidizer are supplied at a time to a chamber in which the pressure is set to an atmospheric pressure or a reduced pressure, and the source gas and the oxidizer react with each other in the vicinity of the substrate or over the substrate. As seen above, no plasma is generated during deposition by a thermal CVD method, which has an advantage in that no defect due to plasma damage is formed.

Films such as the conductive film, the insulating film, the oxide semiconductor film, and the metal oxide film can be formed by a thermal CVD method such as an MOCVD method. For example, in the case where an In—Ga—Zn—O film is deposited, trimethylindium (In(CH₃)₃), trimethylgallium (Ga(CH₃)₃), and dimethylzinc (Zn(CH₃)₂) are used. Without being limited to the above combination, triethylgallium (Ga(C₂H₅)₃) can be used instead of trimethylgallium, and diethylzinc (Zn(C₂H₅)₂) can be used instead of dimethylzinc.

In the case where a hafnium oxide film is formed with a deposition apparatus employing an ALD method, two kinds of gases are used, namely, ozone (O₃) as an oxidizer and a source gas which is obtained by vaporizing liquid containing a solvent and a hafnium precursor (hafnium alkoxide or hafnium amide such as tetrakis(dimethylamide)hafnium (TDMAH, Hf[N(CH₃)₂]₄) or tetrakis(ethylmethylamide)hafnium).

In the case where an aluminum oxide film is formed with a deposition apparatus employing an ALD method, two kinds of gases are used, namely, H₂O as an oxidizer and a source gas which is obtained by vaporizing liquid containing a solvent and an aluminum precursor (e.g., trimethylaluminum (TMA, Al(CH₃)₃)). Examples of another material include tris(dimethylamide)aluminum, triisobutylaluminum, and aluminum tris(2,2,6,6-tetramethyl-3,5-heptanedionate).

In the case where a silicon oxide film is formed with a deposition apparatus employing an ALD method, hexachlorodisilane is adsorbed on a surface on which a film is to be deposited, and radicals of an oxidizing gas (O₂ or dinitrogen monoxide) are supplied to react with the adsorbate.

In the case where a tungsten film is formed with a deposition apparatus employing an ALD method, a WF₆ gas and a B₂H₆ gas are sequentially introduced to form an initial tungsten film, and then, a WF₆ gas and an H₂ gas are used to form a tungsten film. Note that an SiH₄ gas may be used instead of a B₂H₆ gas.

In the case where an oxide semiconductor film such as an In—Ga—Zn—O film is formed with a deposition apparatus employing an ALD method, an In(CH₃)₃ gas and an O₃ gas are used to form an In—O layer, a Ga(CH₃)₃ gas and an O₃ gas are used to form a Ga—O layer, and then, a Zn(CH₃)₂ gas and an O₃ gas are used to form a Zn—O layer. Note that the order of these layers is not limited to this example. A mixed compound layer such as an In—Ga—O layer, an In—Zn—O layer, or a Ga—Zn—O layer may be formed using these gases. Although an H₂O gas which is obtained by bubbling water with an inert gas such as Ar may be used instead of an O₃ gas, it is preferable to use an O₃ gas, which does not contain H.

### <2-7. Method 2 For Manufacturing Transistor>

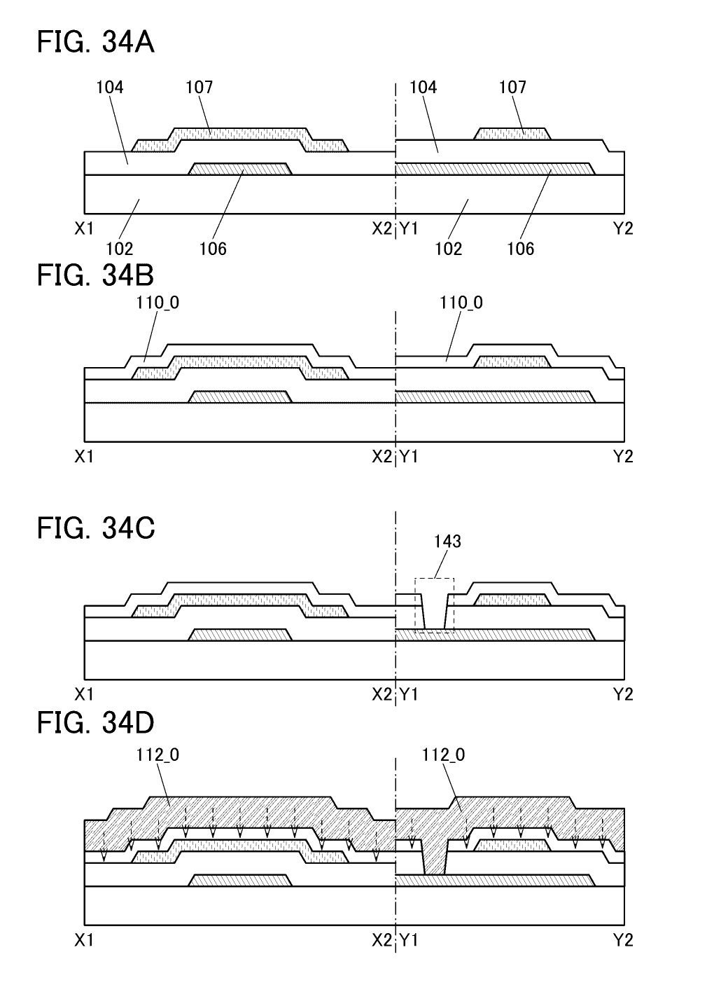

Next, an example of a method for manufacturing the transistor 100A in FIGS. 20A to 20C will be described with reference to FIGS. 34A to 34D, FIGS. 35A to 35C, and FIGS. 36A to 36C. Note that FIGS. 34A to 34D, FIGS. 35A to 35C, and FIGS. 36A to 36C are cross-sectional views in the channel length (L) direction and the channel width (W) direction and illustrate a method for manufacturing the transistor 100A.

First, the conductive film 106 is formed over the substrate 102. Then, the insulating film 104 is formed over the substrate 102 and the conductive film 106, and an oxide semiconductor film is formed over the insulating film 104. After that, the oxide semiconductor film is processed into an island shape, whereby the oxide semiconductor film 107 is formed (see FIG. 34A).

The conductive film 106 can be formed using a material and a method similar to those of the conductive films 120a and 120b. In this embodiment, as the conductive film 106, a stack including a 50-nm-thick tantalum nitride film and a 100-nm-thick copper film is formed by a sputtering method.

Next, the insulating film 110_0 is formed over the insulating film 104 and the oxide semiconductor film 107 (see FIG. 34B).

Subsequently, a mask is formed by lithography in a desired position over the insulating film 110_0, and then, the insulating film 110_0, and the insulating film 104 are partly etched, so that the opening 143 reaching the conductive film 106 is formed (see FIG. 34C).

To form the opening 143, a wet etching method and/or a dry etching method can be used. In this embodiment, the opening 143 is formed by a dry etching method.

Next, the conductive film 112_0 is formed over the conductive film 106 and the insulating film 110_0 so as to cover the opening 143. In the case where a metal oxide film is used as the conductive film 112_0, for example, oxygen might be added from the conductive film 112_0 to the insulating film 110_0 during the formation of the conductive film 112_0 (see FIG. 34D).

In FIG. 34D, oxygen added to the insulating film 110_0 is schematically shown by arrows. Furthermore, the conductive film 112_0 formed to cover the opening 143 is electrically connected to the conductive film 106.

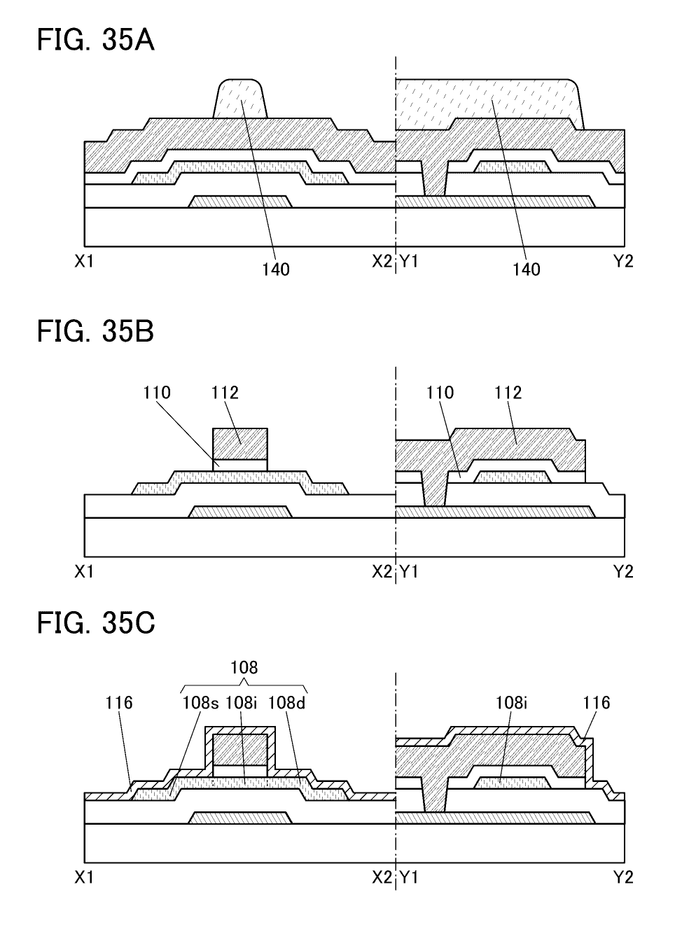

Subsequently, the mask 140 is formed by a lithography process in a desired position over the conductive film 112_0 (see FIG. 35A).

Next, etching is performed from above the mask 140 to process the conductive film 112_0 and the insulating film 110_0. After the processing of the conductive film 112_0 and the insulating film 110_0, the mask 140 is removed. As a result of the processing of the conductive film 112_0 and the insulating film 110_0, the island-shaped conductive film 112 and the island-shaped insulating film 110 are formed (see FIG. 35B).

In this embodiment, the conductive film 112_0 and the insulating film 110_0 are processed by a dry etching method.

After that, the insulating film 116 is formed over the insulating film 104, the oxide semiconductor film 107, and the conductive film 112. Note that when the insulating film 116 is formed, the oxide semiconductor film 107 in regions in contact with the insulating film 116 becomes the source region 108s and the drain region 108d. The oxide semiconductor film 107 in a region in contact with the insulating film 110 becomes the channel region 108i. Accordingly, the oxide semiconductor film 108 including the channel region 108i, the source region 108s, and the drain region 108d is formed (see FIG. 35C).

Note that the insulating film 116 can be formed using a material selected from the above-mentioned materials. In this embodiment, as the insulating film 116, a 100-nm-thick silicon nitride oxide film is formed with a plasma CVD apparatus. In the formation of the silicon nitride oxide film, plasma treatment and deposition treatment are performed at 220° C. Note that the plasma treatment and the deposition treatment can be performed in the same manner described above.

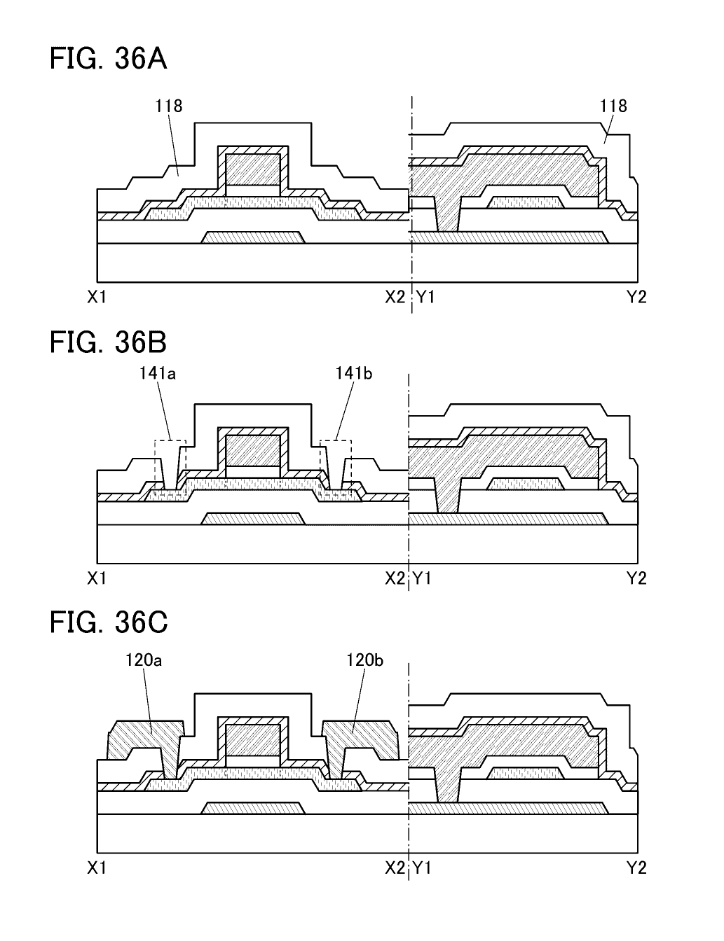

Next, the insulating film 118 is formed over the insulating film 116 (see FIG. 36A).

Subsequently, a mask is formed by lithography in a desired position over the insulating film 118, and then, the insulating film 118 and the insulating film 116 are partly etched, so that the opening 141a reaching the source region 108s and the opening 141b reaching the drain region 108d are formed (see FIG. 36B).

Next, a conductive film is formed over the source region 108s, the drain region 108d, and the insulating film 118 so as to cover the openings 141a and 141b and the conductive film is processed into a desired shape, whereby the conductive films 120a and 120b are formed (see FIG. 36C).

Through the above steps, the transistor 100A in FIGS. 20A to 20C can be manufactured.

One embodiment of the present invention is not limited to the example described in this embodiment, in which the transistor includes an oxide semiconductor film. In one embodiment of the present invention, the transistor does not necessarily include an oxide semiconductor film. For example, a channel region, the vicinity of the channel region, a source region, or a drain region of the transistor may be formed using a material containing silicon (Si), germanium (Ge), silicon germanium (SiGe), gallium arsenide (GaAs), or the like.

The structures and the methods described in this embodiment can be combined as appropriate with any of the structures and the methods described in the other embodiments.

### Embodiment 3

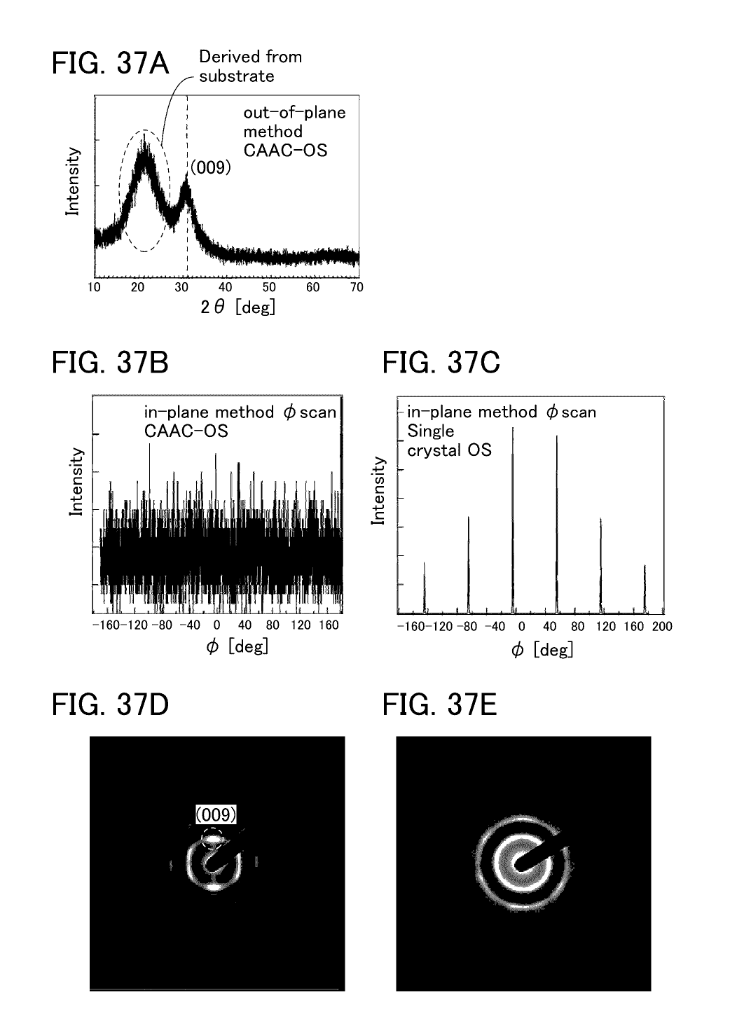

In this embodiment, the structure and the like of an oxide semiconductor will be described with reference to FIGS. 37A to 37E, FIGS. 38A to 38E, FIGS. 39A to 39D, FIGS. 40A and 40B, and FIG. 41.

### <3-1. Structure of Oxide Semiconductor>

An oxide semiconductor is classified into a single-crystal oxide semiconductor and a non-single-crystal oxide semiconductor. Examples of the non-single-crystal oxide semiconductor include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of the crystalline oxide semiconductor include a single-crystal oxide semiconductor, a CAAC-OS, a polycrystalline oxide semiconductor, and an nc-OS.

An amorphous structure is generally thought to be isotropic and have no non-uniform structure, to be metastable and have no fixed atomic arrangement, to have a flexible bond angle, and to have a short-range order but have no long-range order, for example.

In other words, a stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. In contrast, an a-like OS, which is not isotropic, has an unstable structure that contains a void. Because of its instability, an a-like OS has physical properties similar to those of an amorphous oxide semiconductor.

### <3-2. CAAC-OS>

First, a CAAC-OS will be described.

A CAAC-OS is one of oxide semiconductors and has a plurality of c-axis aligned crystal parts (also referred to as pellets).

Analysis of a CAAC-OS by X-ray diffraction (XRD) will be described. For example, when the structure of a CAAC-OS including an InGaZnO₄ crystal, which is classified into the space group R-3m, is analyzed by an out-of-plane method, a peak appears at a diffraction angle (2θ) of around 31° as shown in FIG. 37A. This peak is derived from the (009) plane of the InGaZnO₄ crystal, which indicates that crystals in the CAAC-OS have c-axis alignment and that the c-axes are aligned in the direction substantially perpendicular to a surface over which the CAAC-OS is formed (also referred to as a formation surface) or a top surface of the CAAC-OS. Note that a peak sometimes appears at 2θ of around 36° in addition to the peak at 2θ of around 31°. The peak at 2θ of around 36° is attributed to a crystal structure classified into the space group Fd-3m; thus, this peak is preferably not exhibited in the CAAC-OS.

On the other hand, in structural analysis of the CAAC-OS by an in-plane method in which an X-ray is incident on the CAAC-OS in the direction parallel to the formation surface, a peak appears at 2θ of around 56°. This peak is derived from the (110) plane of the InGaZnO₄ crystal. When analysis (φ scan) is performed with 2θ fixed at around 56° while the sample is rotated around a normal vector to the sample surface as an axis (φ axis), as shown in FIG. 37B, a peak is not clearly observed. In contrast, in the case where single-crystal InGaZnO₄ is subjected to φ scan with 2θ fixed at around 56°, as shown in FIG. 37C, six peaks which are derived from crystal planes equivalent to the (110) plane are observed. Accordingly, the structural analysis using XRD shows that the directions of the a-axes and b-axes are irregularly oriented in the CAAC-OS.

Next, a CAAC-OS analyzed by electron diffraction will be described. For example, when an electron beam with a probe diameter of 300 nm is incident on a CAAC-OS including an InGaZnO₄ crystal in the direction parallel to the formation surface of the CAAC-OS, a diffraction pattern (also referred to as a selected-area electron diffraction pattern) in FIG. 37D can be obtained. This diffraction pattern includes spots derived from the (009) plane of the InGaZnO₄ crystal. Thus, the results of electron diffraction also indicate that pellets included in the CAAC-OS have c-axis alignment and that the c-axes are aligned in the direction substantially perpendicular to the formation surface or the top surface of the CAAC-OS. Meanwhile, FIG. 37E shows a diffraction pattern obtained in such a manner that an electron beam with a probe diameter of 300 nm is incident on the same sample in the direction perpendicular to the sample surface. In FIG. 37E, a ring-like diffraction pattern is observed. Thus, the results of electron diffraction using an electron beam with a probe diameter of 300 nm also indicate that the a-axes and b-axes of the pellets included in the CAAC-OS do not have regular alignment. The first ring in FIG. 37E is derived from the (010) plane, the (100) plane, and the like of the InGaZnO₄ crystal. The second ring in FIG. 37E is derived from the (110) plane and the like.

In a combined analysis image (also referred to as a high-resolution transmission electron microscope (TEM) image) of a bright-field image and a diffraction pattern of a CAAC-OS, which is obtained using a TEM, a plurality of pellets can be observed. However, even in the high-resolution TEM image, a boundary between pellets, that is, a grain boundary is not clearly observed in some cases. Thus, in the CAAC-OS, a reduction in electron mobility due to the grain boundary is less likely to occur.

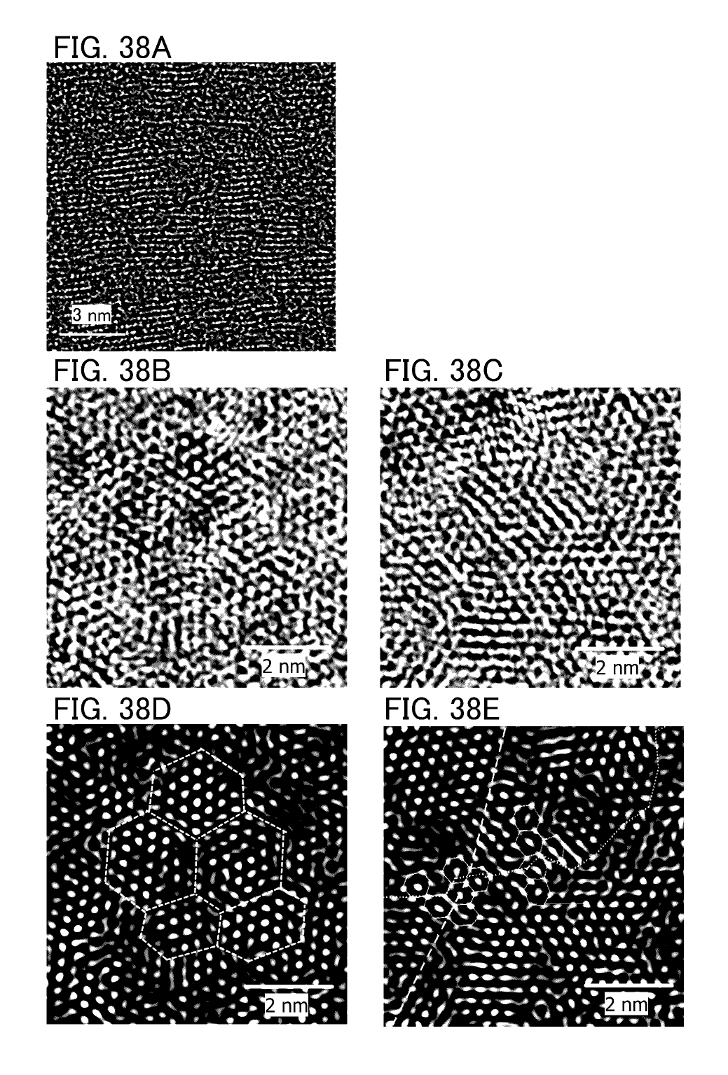

FIG. 38A shows a high-resolution TEM image of a cross section of the CAAC-OS which is observed in the direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be observed with, for example, an atomic resolution analytical electron microscope JEM-ARM200F manufactured by JEOL Ltd.

FIG. 38A shows pellets in which metal atoms are arranged in a layered manner. FIG. 38A proves that the size of a pellet is greater than or equal to 1 nm or greater than or equal to 3 nm. Therefore, the pellet can also be referred to as a nanocrystal (nc). Furthermore, the CAAC-OS can also be referred to as an oxide semiconductor including c-axis aligned nanocrystals (CANC). A pellet reflects unevenness of a formation surface or a top surface of the CAAC-OS and is parallel to the formation surface or the top surface of the CAAC-OS.

FIGS. 38B and 38C show Cs-corrected high-resolution TEM images of a plane of the CAAC-OS observed in the direction substantially perpendicular to the sample surface. FIGS. 38D and 38E are images obtained by image processing of FIGS. 38B and 38C. The method of image processing is as follows. The image in FIG. 38B is subjected to fast Fourier transform (FFT) to obtain an FFT image. Then, mask processing is performed on the obtained FFT image such that part in the range of 2.8 nm⁻¹ to 5.0 nm⁻¹ from the reference point is left. After the mask processing, the FFT image is subjected to inverse fast Fourier transform (IFFT) to obtain a processed image. The image obtained in this manner is referred to as an FFT filtering image. The FFT filtering image is a Cs-corrected high-resolution TEM image from which a periodic component is extracted and shows a lattice arrangement.

In FIG. 38D, a portion in which the lattice arrangement is broken is shown by dashed lines. A region surrounded by dashed lines corresponds to one pellet. The portion denoted by the dashed lines is a junction of pellets. The dashed lines draw a hexagon, which means that the pellet has a hexagonal shape. Note that the shape of the pellet is not always a regular hexagon but is a non-regular hexagon in many cases.

In FIG. 38E, a dotted line denotes a portion between a region where a lattice arrangement is well aligned and another region where a lattice arrangement is well aligned, and dashed lines denote the directions of the lattice arrangements. A clear crystal grain boundary cannot be observed even in the vicinity of the dotted line. When a lattice point in the vicinity of the dotted line is regarded as a center and surrounding lattice points are joined, a distorted hexagon, a distorted pentagon, or a distorted heptagon can be formed, for example. That is, a lattice arrangement is distorted so that formation of a crystal grain boundary is inhibited. This is probably because the CAAC-OS can tolerate distortion owing to a low density of the atomic arrangement in an a-b plane direction, the interatomic bond distance changed by substitution of a metal element, and the like.

As described above, the CAAC-OS has c-axis alignment, its pellets (nanocrystals) are connected in the a-b plane direction, and its crystal structure has distortion. For this reason, the CAAC-OS can also be referred to as an oxide semiconductor including a c-axis-aligned a-b-plane-anchored (CAA) crystal.

The CAAC-OS is an oxide semiconductor with high crystallinity. Entry of impurities, formation of defects, or the like might decrease the crystallinity of an oxide semiconductor. This means that the CAAC-OS has few impurities and defects (e.g., oxygen vacancies).

Note that an impurity means an element other than the main components of an oxide semiconductor, such as hydrogen, carbon, silicon, or a transition metal element. For example, an element (e.g., silicon) having stronger bonding force to oxygen than a metal element constituting a part of an oxide semiconductor extracts oxygen from the oxide semiconductor, which results in a disordered atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities contained in the oxide semiconductor might serve as carrier traps or carrier generation sources, for example. For example, an oxygen vacancy in the oxide semiconductor might serve as a carrier trap or serve as a carrier generation source when hydrogen is captured therein.

The CAAC-OS having few impurities and oxygen vacancies is an oxide semiconductor with a low carrier density (specifically, lower than 8×10¹¹ cm⁻³, preferably lower than 1×10¹¹ cm⁻³, further preferably lower than 1×10¹⁰ cm⁻³, and higher than or equal to 1×10⁻⁹ cm⁻³). Such an oxide semiconductor is referred to as a highly purified intrinsic or substantially highly purified intrinsic oxide semiconductor. A CAAC-OS has a low impurity concentration and a low density of defect states. Thus, the CAAC-OS can be regarded as an oxide semiconductor having stable characteristics.

<3-3. nc-OS>

Next, an nc-OS will be described.

Analysis of an nc-OS by XRD will be described. When the structure of an nc-OS is analyzed by an out-of-plane method, a peak indicating orientation does not appear. That is, a crystal of an nc-OS does not have orientation.

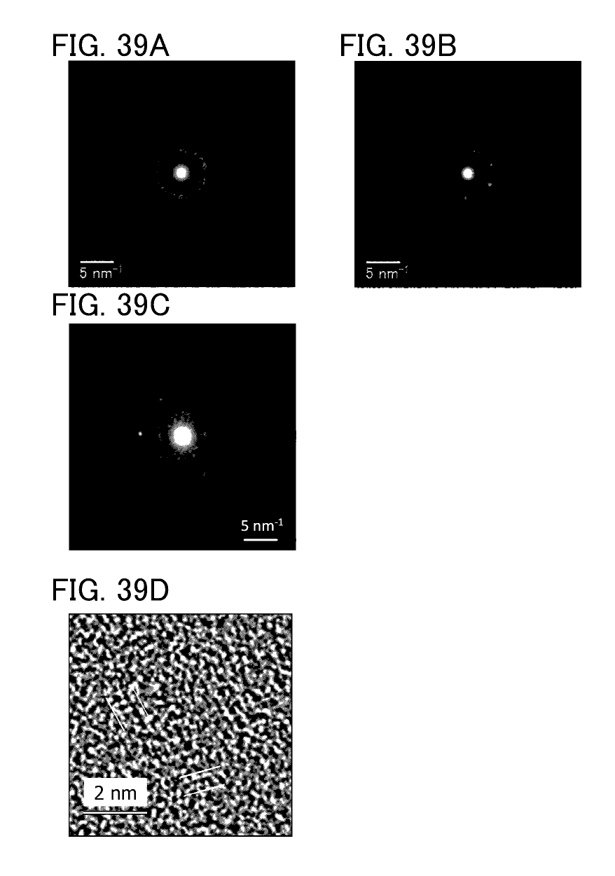

For example, when an electron beam with a probe diameter of 50 nm is incident on a 34-nm-thick region of a thinned nc-OS including an InGaZnO₄ crystal in the direction parallel to the formation surface, a ring-like diffraction pattern (nanobeam electron diffraction pattern) shown in FIG. 39A is observed. FIG. 39B shows a diffraction pattern (nanobeam electron diffraction pattern) obtained when an electron beam with a probe diameter of 1 nm is incident on the same sample. In FIG. 39B, a plurality of spots are observed in a ring-like region. Thus, ordering in an nc-OS is not observed with an electron beam with a probe diameter of 50 nm but is observed with an electron beam with a probe diameter of 1 nm.

When an electron beam with a probe diameter of 1 nm is incident on a region with a thickness less than 10 nm, an electron diffraction pattern in which spots are arranged in an approximately regular hexagonal shape as shown in FIG. 39C is observed in some cases. This means that an nc-OS has a well-ordered region, that is, a crystal, in the thickness range of less than 10 nm. Note that an electron diffraction pattern having regularity is not observed in some regions because crystals are aligned in various directions.

FIG. 39D shows a Cs-corrected high-resolution TEM image of a cross section of an nc-OS observed in the direction substantially parallel to the formation surface. In the high-resolution TEM image, the nc-OS has a region in which a crystal part is observed as indicated by additional lines and a region in which a crystal part is not clearly observed. In most cases, the size of a crystal part included in the nc-OS is greater than or equal to 1 nm and less than or equal to 10 nm, specifically greater than or equal to 1 nm and less than or equal to 3 nm. Note that an oxide semiconductor including a crystal part whose size is greater than 10 nm and less than or equal to 100 nm may be referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

As described above, in the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, in some cases, the nc-OS cannot be distinguished from an a-like OS or an amorphous oxide semiconductor, depending on an analysis method.

Since there is no regularity of crystal orientation between the pellets (nanocrystals), the nc-OS can also be referred to as an oxide semiconductor including random aligned nanocrystals (RANC) or an oxide semiconductor including non-aligned nanocrystals (NANC).

The nc-OS is an oxide semiconductor that has higher regularity than an amorphous oxide semiconductor. Therefore, the nc-OS has a lower density of defect states than the a-like OS and the amorphous oxide semiconductor. Note that there is no regularity of crystal orientation between different pellets in the nc-OS. Therefore, the nc-OS has a higher density of defect states than the CAAC-OS.

<3-4. a-like OS>

An a-like OS has a structure between the structure of an nc-OS and the structure of an amorphous oxide semiconductor.

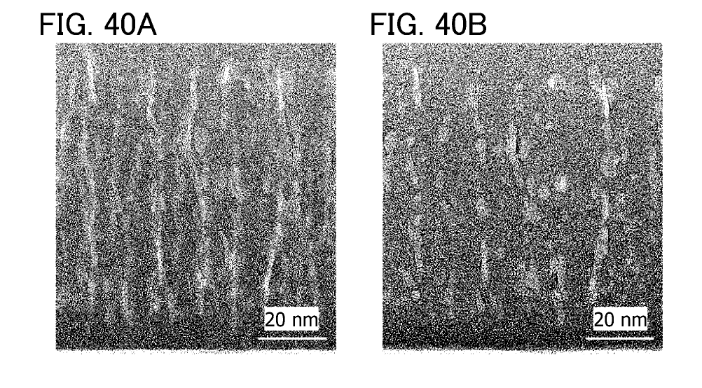

FIGS. 40A and 40B show high-resolution cross-sectional TEM images of an a-like OS. The high-resolution cross-sectional TEM image of the a-like OS in FIG. 40A is taken at the start of the electron irradiation. The high-resolution cross-sectional TEM image of the a-like OS in FIG. 40B is taken after the irradiation with electrons (e⁻) at 4.3×10⁸ e⁻/nm². FIGS. 40A and 40B show that striped bright regions extending vertically are observed in the a-like OS from the start of the electron irradiation. It can be also found that the shape of the bright region changes after the electron irradiation. Note that the bright region is presumably a void or a low-density region.

The a-like OS has an unstable structure because it contains a void. To verify that an a-like OS has an unstable structure as compared with a CAAC-OS and an nc-OS, a change in structure caused by electron irradiation will be described below.

An a-like OS, an nc-OS, and a CAAC-OS are prepared as samples. Each of the samples is an In—Ga—Zn oxide.

First, a high-resolution cross-sectional TEM image of each sample is obtained. The high-resolution cross-sectional TEM images show that all the samples have crystal parts.

It is known that a unit cell of an InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion in which the spacing between lattice fringes is greater than or equal to 0.28 nm and less than or equal to 0.30 nm is regarded as a crystal part of InGaZnO₄ in the following description. Each lattice fringe corresponds to the a-b plane of the InGaZnO₄ crystal.

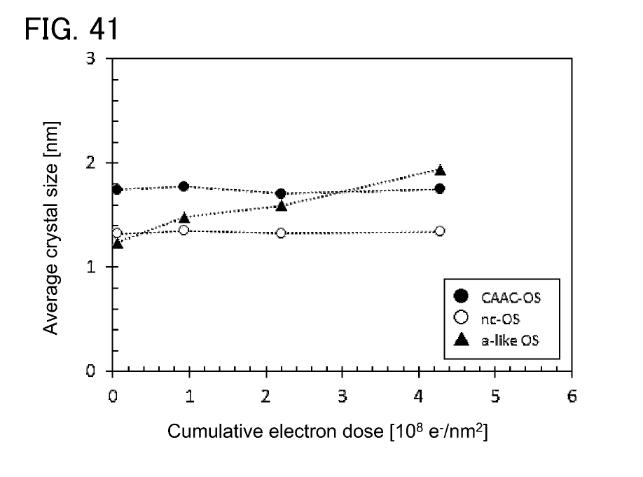

FIG. 41 shows a change in the average size of crystal parts (at 22 points to 30 points) in each sample. Note that the crystal part size corresponds to the length of a lattice fringe. FIG. 41 indicates that the crystal part size in the a-like OS increases with an increase in the cumulative electron dose in obtaining TEM images, for example. As shown in FIG. 41, a crystal part with a size of approximately 1.2 nm (also referred to as an initial nucleus) at the start of TEM observation grows to a size of approximately 1.9 nm at a cumulative electron (e⁻) dose of 4.2×10⁸ e⁻/nm². In contrast, the crystal part sizes in the nc-OS and the CAAC-OS show few changes from the start of electron irradiation to a cumulative electron dose of 4.2×10⁸ e⁻/nm². As shown in FIG. 41, the crystal part sizes in the nc-OS and the CAAC-OS are approximately 1.3 nm and approximately 1.8 nm, respectively, regardless of the cumulative electron dose. For the electron beam irradiation and TEM observation, a Hitachi H-9000NAR transmission electron microscope was used. The conditions of the electron beam irradiation were as follows: the accelerating voltage was 300 kV; the current density was 6.7×10⁵ e⁻/(nm²·s); and the diameter of an irradiation region was 230 nm.

In this manner, growth of the crystal part in the a-like OS may be induced by electron irradiation. In contrast, in the nc-OS and the CAAC-OS, growth of the crystal part is hardly induced by electron irradiation. That is, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single-crystal oxide semiconductor having the same composition. The density of the nc-OS and the density of the CAAC-OS are each higher than or equal to 92.3% and lower than 100% of the density of the single-crystal oxide semiconductor having the same composition. It is difficult to deposit an oxide semiconductor having a density lower than 78% of the density of the single-crystal oxide semiconductor.

For example, in the case of an oxide semiconductor whose atomic ratio of In to Ga and Zn is 1:1:1, the density of single-crystal InGaZnO₄ with a rhombohedral crystal structure is 6.357 g/cm³. Accordingly, in the case of the oxide semiconductor whose atomic ratio of In to Ga and Zn is 1:1:1, the density of the a-like OS is higher than or equal to 5.0 g/cm³ and lower than 5.9 g/cm³, for example. In the case of the oxide semiconductor whose atomic ratio of In to Ga and Zn is 1:1:1, the density of the nc-OS and the density of the CAAC-OS are each higher than or equal to 5.9 g/cm³ and lower than 6.3 g/cm³, for example.

In the case where an oxide semiconductor having a certain composition does not exist in a single-crystal state, single-crystal oxide semiconductors with different compositions are combined at an adequate ratio, which makes it possible to calculate a density equivalent to that of a single-crystal oxide semiconductor with the desired composition. The density of a single-crystal oxide semiconductor having the desired composition may be calculated using a weighted average with respect to the combination ratio of the single-crystal oxide semiconductors with different compositions. Note that it is preferable to use as few kinds of single-crystal oxide semiconductors as possible to calculate the density.

As described above, oxide semiconductors have various structures and various properties. Note that an oxide semiconductor may be a stacked film including two or more of an amorphous oxide semiconductor, an a-like OS, an nc-OS, and a CAAC-OS, for example.

The structures described in this embodiment can be used in appropriate combination with the structures described in any of the other embodiments.

### Embodiment 4

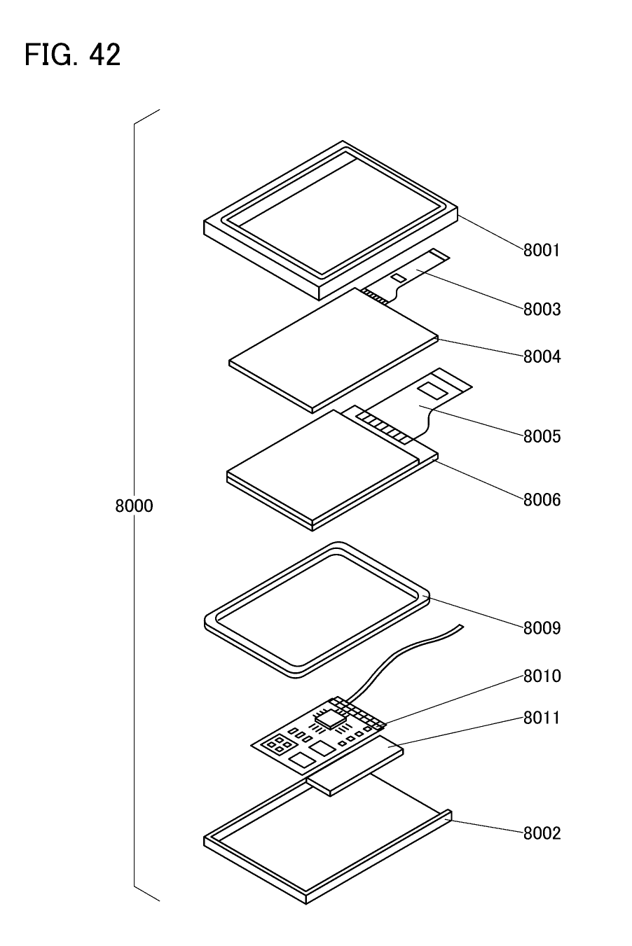

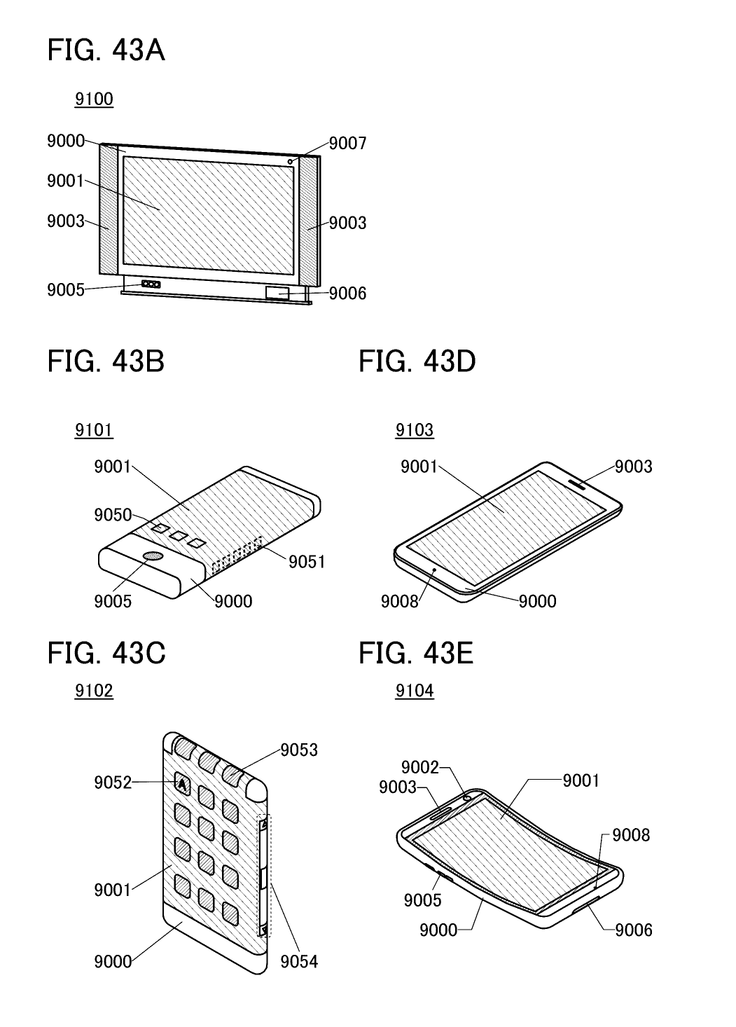

In this embodiment, a display module and electronic devices that include the display device of one embodiment of the present invention will be described with reference to FIG. 42, FIGS. 43A to 43E, and FIGS. 44A to 44E, and FIGS. 45A and 45B.

### <4-1. Display Module>

In a display module 8000 illustrated in FIG. 42, a touch panel 8004 connected to an FPC 8003, a display panel 8006 connected to an FPC 8005, a frame 8009, a printed board 8010, and a battery 8011 are provided between an upper cover 8001 and a lower cover 8002.

The display device of one embodiment of the present invention can be used for, for example, the display panel 8006.

The shapes and sizes of the upper cover 8001 and the lower cover 8002 can be changed as appropriate in accordance with the sizes of the touch panel 8004 and the display panel 8006.

The touch panel 8004 can be a resistive touch panel or a capacitive touch panel and may overlap with the display panel 8006. Alternatively, a counter substrate (sealing substrate) of the display panel 8006 can have a touch panel function. Alternatively, a photosensor may be provided in each pixel of the display panel 8006 so as to function as an optical touch panel.

The frame 8009 protects the display panel 8006 and functions as an electromagnetic shield for blocking electromagnetic waves generated by the operation of the printed board 8010. The frame 8009 can function as a radiator plate.

The printed board 8010 is provided with a power supply circuit and a signal processing circuit for outputting a video signal and a clock signal. As a power source for supplying power to the power supply circuit, an external commercial power source or a power source using the battery 8011 provided separately may be used. The battery 8011 can be omitted in the case of using a commercial power source.

The display module 8000 may be additionally provided with a member such as a polarizing plate, a retardation plate, or a prism sheet.

### <4-2. Electronic Device>

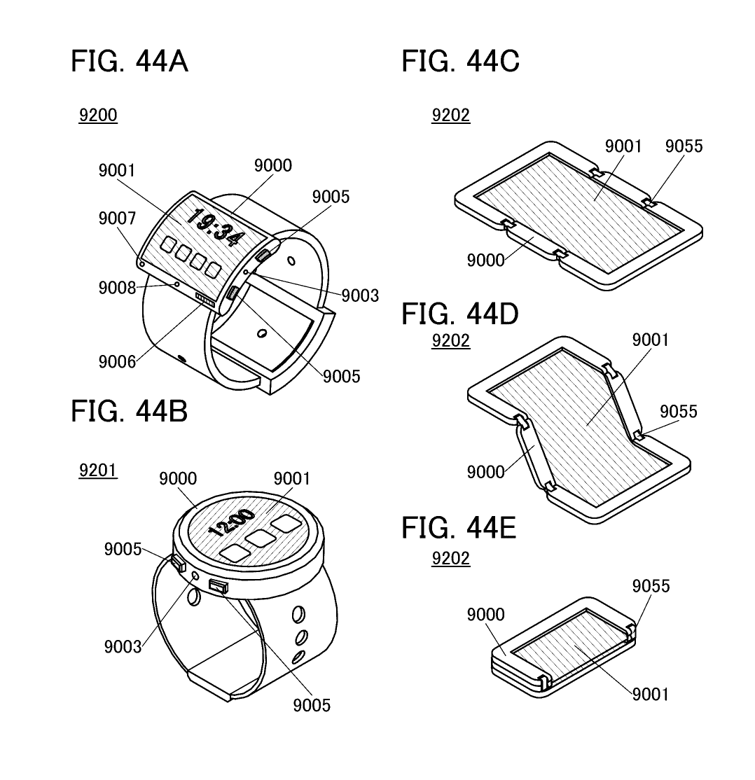

FIGS. 43A to 43E and FIGS. 44A to 44E illustrate electronic devices. These electronic devices can include a housing 9000, a display portion 9001, a camera 9002, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIGS. 43A to 43E and FIGS. 44A to 44 E can have a variety of functions, for example, a function of displaying a variety of data (a still image, a moving image, a text image, and the like) on the display portion, a touch panel function, a function of displaying a calendar, date, time, and the like, a function of controlling a process with a variety of software (programs), a wireless communication function, a function of being connected to a variety of computer networks with a wireless communication function, a function of transmitting and receiving a variety of data with a wireless communication function, a function of reading a program or data stored in a memory medium and displaying the program or data on the display portion, and the like. Note that functions of the electronic devices illustrated in FIGS. 43A to 43E and FIGS. 44A to 44E are not limited thereto, and the electronic devices may have other functions.

The electronic devices illustrated in FIGS. 43A to 43E and FIGS. 44A to 44E will be described in detail below.

FIG. 43A is a perspective view illustrating a television device 9100. The television device 9100 can include the display portion 9001 having a large screen size of, for example, 50 inches or more, 80 inches or more, or 100 inches or more.

FIG. 43B, FIG. 43C, FIG. 43D, and FIG. 43E are perspective views illustrating a portable information terminal 9101, a portable information terminal 9102, a portable information terminal 9103, and a portable information terminal 9104, respectively.

The portable information terminal 9101 illustrated in FIG. 43B has, for example, one or more of a function of a telephone set, a notebook, and an information browsing system. Specifically, the portable information terminal 9101 can be used as a smartphone. Although not illustrated, the speaker 9003, the connection terminal 9006, the sensor 9007, and the like may be provided in the portable information terminal 9101. The portable information terminal 9101 can display characters and image information on its plurality of surfaces. For example, three operation buttons 9050 (also referred to as operation icons or simply icons) can be displayed on one surface of the display portion 9001. Furthermore, information 9051 indicated by dashed rectangles can be displayed on another surface (for example, a side surface) of the display portion 9001. Examples of the information 9051 include notification from a social networking service (SNS), display indicating reception of an e-mail or an incoming call, the title of the e-mail, the SNS, or the like, the sender of the e-mail, the SNS, or the like, the date, the time, remaining battery, and the strength of a received signal. Alternatively, the operation buttons 9050 or the like may be displayed in place of the information 9051. The display portion 9001 of the portable information terminal 9101 partly has a curved surface.

The portable information terminal 9102 illustrated in FIG. 43C has a function of displaying information, for example, on three or more sides of the display portion 9001. Here, information 9052, information 9053, and information 9054 are displayed on different sides. For example, a user of the portable information terminal 9102 can see the display (here, the information 9053) with the portable information terminal 9102 put in a breast pocket of his/her clothes. Specifically, a caller's phone number, name, or the like of an incoming call is displayed in a position that can be seen from above the portable information terminal 9102. Thus, the user can see the display without taking out the portable information terminal 9102 from the pocket and decide whether to answer the call. The display portion 9001 of the portable information terminal 9102 partly has a curved surface.

Unlike in the portable information terminals 9101 and 9102 described above, the display portion 9001 does not have a curved surface in the portable information terminal 9103 illustrated in FIG. 43D.

The display portion 9001 of the portable information terminals 9104 illustrated in FIG. 43E is curved. As illustrated in FIG. 43E, it is preferable that the portable information terminal 9104 be provided with a camera 9002 to have a function of taking a still image, a function of taking a moving image, a function of storing the taken image in a memory medium (an external memory medium or a memory medium incorporated in the camera), a function of displaying the taken image on the display portion 9001, or the like.

FIG. 44A is a perspective view of a watch-type portable information terminal 9200. FIG. 44B is a perspective view of a watch-type portable information terminal 9201.

The portable information terminal 9200 illustrated in FIG. 44A is capable of executing a variety of applications such as mobile phone calls, e-mailing, viewing and editing texts, music reproduction, Internet communication, and computer games. The display surface of the display portion 9001 is bent, and images can be displayed on the bent display surface. The portable information terminal 9200 can employ near field communication that is a communication method based on an existing communication standard. In that case, for example, mutual communication between the portable information terminal 9200 and a headset capable of wireless communication can be performed, and thus hands-free calling is possible. Moreover, the portable information terminal 9200 includes the connection terminal 9006, and data can be directly transmitted to and received from another information terminal via a connector. Charging through the connection terminal 9006 is possible. Note that the charging operation may be performed by wireless power feeding without using the connection terminal 9006.

Unlike in the portable information terminal 9200 illustrated in FIG. 44A, the display surface of the display portion 9001 is not curved in the portable information terminal 9201 illustrated in FIG. 44B. Furthermore, the external state of the display portion of the portable information terminal 9201 is a non-rectangular shape (a circular shape in FIG. 44B).

FIGS. 44C, 44D, and 44E are perspective views of a foldable portable information terminal 9202. FIG. 44C is a perspective view illustrating the portable information terminal 9202 that is opened. FIG. 44D is a perspective view illustrating the portable information terminal 9202 that is being opened or being folded. FIG. 44E is a perspective view illustrating the portable information terminal 9202 that is folded.

The folded portable information terminal 9202 is highly portable, and the opened portable information terminal 9202 is highly browsable due to a seamless large display region. The display portion 9001 of the portable information terminal 9201 is supported by three housings joined together by hinges 9055. By folding the portable information terminal 9202 at a connection portion between two housings 9000 with the hinges 9055, the portable information terminal 9202 can be reversibly changed in shape from opened to folded. For example, the portable information terminal 9202 can be bent with a radius of curvature of greater than or equal to 1 mm and less than or equal to 150 mm.

The display device which is one embodiment of the present invention can be preferably used for the display portion 9001.

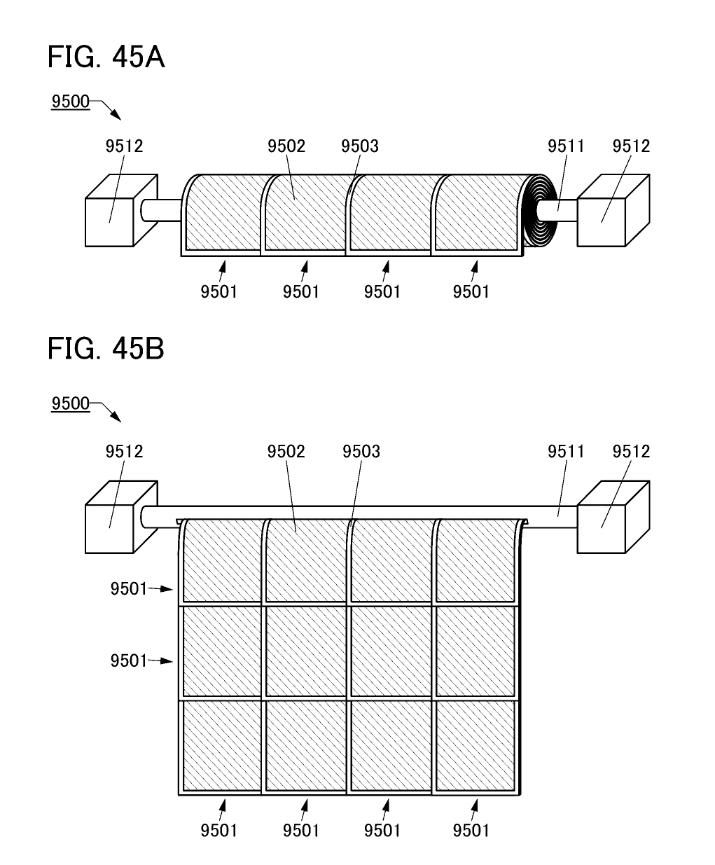

FIGS. 45A and 45B are perspective views of a display device 9500 including a plurality of display panels. Note that the plurality of display panels are wound in the perspective view in FIG. 45A, and are unwound in the perspective view in FIG. 45B.

The display device 9500 illustrated in FIGS. 45A and 45B includes a plurality of display panels 9501, a hinge 9511, and a bearing 9512. The plurality of display panels 9501 each include a display region 9502 and a light-transmitting region 9503.

Each of the plurality of display panels 9501 is flexible. Two adjacent display panels 9501 are provided so as to partly overlap with each other. For example, the light-transmitting regions 9503 of the two adjacent display panels 9501 can be overlapped each other. A display device having a large screen can be obtained with the plurality of display panels 9501. The display device is highly versatile because the display panels 9501 can be wound depending on its use.

Moreover, although the display regions 9502 of the adjacent display panels 9501 are separated from each other in FIGS. 45A and 45B, without limitation to this structure, the display regions 9502 of the adjacent display panels 9501 may overlap with each other without any space so that a continuous display region 9502 is obtained, for example.

The display device of one embodiment of the present invention can be preferably used in the display panel 9501.

Electronic devices described in this embodiment are characterized by having a display portion for displaying some sort of information. Note that the semiconductor device of one embodiment of the present invention can also be used for an electronic appliance that does not have a display portion.

The structure described in this embodiment can be used in appropriate combination with the structure described in any of the other embodiments.

### Embodiment 5

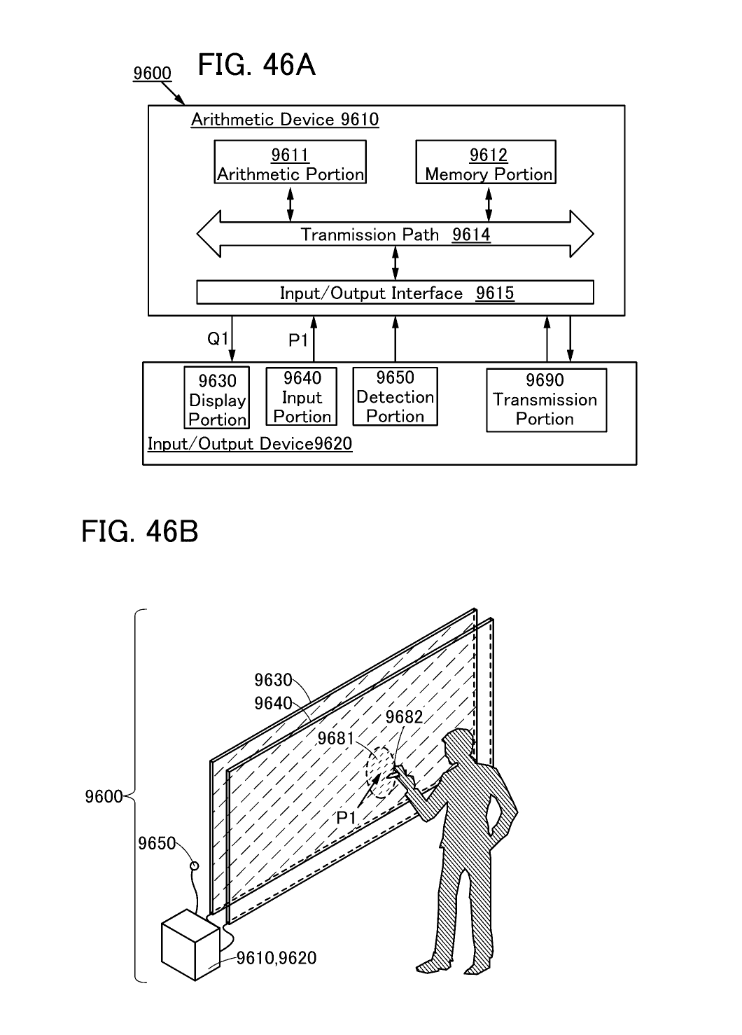

In this embodiment, the structure of a data processor including the display device of one embodiment of the present invention will be described with reference to FIGS. 46A and 46B.

FIG. 46A is a block diagram illustrating the structure of a data processor 9600 including the display device of one embodiment of the present invention. FIG. 46B is a schematic diagram illustrating the data processor 9600 being in operation.

The following describes components of the data processor 9600. In some cases, the components cannot be clearly distinguished from each other and one component also serves as another component or includes part of another component.

### <5. Structure Example of Data Processor>

The data processor 9600 includes an arithmetic device 9610 and an input/output device 9620.

### [Arithmetic Unit]

The arithmetic device 9610 includes an arithmetic portion 9611, a memory portion 9612, a transmission path 9614, and an input/output interface 9615.

### [Arithmetic Portion]

The arithmetic portion 9611 has a function of executing a program.

### [Memory Portion]

The memory portion 9612 has a function of storing a program executed by the arithmetic portion 9611, initial information, setting information, an image, or the like. Specifically, a hard disk, a flash memory, a memory including a transistor formed using an oxide semiconductor, or the like can be used as the memory portion 9612.

### [Program]

A program is executed by the arithmetic portion 9611 through three steps described below with reference to FIG. 46B, for example.

In a first step, positional data P1 is acquired.

In a second step, a first region 9681 is determined on the basis of the positional data P1.

In a third step, an image (image data Q1) with higher luminance than an image displayed on a region other than the first region 9681 is produced as an image displayed on the first region 9681.

For example, the arithmetic device 9610 determines the first region 9681 on the basis of the positional data P1. The first region 9681 can have, specifically, an elliptical shape, a circular shape, a polygonal shape, a rectangular shape, or the like. A region within a 60-cm radius, preferably within a 5-30-cm radius, from the positional data P1 is determined as the first region 9681, for example.

To produce an image with higher luminance than an image displayed on a region other than the first region 9681 as an image displayed on the first region 9681, the luminance of the image displayed on the first region 9681 is increased to 110% or more, preferably 120% or more and 200% or less, of the luminance of the image displayed on the region other than the first region 9681. Alternatively, the average luminance of the image displayed on the first region 9681 is increased to 110% or more, preferably 120% or more and 200% or less, of the average luminance of the image displayed on the region other than the first region 9681.

As a result of the program, the data processor 9600 can generate the image data Q1 with higher luminance than an image displayed on a region other than the first region 9681 as an image displayed on the first region 9681 on the basis of the positional data P1. Consequently, the data processor 9600 can have high convenience and can provide operators with comfortable operation.

### [Input/Output Interface]

The input/output interface 9615 includes a terminal or a wiring. The input/output interface 9615 has a function of supplying data and a function of receiving data. The input/output interface 9615 can be electrically connected to the transmission path 9614 and/or the input/output device 9620, for example.

### [Transmission Path]

The transmission path 9614 includes a wiring. The transmission path 9614 has a function of supplying data and a function of receiving data. The transmission path 9614 can be electrically connected to the arithmetic portion 9611, the memory portion 9612, or the input/output interface 9615, for example.

### [Input/Output Device]

The input/output device 9620 includes a display portion 9630, an input portion 9640, a sensor portion 9650, and a communication portion 9690.

### [Display Portion]

The display portion 9630 includes a display panel. The display panel includes a pixel having a structure including a reflective display element and a transmissive light-emitting element. The luminance of a displayed image can be increased by increasing the reflectance of the reflective display element or the luminance of the light-emitting element with the use of the image data. That is, the display device of one embodiment of the present invention can be preferably used in the display portion 9630.

### [Input Portion]

The input portion 9640 includes an input panel. The input panel includes, for example, a proximity sensor. The proximity sensor has a function of sensing a pointer 9682. Note that a finger, a stylus pen, or the like can be used as the pointer 9682. For the stylus pen, a light-emitting element such as a light-emitting diode, a metal piece, a coil, or the like can be used.

As the proximity sensor, a capacitive proximity sensor, an electromagnetic inductive proximity sensor, an infrared proximity sensor, a proximity sensor including a photoelectric conversion element, or the like can be used.

The capacitive proximity sensor includes a conductive film and has a function of sensing the proximity to the conductive film. To determine positional data, for example, a plurality of conductive films are provided in different regions of the input panel and a region where a finger or the like used as the pointer 9682 approaches can be determined in accordance with a change in parasitic capacitance of the conductive films.

The electromagnetic inductive proximity sensor includes a function of sensing the proximity of a metal piece, a coil, or the like to a sensor circuit. To determine positional data, for example, a plurality of oscillation circuits are provided in different regions of the input panel and a region where a metal piece, a coil, or the like included in a stylus pen or the like used as the pointer 9682 approaches can be determined in accordance with a change in the circuit constant of the oscillation circuits.

The photo-detection proximity sensor has a function of sensing the proximity of a light-emitting element. To determine positional data, for example, a plurality of photoelectric conversion elements are provided in different regions of the input panel and a region where a light-emitting element included in a stylus pen or the like used as the pointer 9682 approaches can be determined in accordance with a change in the electromotive force of the photoelectric conversion elements.

### [Sensor Portion]

As the sensor portion 9650, an illuminance sensor that senses the environmental brightness, a human motion sensor, or the like can be used.

### [Communication Portion]

The communication portion 9690 has a function of supplying data to a network and acquiring data from the network.

The data processor 9600 described above can be used for education, or can be used for a digital signage or a smart television system, for example.

This embodiment can be combined with any of the other embodiments in this specification as appropriate.

This application is based on Japanese Patent Application serial no. 2015-179114 filed with Japan Patent Office on Sep. 11, 2015, the entire contents of which are hereby incorporated by reference.

What is claimed is:

1. A display device comprising:
a first display element;
a second display element;
a first transistor; and
a second transistor,
wherein the first display element comprises a first pixel electrode and a liquid crystal layer,
wherein the second display element comprises a second pixel electrode and a light-emitting layer,
wherein the first transistor is electrically connected to the first pixel electrode,
wherein the second transistor is electrically connected to the second pixel electrode,
wherein the first transistor and the second transistor each comprise an oxide semiconductor film, and
wherein the first pixel electrode and the second pixel electrode each comprise at least one metal element contained in the oxide semiconductor film.

2. The display device according to claim 1,
wherein the first display element further comprises a reflective film,
wherein the reflective film is electrically connected to the first pixel electrode and has a function of reflecting incident light,
wherein the reflective film is provided with an opening transmitting incident light, and
wherein the second display element has a function of emitting light toward the opening.

3. The display device according to claim 1,
wherein the oxide semiconductor film comprises In, Zn, and M, and
wherein M is Al, Ga, Y, or Sn.

4. The display device according to claim 1,
wherein the oxide semiconductor film comprises a crystal part, and
wherein the crystal part has c-axis alignment.

5. The display device according to claim 1, wherein at least one of the first transistor and the second transistor has a staggered structure.

6. The display device according to claim 1,
wherein at least one of the first transistor and the second transistor comprise:
a first conductive film,
a first insulating film over the first conductive film;
a first oxide semiconductor film over the first insulating film;
a second insulating film over the first oxide semiconductor film; and
a second oxide semiconductor film over the second insulating film,
wherein the second oxide semiconductor film covers a side surface of the first oxide semiconductor film with the second insulating film positioned therebetween in a cross section in a channel width direction, and
wherein the first oxide semiconductor film is surrounded by the first conductive film and the second oxide semiconductor film in the cross section in the channel width direction.
